(19) United States
(12) Patent Application Publication
(10) Pub. No.: US 2010/0140602 A1
(43) Pub. Date: Jun. 10, 2010

(54) ORGANIC ELECTROLUMINESCENCE DEVICE

(75) Inventor: Wataru SOTOYAMA, Kanagawa (JP)

Correspondence Address: Solaris Intellectual Property Group, PLLC, 401 Holland Lane, Suite 407, Alexandria, VA, 22314, US

(73) Assignee: FUJIFILM CORPORATION, Minato-ku, Tokyo (JP)

(21) Appl. No.: 12/628,241

(22) Filed: Dec. 1, 2009

(30) Foreign Application Priority Data
Dec. 9, 2008 (JP) 2008-313239

(51) Int. Cl. H01L 51/54

(52) U.S. Cl. 257/40; 257/E51.044

(57) ABSTRACT

There is provided an organic electroluminescence device comprising a pair of electrodes on a substrate and at least one organic layer containing a luminescence layer between the electrodes, the luminescence layer comprising at least 3 luminescence materials different in luminescent color, and the at least 3 luminescence materials being platinum complexes.

### CROSS-REFERENCE TO RELATED APPLICATION

This application claims priority under 35 USC 119 from Japanese Patent Application No. 2008-313239 filed on Dec. 9, 2008, the disclosure of which is incorporated by reference herein.

### BACKGROUND

1. Field of the Invention

The present invention relates to an organic electroluminescence device (also referred to hereinafter as organic EL device) which can be utilized as surface light sources such as full color displays, backlights and illumination sources, and light source arrays such as printers.

2. Related Art

Nowadays, various display devices have been actively researched and developed, and particularly organic EL devices can attain highly intensive light emission with low voltage and are thus attracted as promising display devices.

An organic EL device is composed of a luminescence layer or plural organic layers containing a luminescence layer, and a pair of electrodes into which an organic layer was interposed. The organic EL device is a device wherein an electron injected from a cathode and a hole injected from an anode are recombined in an organic layer, to utilize emission from an exciton formed and/or emission from another exciton molecule formed by energy transfer from the above exciton.

The organic electroluminescence devices can attain high-intensity emission with low voltage and thus have potential applications in a wide variety of broad fields including cell phone displays, personal digital assistants (PDA), computer displays, automotive information displays, TV monitors, and generic illumination, and have advantages such as device thinning, weight saving, downsizing, and power saving. Accordingly, the organic electroluminescence devices are highly expected to play principle roles in the future electron display market. In order that the organic electroluminescence devices can be used practically in place of conventional displays in these fields, however, there are still problems for many technical improvements such as emission intensity and hue, durability in broad usage environments, and low-cost productivity in large amounts.

The organic EL device is also characterized in that emission of various emission colors is possible by mixing plural emission colors.

Among emission colors, there is particularly high need for white emission. White emission can be utilized for electrical power saving in generic illumination, in-vehicle displays, and backlights. A color filter may be used to divide white emission into blue, green and red pixels or to enable a full-color display.

For example, an organic EL device wherein two or more different luminescence materials are contained in a luminescence layer and at least one of the luminescence materials is an ortho-metalated complex is disclosed (see, for example, Japanese Patent Application Laid-Open (JP-A) No. 2001-319780). Specifically, a green light-emitting tris(2-phenylpyridine) iridium complex and a red light-emitting bis(2-phenylquinoline)acetyl acetate iridium complex have been disclosed as ortho-metalated complexes. Other luminescence material used with these iridium complexes, that is, a blue light-emitting butadiene compound and pyrene compound, a green light-emitting coumarin compound, a red light-emitting styryl compound, and a nonmetal complex such as rubrene have been disclosed.

It is disclosed an organic luminescence device containing at least two or more luminescence materials in a luminescence layer, wherein at least one of the luminescence materials is a phosphorescence material and the excitation lifetime of a luminescence material having the shortest light wavelength is shorter than the excitation lifetime of other luminescence materials. Specifically, it is disclosed that a fluorescence material is used as a blue luminescence material, and phosphorescence materials are used as green and red luminescence materials. BAlq and Zn(BTZ)₂ are disclosed as fluorescence materials for blue luminescence material, Ir(ppy)₃ and Ir(CH₃-ppy)₃ as phosphorescence materials for green luminescence material, and Ir(piq)₃ and Ir(tiq)₃ as phosphorescence materials for red luminescence material.

### SUMMARY

The present invention has been made in view of the above circumstances and provides an organic electroluminescence device comprising a pair of electrodes on a substrate and at least one organic layer containing a luminescence layer between the electrodes, the luminescence layer comprising at least 3 luminescence materials different in luminescent color, and the at least 3 luminescence materials being platinum complexes.

### DETAILED DESCRIPTION OF THE INVENTION

Hereinafter, the organic electroluminescence device of the present invention (also referred to hereinafter as “organic EL device”) will be described in detail.

The organic EL device of the invention has a cathode and an anode on a substrate and has an organic layer containing an organic luminescence layer (hereinafter referred to sometimes as simply “luminescence layer”) between both the electrodes. From the viewpoint of properties of the fluorescent device, at least one electrode selected from the anode and cathode is preferably transparent.

The organic layer in the invention may be either a single layer or a lamination layer. When the organic layer is a lamination layer, the lamination layer is preferably a layer containing a hole transporting layer, a luminescence layer and an electron transporting layer laminated in this order from the anode side. The lamination layer may have an electron blocking layer or the like between the hole transporting layer and the luminescence layer or between the luminescence layer and the electron transporting layer. The lamination layer may have a hole injecting layer between the anode and the hole transporting layer or may have an electron injecting layer between the cathode and the electron transporting layer. Each layer may be divided into plural secondary layers.

The organic EL device is an organic electroluminescence device comprising a pair of electrodes on a substrate and at least one organic layer containing a luminescence layer between the electrodes, the luminescence layer comprising at least 3 luminescence materials different in luminescent color, and the at least 3 luminescence materials being platinum complexes.

Preferably, the at least 3 luminescence materials are a blue luminescence material having a luminescence peak wavelength of 400 nm or more and less than 500 nm, a green luminescence material having a luminescence peak wavelength of 500 nm or more and less than 570 nm, and a red luminescence material having a luminescence peak wavelength of 570 to 670 nm.

Preferably, the at least 3 luminescence materials are platinum complexes having a tridentate ligand or a tetradentate ligand.

Preferably, at least one of the at least 3 luminescence materials is at least one metal complex, wherein the metal complex has a tridentate or higher dentate ligand having a partial structure represented by the following formula (1), and the ligand is a linear ligand:

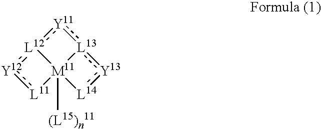

wherein in formula (1), M¹¹ represents a platinum ion; L¹¹, L¹², L¹³, L¹⁴ and L¹⁵ each independently represent a ligand coordinated to M¹¹; an atomic group may further be present between L¹¹ and L¹⁴, to form a cyclic ligand; L¹⁵ does not bond to both L¹¹ and L¹⁴ to form a cyclic ligand; Y¹¹, Y¹² and Y¹³ each independently represent a linking group, a single bond or a double bond; bonds between L¹¹ and Y¹², Y¹² and L¹², L¹² and Y¹¹, Y¹¹ and L¹³, L¹³ and Y¹³, and Y¹³ and L¹⁴ each independently represent a single bond or a double bond; and n¹¹ represents an integer from 0 to 4.

Preferably, at least one of the at least 3 luminescence materials has a partial structure represented by the following formula (2):

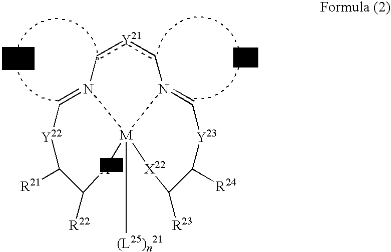

wherein in formula (2), M²¹ represents a platinum ion; Y²¹ represents a linking group, a single bond or a double bond; Y²² and Y²³ each independently represent a single bond or a linking group; Q²¹ and Q²² each independently represent an atomic group forming a nitrogen-containing heterocycle; a bond between a ring formed by Q²¹ and Y²¹, and a bond between a ring formed by Q²² and Y²¹, each independently represent a single bond or a double bond; X²¹ and X²² each independently represent an oxygen atom, a sulfur atom or a substituted or unsubstituted nitrogen atom; R²¹, R²², R²³ and R²⁴ each independently represent a hydrogen atom or a substituent; R²¹ and R²², or R²³ and R²⁴, may be bonded to each other to form a ring; L²⁵ represents a ligand coordinated to M²¹; and n²¹ represents an integer from 0 to 4.

Preferably, at least one of the at least 3 luminescence materials is at least one platinum complex of a tetradentate ligand having a partial structure represented by the formula (3):

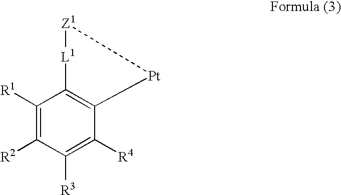

wherein in formula (3), Z¹ represents a nitrogen-containing heterocycle coordinated via a nitrogen atom to platinum; L¹ represents a single bond or a linking group; R¹, R³ and R⁴ each independently represent a hydrogen atom or a substituent; and R² represents a substituent.

Preferably, the platinum complex of a tetradentate ligand containing a partial structure represented by formula (3) is a platinum complex represented by the following formula (4):

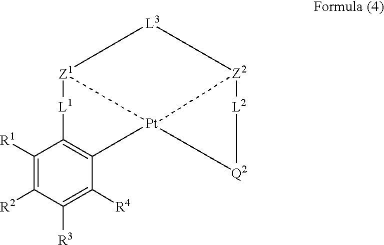

wherein in formula (4), Z¹ and Z² each independently represent a nitrogen-containing heterocycle coordinated via a nitrogen atom to platinum; Q² represents a group bonded to platinum via a carbon atom, an oxygen atom, a sulfur atom, a nitrogen atom or a phosphorus atom; L¹, L² and L³ each independently represent a single bond or a linking group; R¹, R³ and R⁴ each independently represent a hydrogen atom or a substituent, and R² represents a substituent.

Preferably, the platinum complex represented by formula (3) is a platinum complex represented by the following formula (5):

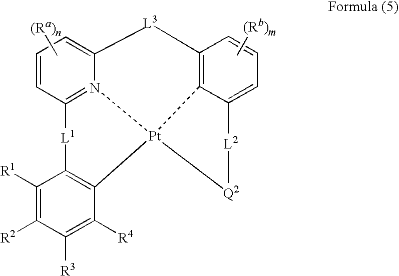

wherein in formula (5), Q² represents a group bonded to platinum via a carbon atom, an oxygen atom, a sulfur atom, a nitrogen atom or a phosphorus atom; L¹, L² and L³ each independently represent a single bond or a linking group; R¹, R³ and R⁴ each independently represent a hydrogen atom or a substituent; R² represents a substituent; R^{a} and R^{b} each independently represent a substituent; and n and m each independently represent an integer from 0 to 3.

Preferably, the platinum complex represented by formula (4) is a platinum complex represented by the following formula (6):

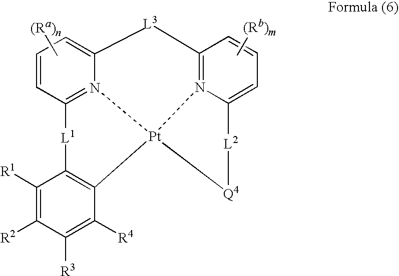

wherein in formula (6), Q⁴ represents an aromatic hydrocarbon cyclic group or an aromatic heterocyclic group which is bonded to platinum via a carbon atom or a nitrogen atom; L¹, L² and L³ each independently represent a single bond or a linking group; R¹, R³ and R⁴ each independently represent a hydrogen atom or a substituent; R² represents a substituent; R^{a} and R^{b} each independently represent a substituent; n and m each independently represent an integer from 0 to 3.

Preferably, the platinum complex represented by formula (6) is a compound represented by the following formula (7):

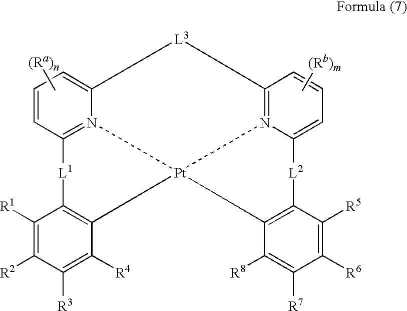

wherein in formula (7), L¹, L², L³, R¹ to R⁴, R^{a}, R^{b}, n and m have the same meanings as defined in the formula (6), R⁵, R⁷ and R⁸ each independently represent a hydrogen atom or a substituent; and R⁶ represents a substituent.

Preferably, the luminescence layer contains a hole transporting host material.

2. Constitutional Element of the Organic Electroluminescence Device

Now, the element constituting the luminescence device of the invention will be described in more detail.

(Substrate)

The substrate used in the invention is preferably a substrate that does not scatter or decline light emitted from the organic layer. Specific examples include yttrium stabilized with zirconia (YSZ), inorganic materials such as glass, polyesters such as polyethylene terephthalate, polybutylene terephthalate and polyethylene naphthalate, and organic materials such as polystyrene, polycarbonate, polyether sulfone, polyarylate, polyimide, polycycloolefin, norbornene resin, and poly(chlorotrifluoroethylene).

For example, when glass is used as the substrate, its material is preferably alkali-free glass to reduce eluted ions from the glass. When soda lime glass is used, the glass onto which a barrier coat such as silica has been applied is preferably used. When an organic material is used, the organic material is preferably one excellent in heat resistance, dimensional stability, solvent resistance, electrical insulation, and workability.

The shape, structure, size etc: of the substrate are not particularly limited, and can be selected appropriately depending on the use, object etc. of the luminescence device. Generally, the shape of the substrate is preferably plate. The structure of the substrate may be either a single layer structure or a laminate structure, or may be formed of single member of two or more members.

The substrate may be colorless and transparent or colored and transparent, but is preferably colorless and transparent to prevent scattering or declining of light emitted from the organic luminescence layer.

The substrate can be provided with a moisture permeation preventing layer (gas barrier layer) on its surface or backside.

The material of the moisture permeation preventing layer (gas barrier layer) is preferably an inorganic material such as silicon nitride and silicon oxide. The moisture permeation preventing layer (gas barrier layer) can be formed by for example high-frequency sputtering or the like.

When a thermoplastic substrate is used, a hard coat layer, an undercoat layer etc. may further be arranged as necessary.

(Anode)

It may usually suffice that the anode functions as an electrode to supply holes to the organic layer, and the shape, structure, size, etc. thereof are not particularly limited and can be selected properly from known electrode materials in accordance with the application use and the purpose of the luminescence device. As described above, the anode is set as transparent anode.

The material for the anode includes preferably, for example, metals, alloys, metal oxides, conductive compounds or mixtures of them. Specific examples of the anode material include conductive metal oxides such as tin oxide doped with antimony, fluorine, etc. (ATO, FTO), tin oxide, zinc oxide, indium oxide, indium tin oxide (ITO), and indium zinc oxide (IZO), metals such as gold, silver, chromium, and nickel, as well as mixtures or laminates of such metals with conductive metal oxides, inorganic conductive materials such as copper iodide and copper sulfide, organic conductive materials such as polyaniline, polythiophene and polypyrrole, and laminates thereof with ITO. Among them, preferred are conductive metal oxides, and ITO is particularly preferred with a view point of productivity, high conductivity, transparency, etc.

The anode can be formed on the substrate in accordance with a method selected properly, for example, from wet methods such as a printing method and a coating method, physical methods such as a vacuum vapor deposition method, a sputtering method, and an ion plating method, and chemical methods such as CVD and plasma CVD, in consideration of adaptability to the material constituting the anode. For example, when ITO is selected as the material for the anode, the anode can be formed in accordance with a DC or RF (Radio Frequency) sputtering method, a vacuum deposition method, an ion plating method, etc.

In the organic EL device of the invention, the position for forming the anode is not particularly limited and can be selected properly in accordance with the application use and the purpose of the luminescence device and it is preferably formed on the substrate. In this case, the anode may be formed entirely or partially on one of the surfaces of the substrate.

Patterning upon forming the anode may be conducted by chemical etching adopting photolithography, etc., or by physical etching adopting laser, etc. Further, the patterning may be conducted by vacuum vapor deposition, sputtering, etc. with a mask, or by a lift-off method or a printing method.

The thickness of the anode can be selected properly depending on the material constituting the anode and cannot be determined generally, but is usually about from 10 nm to 50 preferably from 50 nm to 20 μM.

The resistance value of the anode is preferably 10³Ω/□ or less, more preferably 10²Ω/□ or less. When the anode is transparent, it may be colorless transparent or colored transparent. For taking out light emission from the side of the transparent anode, the transmittance is preferably 60% or higher, more preferably 70% or higher.

The transparent electrode is described specifically in “New Development of Transparent Electrode Film”, supervised by Yutaka Sawada, published from CMC (1999) and the matters described therein can be applied to the invention. When a plastic substrate of low heat resistance is used, a transparent electrode using ITO or IZO and formed as a film at a low temperature of 150° C. or lower is preferred.

(Cathode)

It may usually suffice that the cathode functions as an electrode to inject electrons to the organic layer, and the shape, structure, size, etc. thereof are not particularly limited and can be selected properly from known electrode materials in accordance with the application use and the purpose of the luminescence device.

The material constituting the cathode includes, for example, metals, alloys, metal oxides, electroconductive compounds, and mixtures thereof. Specific examples include alkali metals (for example, Li, Na, K, and Cs), alkaline earth metals (for example, Mg and Ca), gold, silver, lead, aluminum, an sodium-potassium alloy, a lithium-aluminum alloy, a magnesium-silver alloy, indium, and rare earth metals such as ytterbium. They may be used alone or two or more of them can be preferably used in combination from the viewpoint of meeting both stability and electron injecting property.

Among them, the material constituting the cathode is either preferably an alkali metal or alkaline earth metal from the viewpoint of electron injecting property or preferably a material based on aluminum from the viewpoint of excellent storage stability.

The material based on aluminum refers to aluminum alone, an alloy of aluminum and 0.01 to 10% by weight of an alkali metal or alkaline earth metal, or a mixture thereof (for example, an lithium-aluminum alloy, a magnesium-aluminum alloy, etc.).

The materials for the cathode are described specifically in JP-A Nos. 2-15595 and 5-121172 and the materials described in the publications can be applied also to the invention.

The method of forming the cathode is not particularly limited and can be carried out in accordance with known methods.

For example, the cathode can be formed in accordance with a method selected properly from wetting methods such as a printing method and a coating method, physical methods such as a vacuum vapor deposition method, a sputtering method and an ion plating method, and chemical methods such as a CVD or plasma CVD method, in consideration of adaptability to the material constituting the cathode. For example, when a metal or the like is selected as a material for the cathode, it can be formed in accordance with a sputtering method, etc. by sputtering one of them or plurality of them simultaneously or successively.

Patterning upon forming the cathode may be conducted by chemical etching such as photolithography, physical etching such as laser, or vacuum vapor deposition or sputtering with a mask or by a lift off method or a printing method.

In the invention, the position for forming the cathode is not particularly limited and it may be formed entirely or partially on the organic layer.

Further, a dielectric layer of a fluoride or oxide of an alkali metal or alkaline earth metal may be inserted at a thickness of from 0.1 to 5 nm between the cathode and the organic layer. The dielectric layer can be regarded as a sort of an electron injecting layer. The dielectric layer can be formed, for example, by a vacuum vapor deposition method, a sputtering method or an ion plating method.

The thickness of the cathode can be suitably selected depending on the material constituting the cathode and cannot be sweepingly defined, but is usually about 10 nm to 5 μm, preferably 50 nm to 1 μm.

The cathode may be transparent or opaque. The transparent cathode is formed as thin as 1 nm to 10 nm and can be formed by laminating a transparent conductive material such as ITO and IZO.

(Organic Layer)

The organic layer in the invention will be described.

The organic EL device of the invention is an organic electroluminescence device comprising a pair of electrodes on a substrate and at least one organic layer containing a luminescence layer between the electrodes, the luminescence layer comprising at least 3 luminescence materials different in luminescent color, and the at least 3 luminescence materials being platinum complexes.

Other organic layers than the organic luminescence layer include layers such as a hole transporting layer, an electron transporting layer, a charge blocking layer, a hole injecting layer, and an electron injecting layer as described above.

In the organic EL device of the invention, the layers constituting the organic layer can be formed suitably by any of a dry film forming method such as a vapor deposition method or a sputtering method, a wet coating method, a transfer method, a printing method, an inkjet recording system, etc.

(Luminescence Layer)

The organic luminescence layer is a layer having a function of accepting holes from the anode, the hole injecting layer, or the hole transporting layer and accepting electrons from the cathode, the electron injecting layer, or the electron transporting layer upon application of an electric field, and providing a site for re-combination of hole and electron to emit light.

The luminescence layer in the invention contains at least 3 luminescence materials different in luminescent color, and at least the 3 luminescence materials are platinum complexes. Preferably, the luminescence material has a tridentate or higher dentate ligand having a partial structure represented by the formula (1), and the ligand is a linear ligand that is at least one kind of metal complex.

Preferably, the luminescence material contains a partial structure represented by the formula (2).

Preferably, the luminescence material is at least one kind of platinum complex of a tetradentate ligand containing the partial structure represented by the formula (3).

Preferably, the platinum complex of a tetradentate ligand containing the partial structure represented by the formula (3) is a platinum complex represented by the formula (4).

Preferably, the platinum complex represented by the formula (3) is a platinum complex represented by the formula (5).

Preferably, the platinum complex represented by the formula (4) is a platinum complex represented by the formula (6).

Preferably, the platinum complex represented by the formula (6) is a compound represented by the formula (7).

The content of the platinum complex in the luminescence layer used in the invention is 0.1 to 50% by weight, more preferably 1 to 40% by weight, even more preferably 5 to 30% by weight, most preferably 7 to 20% by weight, based on the total amount of the platinum complex.

The blue luminescence material having a luminescence peak wavelength of 400 nm or more and less than 500 nm is preferably 0.1 to 40% by weight, more preferably 1 to 25% by weight, even more preferably 5 to 20% by weight.

The green luminescence material having a luminescence peak wavelength of 500 nm or more and less than 570 nm is preferably 0.05 to 25% by weight, more preferably 0.1 to 20% by weight, even more preferably 0.2 to 10% by weight.

The red luminescence material having a luminescence peak wavelength of 570 to 670 nm is preferably 0.05 to 25% by weight, more preferably 0.1 to 20% by weight, even more preferably 0.1 to 10% by weight.

The relative contents of the blue luminescence material having a luminescence peak wavelength of 400 nm or more and less than 500 nm, the green luminescence material having a luminescence peak wavelength of 500 nm or more and less than 570 nm, and the red luminescence material having a luminescence peak wavelength of 570 to 670 nm, in terms of % by weight, are established such that the blue luminescence material:green luminescence material:red luminescence material is preferably 1 or more:1 or more:1, more preferably 2 or more:1 or more:1, even more preferably 5 or more:1 or more:1.

In the device having 1 luminescence layer wherein blue, green and red light-emitting platinum complexes are contained to emit white light, the relative contents of the luminescence materials are established such that the blue luminescence material:green luminescence material:red luminescence material are particularly preferably 10 or more:1 or more:1, in terms of % by weight.

The luminescence material in the invention will be described in detail.

First, the compound represented by the formula (1) will be described in detail.

In the formula (1), M¹¹ represents a platinum ion.

In the formula (1), L¹¹, L¹², L¹³ and L¹⁴ each independently represent a ligand coordinated to M¹¹. The atom contained in L¹¹, L¹², L¹³ and L¹⁴ and coordinated to M¹¹ is preferably a nitrogen atom, an oxygen atom, a sulfur atom, a carbon atom or a phosphorus atom, more preferably a nitrogen atom, an oxygen atom, a sulfur atom or a carbon atom, still more preferably a nitrogen atom, an oxygen atom or a carbon atom.

Bonds formed by M¹¹ and L¹¹, L¹², L¹³ and L¹⁴ respectively may be independently a covalent bond, an ionic bond and a coordinate bond. For the sake of description, the ligand in the invention is used when formed not only with a coordinate bond but also with another ionic or covalent bond.

Ligand consisting of L¹¹, Y¹², L¹², Y¹¹, L¹³, Y¹³ and L¹⁴ are preferably anionic ligands (ligands wherein at least one anion is bonded to a metal). The number of anions in the anionic ligands is preferably 1 to 3, more preferably 1 to 2, still more preferably 2.

L¹¹, L¹², L¹³ and L¹⁴ coordinated via a carbon atom to M¹¹ are not particularly limited and each independently represent an imino ligand, an aromatic hydrocarbon ring ligand (for example, a benzene ligand, a naphthalene ligand, an anthracene ligand, a phenanthrene ligand etc.), a heterocycle ligand (for example, a furan ligand, a thiophene ligand, a pyridine ligand, a pyrazine ligand, a pyrimidine ligand, a thiazole ligand, an oxazole ligand, a pyrrole ligand, an imidazole ligand, a pyrazole ligand, and a condensed ligand containing the same (for example, a quinoline ligand, a benzothiazole ligand etc.) or tautomers thereof).

L¹¹, L¹², L¹³ and L¹⁴ coordinated via a nitrogen atom to M¹¹ are not particularly limited and each independently represent a nitrogen-containing heterocycle ligand (for example, a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, an oxadiazole ligand, a thiadiazole ligand and a condensed ligand containing the same (for example, a quinoline ligand, a benzoxazole ligand, a benzimidazole ligand etc.) or tautomers thereof (in the invention, not only usual tautomers but the following examples are also defined as tautomers). For example, in JP-A No. 2007-103493, a 5-membered heterocyclic ligand of exemplary compound (24) described in Compound No. 24, a terminal 5-membered heterocyclic ligand of exemplary compound (64) described in Compound No. 28, and a 5-membered heterocyclic ligand of exemplary compound (145) described in Compound No. 37 are also defined as pyrrole tautomers), an amino ligand (an alkylamino ligand (preferably having 2 to 30 carbon atoms, more preferably 2 to 20 carbon atoms, and still more preferably 2 to 10, for example, methylamino etc.), an arylamino ligand (for example, phenylamino etc.), an acylamino ligand (preferably having 2 to 30 carbon atoms, more preferably 2 to 20 carbon atoms, and still more preferably 2 to 10, for example, acetylamino, benzoylamino etc.), an alkoxycarbonylamino ligand (preferably having 2 to 30 carbon atoms, more preferably 2 to 20 carbon atoms, and still more preferably 2 to 12, for example, methoxycarbonylamino etc.), an aryloxycarbonylamino ligand (preferably having 7 to 30 carbon atoms, more preferably 7 to 20 carbon atoms, and still more preferably 7 to 12, for example, phenyloxycarbonylamino etc.), a sulfonylamino ligand (preferably having 1 to 30 carbon atoms, more preferably 1 to 20 carbon atoms, and still more preferably 1 to 12, for example, methanesulfonylamino, benzenesulfonylamino etc.), an imino ligand etc.). These ligands may further be substituted.

L¹¹, L¹², L¹³ and L¹⁴ coordinated via an oxygen atom to M¹¹ are not particularly limited and each independently represent an alkoxy ligand (preferably having 1 to 30 carbon atoms, more preferably 1 to 20 carbon atoms, and still more preferably 1 to 10 carbon atoms, for example, methoxy, ethoxy, butoxy, 2-ethylhexyloxy etc.), an aryloxy ligand (preferably having 6 to 30 carbon atoms, more preferably 6 to 20 carbon atoms, and still more preferably 6 to 12, for example, phenyloxy, 1-naphthyloxy, 2-naphthyloxy etc.), a heterocyclic oxy ligand (preferably having 1 to 30 carbon atoms, more preferably 1 to 20 carbon atoms, and still more preferably 1 to 12, for example, pyridyloxy, pyrazyloxy, pyrimidyloxy, quinolyloxy etc.), an acyloxy ligand (preferably having 2 to 30 carbon atoms, more preferably 2 to 20 carbon atoms, and still more preferably 2 to 10, for example, acetoxy, benzoyloxy etc.), a silyloxy ligand (preferably having 3 to 40 carbon atoms, more preferably 3 to 30 carbon atoms, and still more preferably 3 to 24 carbon atoms, for example, trimethylsilyloxy, triphenylsilyloxy etc.), a carbonyl ligand (for example, a ketone ligand, an ester ligand, an amido ligand etc.), an ether ligand (for example, a dialkylether ligand, a diarylether ligand, a furylether ligand etc.) etc. These ligands may further be substituted.

L¹¹, L¹², L¹³ and L¹⁴ coordinated via a sulfur atom to M¹¹ are not particularly limited and each independently represent an alkylthio ligand (preferably having 1 to 30 carbon atoms, more preferably 1 to 20 carbon atoms, and still more preferably 1 to 12, for example, methylthio, ethylthio etc.), an arylthio ligand (preferably having 6 to 30 carbon atoms, more preferably 6 to 20 carbon atoms, and still more preferably 6 to 12 carbon atoms, for example, phenylthio etc.), a heterocyclic thio ligand (preferably having 1 to 30 carbon atoms, more preferably 1 to 20 carbon atoms, and still more preferably 1 to 12 carbon atoms, for example, pyridylthio, 2-benzimidazolylthio, 2-benzoxazolylthio, 2-benzothiazolylthio etc.), a thiocarbonyl ligand (for example, a thioketone ligand, a thioester ligand etc.), and a thioether ligand (for example, a dialkylthioether ligand, a diarylthioether ligand, a thiofuryl ligand etc.). These ligands may further be substituted.

L¹¹, L¹², L¹³ and L¹⁴ coordinated via a phosphorus atom to M¹¹ are not particularly limited and each independently represent a dialkylphosphino ligand, a diarylphosphino ligand, a trialkylphosphine ligand, a triarylphosphine ligand, a phosphinine ligand etc. These ligands may further be substituted.

L¹¹ and L¹⁴ each independently represent preferably an aromatic hydrocarbon ring ligand, an alkyloxy ligand, an aryloxy ligand, an ether ligand, an alkylthio ligand, an arylthio ligand, an alkylamino ligand, an arylamino ligand, an acylamino ligand, a nitrogen-containing heterocyclic ligand (for example, a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, an oxadiazole ligand, a thiadiazole ligand or a condensed ligand containing the same (for example, a quinoline ligand, a quinoxaline ligand, a phthalazine ligand, a benzoxazole ligand, a benzimidazole ligand etc.), or tautomers thereof), more preferably an aromatic hydrocarbon ring ligand, an aryloxy ligand, an arylthio ligand, an arylamino ligand, a pyridine ligand, a pyrazine ligand, a pyrazole ligand, an imidazole ligand or a condensed ligand containing, the same (for example, a quinoline ligand, a quinoxaline ligand, a phthalazine ligand, a benzimidazole ligand etc.), or tautomers thereof, still more preferably an aromatic hydrocarbon ring ligand, an aryloxy ligand, an arylthio ligand, an arylamino ligand, a pyridine ligand, a pyrazine ligand, a pyrazole ligand, an imidazole ligand or a condensed ligand containing the same, further more preferably an aromatic hydrocarbon ring ligand, an aryloxy ligand, a pyridine ligand, a pyrazine ligand, a pyrazole ligand, an imidazole ligand or a condensed ligand containing the same.

Each of L¹² and L¹³ is independently preferably a ligand forming a coordinate bond with M¹¹, and the ligand forming a coordinate bond with M¹¹ is preferably a pyridine ring, a pyrazine ring, a pyrimidine ring, a triazine ring, a thiazole ring, an oxazole ring, a pyrrole ring, a triazole ring or a condensed ligand containing the same (for example, a quinoline ring, a quinoxaline ligand, a phthalazine ligand, a benzoxazole ring, a benzimidazole ring, an indolenine ring etc.), and tautomers thereof, still more preferably a pyridine ring, a pyrazine ring, a pyrimidine ring, a pyrrole ring or a condensed ligand containing the same (for example, a quinoline ring, a quinoxaline ring, a phthalazine ring, an indole ring etc.), and tautomers thereof, further more preferably a pyridine ring, a pyrazine ring, a pyrimidine ring or a condensed ligand containing the same (for example, a quinoline ring etc.), and even more preferably a pyridine ring or a condensed ligand containing a pyridine ring (for example, a quinoline ring etc.).

In the formula (1), L¹⁵ represents a ligand coordinated to M¹¹. L¹⁵ is preferably a monodentate to tetradentate ligand, more preferably a monodentate to tetradentate anionic ligand. The monodentate to tetradentate anionic ligand is not particularly limited, but is preferably a halogen ligand, a 1,3-diketone ligand (for example, an acetylacetone ligand etc.), a pyridine ligand-containing monoanionic bidentate ligand (for example, a picolinic acid ligand, a 2-(2-hydroxyphenyl)-pyridine ligand etc.), or a tetradentate ligand formed by L¹¹, Y¹², L¹², Y¹¹, L¹³, Y¹³ or L¹⁴, more preferably a 1,3-diketone ligand (for example, an acetylacetone ligand etc.), a pyridine ligand-containing monoanionic bidentate ligand (for example, a picolinic acid ligand, a 2-(2-hydroxyphenyl)-pyridine ligand etc.), or a tetradentate ligand formed by L¹¹, Y¹², L¹², Y¹¹, L¹³, Y¹³ or L¹⁴, still more preferably a 1,3-diketone ligand (for example, an acetylacetone ligand etc.) or a pyridine ligand-containing monoanionic bidentate ligand (for example, a picolinic acid ligand, a 2-(2-hydroxyphenyl)-pyridine ligand etc.), further more preferably a 1,3-diketone ligand (for example, an acetylacetone ligand etc.). The number of coordination positions and the number of ligands are not higher than the coordination number of the metal. However, L¹⁵ does not bond to both L¹¹ and L¹⁴ to form a cyclic ligand.

In the formula (1), Y¹¹, Y¹² and Y¹³ each independently represent a linking group, a single bond or a double bond. The liking group is not particularly limited, but is preferably a linking group constituted for example of an atom selected from a carbon atom, a nitrogen atom, an oxygen atom, a sulfur atom, a silicon atom and a phosphorus atom. Specific examples of the linking group include, for example, the following groups:

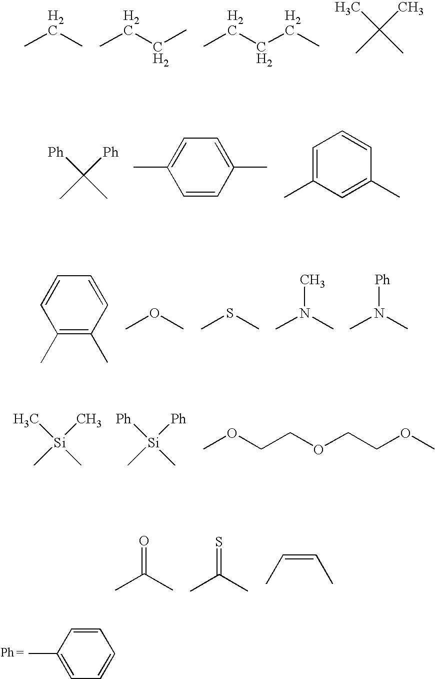

When Y¹¹, Y¹² or Y¹³ is a linking group, a bond between L¹¹ and Y¹², Y¹² and L¹², L¹² and Y¹¹, Y¹¹ and L¹³, L¹³ and Y¹³, or Y¹³ and L¹⁴ independently represent a single bond or a double bond.

Y¹¹, Y¹² or Y¹³ is independently preferably a single bond, a double bond, a carbonyl linking group, an alkylene linking group, an alkenylene group or an amino linking group. Y¹¹ is more preferably a single bond, an alkylene linking group or an amino linking group, even more preferably an alkylene linking group. Y¹² or Y¹³ is more preferably a single bond or an alkenylene group, even more preferably a single bond.

The ring formed by Y¹², Y¹¹, L¹² and M¹¹, the ring formed by Y¹¹, L¹², L¹³ and M¹¹, or the ring formed by Y¹³, L¹³, L¹⁴ and M¹¹ is preferably a 4- to 10-membered ring, more preferably a 5- to 7-membered ring, still more preferably a 5- or 6-membered ring.

In the formula (1), n¹¹ represents 0 to 4. When M¹¹ is a metal having a coordination number of 4, n¹¹ is 0, and when M¹¹ is a metal having a coordination number of 6, n¹¹ is preferably 1 or 2, more preferably 1. When M¹¹ has a coordination number of 6 and n¹¹ is 1, L¹⁵ represents a bidentate ligand, and when M¹¹ has a coordination number of 6 and n¹¹ is 2, L¹⁵ represents a monodentate ligand. When M¹¹ is a metal having a coordination number of 8, n¹¹ is preferably 1 to 4, more preferably 1 or 2, even more preferably 1. When M¹¹ has a coordination number of 8 and n¹¹ is 1, L¹⁵ represents a tetradentate ligand, and when M¹¹ has a coordination number of 8 and n¹¹ is 2, L¹⁵ represents a bidentate ligand. When there are plural n¹¹s, plural L¹⁵ may be the same or different.

The compound represented by the formula (1) is preferably a compound represented by the formula (2).

In the formula (2), Q²¹ and Q²² each independently represent an atomic group forming a nitrogen-containing heterocycle (a ring containing nitrogen coordinated to M²¹). The nitrogen-containing heterocycle formed by Q²¹ or Q²² is not particularly limited, and includes for example a pyridine ring, a pyrazine ring, a pyrimidine ring, a pyridazine ring, a triazine ring, a pyrazole ring, an imidazole ring, a thiazole ring, an oxazole ring, a pyrrole ring, a triazole ring or a condensed ring containing the same (for example, a quinoline ring, a quinoxaline ring, a phthalazine ring, an indole ring, a benzoxazole ring, a benzimidazole ring, an indolenine ring etc.) and tautomers thereof.

The nitrogen-containing heterocycle formed by Q²¹ or Q²² is preferably a pyridine ring, a pyrazine ring, a pyrimidine ring, a pyridazine ring, a triazine ring, a pyrazole ring, an imidazole ring, an oxazole ring, a pyrrole ring or a condensed ring containing the same (for example, a quinoline ring, a quinoxaline ring, a phthalazine ring, an indole ring, a benzoxazole ring, a benzimidazole ring etc.) and tautomers thereof, still more preferably a pyridine ring, a pyrazine ring, a pyrimidine ring, an imidazole ring, a pyrrole ring or a condensed ring containing the same (for example, a quinoline ligand etc.) and tautomers thereof, further more preferably a pyridine ring or a condensed ring thereof (for example, a quinoline ring etc.), even more preferably a pyridine ring.

X²¹ and X²² each independently represent an oxygen atom, a sulfur atom, a substituted or unsubstituted nitrogen atom, more preferably an oxygen atom, a sulfur atom or a substituted nitrogen atom, still more preferably an oxygen atom or a sulfur atom, further more preferably an oxygen atom.

Y²¹ has the same meaning as defined in Y¹¹ in the formula (1), and its preferable scope is also the same as defined therein.

Y²² and Y²³ each independently represent a single bond or a linking group, preferably a single bond. The linking group is not particularly limited, and examples of the linking group include a carbonyl linking group, a thiocarbonyl linking group, an alkylene group, an alkenylene group, an arylene group, a heteroarylene group, an oxygen atom linking group, a nitrogen atom linking group, a sulfur atom linking group and a linking group consisting of a combination thereof.

The linking group represented by Y²² or Y²³ is preferably a carboxyl linking group, an alkylene linking group or an alkenylene linking group, more preferably a carbonyl linking group or an alkenylene linking group, even more preferably a carbonyl linking group.

R²¹, R²², R²³ and R²⁴ each independently represent a hydrogen atom or a substituent. The substituent is not particularly limited, and examples of the substituent include an alkyl group (preferably having 1 to 30 carbon atoms, more preferably 1 to 20 carbon atoms, and still more preferably 1 to 10, for example, methyl, ethyl, iso-propyl, tert-butyl, n-octyl, n-decyl, n-hexadecyl, cyclopropyl, cyclopentyl, and cyclohexyl), an alkenyl group (preferably having 2 to 30 carbon atoms, more preferably 2 to 20 carbon atoms, and still more preferably 2 to 10 carbon atoms, for example, vinyl, allyl, 2-butenyl, and 3-pentenyl), an alkynyl group (preferably having 2 to 30 carbon atoms, more preferably 2 to 20 carbon atoms, and still more preferably 2 to 10 carbon atoms, for example, propargyl and 3-pentynyl), an aryl group (preferably having 6 to 30 carbon atoms, more, preferably 6 to 20 carbon atoms, and still more preferably 6 to 12 carbon atoms, for example, phenyl, p-methylphenyl, naphthyl and anthranyl), an amino group (preferably having 0 to 30 carbon atoms, more preferably 0 to 20 carbon atoms, and still more preferably 0 to 10 carbon atoms, for example, amino, methylamino, dimethylamino, diethylamino, dibenzylamino, diphenylamino, and ditolylamino),

an alkoxy group (preferably having 1 to 30 carbon atoms, more preferably 1 to 20 carbon atoms, and still more preferably 1 to 10 carbon atoms, for example, methoxy, ethoxy, butoxy, and 2-ethylhexyloxy), an aryloxy group (preferably having 6 to 30 carbon atoms, more preferably 6 to 20 carbon atoms, and still more preferably 6 to 12 carbon atoms, for example, phenyloxy, 1-naphthyloxy, and 2-naphthyloxy), a heterocyclic oxy group (preferably having 1 to 30 carbon atoms, more preferably 1 to 20 carbon atoms, and still more preferably 1 to 12 carbon atoms, for example, pyridyloxy, pyrazyloxy, pyrimidinyloxy, and quinolyloxy), an acyl group (preferably having 1 to 30 carbon atoms, more preferably 1 to 20 carbon atoms, and still more preferably 1 to 12 carbon atoms, for example, acetyl, benzoyl, formyl, and pivaloyl), an alkoxycarbonyl group (preferably having 2 to 30 carbon atoms, more preferably 2 to 20 carbon atoms, and still more preferably 2 to 12 carbon atoms, for example, methoxycarbonyl and ethoxycarbonyl), an aryloxycarbonyl group (preferably having 7 to 30 carbon atoms, more preferably 7 to 20 carbon atoms, and still more preferably 7 to 12 carbon atoms, for example, phenyloxycarbonyl),

an acyloxy group (preferably having 2 to 30 carbon atoms, more preferably 2 to 20 carbon atoms, and still more preferably 2 to 10 carbon atoms, for example, acetoxy and benzoyloxy), an acylamino group (preferably having 2 to 30 carbon atoms, more preferably 2 to 20 carbon atoms, and still more preferably 2 to 10 carbon atoms, for example, acetylamino and benzoylamino), an alkoxycarbonylamino group (preferably having 2 to 30 carbon atoms, more preferably 2 to 20 carbon atoms, and still more preferably 2 to 12 carbon atoms, for example, methoxycarbonylamino), an aryloxycarbonylamino group (preferably having 7 to 30 carbon atoms, more preferably 7 to 20 carbon atoms, and still more preferably 7 to 12 carbon atoms, for example, phenyloxycarbonylamino), a sulfonylamino group (preferably having 1 to 30 carbon atoms, more preferably 1 to 20 carbon atoms, and still more preferably 1 to 12 carbon atoms, for example, methanesulfonylamino and benzenesulfonylamino), a sulfamoyl group (preferably having 0 to 30 carbon atoms, more preferably 0 to 20 carbon atoms, and still more preferably 0 to 12 carbon atoms, for example, sulfamoyl, methylsulfamoyl, dimethylsulfamoyl, and phenylsulfamoyl),

a carbamoyl group (preferably having 1 to 30 carbon atoms, more preferably 1 to 20 carbon atoms, and still more preferably 1 to 12 carbon atoms, for example, carbamoyl, methylcarbamoyl, diethylcarbamoyl, and phenylcarbamoyl), an alkylthio group (preferably having 1 to 30 carbon atoms, more preferably 1 to 20 carbon atoms, and still more preferably 1 to 12 carbon atoms, for example, methylthio and ethylthio), an arylthio group (preferably having 6 to 30 carbon atoms, more preferably 6 to 20 carbon atoms, and still more preferably 6 to 12 carbon atoms, for example, phenylthio), a heterocyclic thio group (preferably having 1 to 30 carbon atoms, more preferably 1 to 20 carbon atoms, and still more preferably 1 to 12 carbon atoms, for example, pyridylthio, 2-benzimidazolylthio, 2-benzoxazolylthio and 2-benzothiazolylthio), a sulfonyl group (preferably having 1 to 30 carbon atoms, more preferably 1 to 20 carbon atoms, and still more preferably 1 to 12 carbon atoms, for example, mesyl and tosyl), a sulfinyl group (preferably having 1 to 30 carbon atoms, more preferably 1 to 20 carbon atoms, and still more preferably 1 to 12 carbon atoms, for example, methanesulfinyl and benzenesulfinyl), an ureido group (preferably having 1 to 30 carbon atoms, more preferably 1 to 20 carbon atoms, and still more preferably 1 to 12 carbon atoms, for example, ureido, methylureido, and phenylureido),

a phosphoric amide group (preferably having 1 to 30 carbon atoms, more preferably 1 to 20 carbon atoms, and still more preferably 1 to 12 carbon atoms, for example, diethylphosphoric amide and phenylphosphoric amide), a hydroxy group, a mercapto group, a halogen atom (for example, a fluorine atom, a chlorine atom, a bromine atom, and an iodine atom), a cyano group, a sulfo group, a carboxyl group, a nitro group, a hydroxamic group, a sulfino group, a hydrazino group, an imino group, a heterocyclic group (preferably having 1 to 30 carbon atoms and more preferably 1 to 12 carbon atoms, and having for example a nitrogen atom, an oxygen atom or a sulfur atom as a heteroatom, for example imidazolyl, pyridyl, quinolyl, furyl, thienyl, piperidyl, morpholino, benzoxazolyl, benzimidazolyl, benzthiazolyl, carbazolyl and azepinyl groups), a silyl group (preferably having 3 to 40 carbon atoms, more preferably 3 to 30 carbon atoms, and still more preferably 3 to 24 carbon atoms, for example, trimethylsilyl and triphenylsilyl), and a silyloxy group (preferably having 3 to 40 carbon atoms, more preferably 3 to 30 carbon atoms, and still more preferably 3 to 24 carbon atoms, for example, trimethylsilyloxy and triphenylsilyloxy). Each of these substituents may be further substituted.

R²¹, R²², R²³ and R²⁴ each preferably independently represent an alkyl group or an aryl group, or R²¹ and R²², or R²³ and R²⁴, are preferably groups bonded to each other to form a ring structure (for example, a benzo condensed ring, a pyridine condensed ring or the like). More preferably, R²¹ and R²², or R²³ and R²⁴, are groups bonded to each other to form a ring structure (for example, a benzo condensed ring, a pyridine condensed ring or the like).

L²⁵ has the same meaning as defined in L¹⁵ the formula (1), and its preferable scope is also the same as defined therein.

n²¹ has the same meaning as defined in n¹¹ the formula (1), and its preferable scope is also the same as defined therein.

The compound represented by the formula (2) will be described.

When the ring formed by Q²¹ or Q²² in the formula (2) is a pyridine ring, it is preferable that when Y²¹ is a metal complex representing a linking group, Q²¹ and Q²² each represent a pyridine ring; in the metal complex, Y²¹ is a single bond or a double bond, X²¹ and X²² each represent a sulfur atom or a substituted or unsubstituted nitrogen atom; or in the metal complex, the ring formed by Q²¹ and Q²² is a nitrogen-containing hetero 5-membered ring or a two or more nitrogen atoms-containing 6-membered ring.

A preferable mode of the compound represented by the formula (2) is a compound represented by the following formula (1-A):

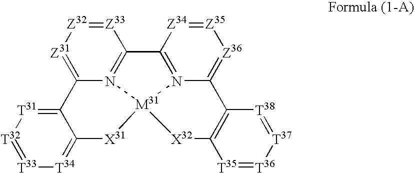

The formula (1-A) will be described.

In the formula (1-A), M³¹ is a platinum ion.

Z³¹, Z³², Z³³, Z³⁴, Z³⁵ and Z³⁶ each independently represent a substituted or unsubstituted carbon or nitrogen atom, more preferably a substituted or unsubstituted carbon atom. A substituent on the carbon includes the group described in R²¹ in the formula (1), and Z³¹ and Z³², Z³² and Z³³, Z³³ and Z³⁴, Z³⁴ and Z³⁵, or Z³⁵ and Z³⁶ may be bonded to each other via a linking group, to form a condensed ring (for example, a benzo condensed ring, a pyridine condensed ring or the like), and Z³¹ and T³¹, or Z³⁶ and T³⁸, may be bonded to each other via a linking group, to form a condensed ring (for example, a benzo condensed ring, a pyridine condensed ring or the like).

A substituent on the carbon is preferably an alkyl group, an alkoxy group, an alkylamino group, an aryl group, a group forming a condensed ring (for example, a benzo condensed ring, a pyridine condensed ring or the like), or a halogen atom, more preferably an alkylamino group, an aryl group, or a group forming a condensed ring (for example, a benzo condensed ring, a pyridine condensed ring or the like), still more preferably an aryl group or a group forming a condensed ring (for example, a benzo condensed ring, a pyridine condensed ring or the like), further more preferably a group forming a condensed ring (for example, a benzo condensed ring, a pyridine condensed ring or the like).

T³¹, T³², T³³, T³⁴, T³⁵, T³⁶, T³⁷ and T³⁸ each independently represent a substituted or unsubstituted carbon or nitrogen atom, more preferably a substituted or unsubstituted carbon atom. A substituent on the carbon includes the group described in R²¹ in the formula (1), and T³¹ and T³², T³² and T³³, T³³ and T³⁴, T³⁵ and T³⁶, T³⁶ and T³⁷ or T³⁷ and T³⁸ may be bonded to each other via a linking group, to form a condensed ring (for example, a benzo condensed ring, a pyridine condensed ring or the like).

A substituent on the carbon is preferably an alkyl group, an alkoxy group, an alkylamino group, an aryl group, a group forming a condensed ring (for example, a benzo condensed ring, a pyridine condensed ring or the like), or a halogen atom, more preferably an aryl group, a group forming a condensed ring (for example, a benzo condensed ring, a pyridine condensed ring or the like), or a halogen atom, still more preferably an aryl group or a halogen atom, further more preferably an aryl group.

X³¹ and X³² each independently have the same meaning as defined in X²¹ and X²² in the formula (2), and their preferable scope is also the same as defined therein.

Preferable another mode of the compound represented by the formula (1) is a compound represented by the following formula (15-2):

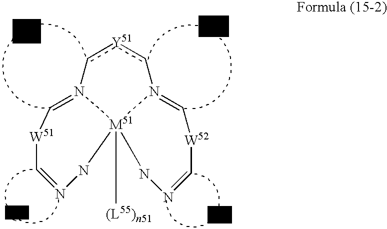

In the formula (15-2), M⁵¹ is a platinum ion.

Q⁵¹ and Q⁵² independently have the same meaning as defined in Q²¹ and Q²² in the formula (2) and their preferable scope is also the same as defined above.

Q⁵³ and Q⁵⁴ each independently represent a group forming a nitrogen-containing heterocycle (a ring containing nitrogen coordinated to M⁵¹). The nitrogen-containing heterocycle formed by Q⁵³ or Q⁵⁴ is not particularly limited, and preferable examples include tautomers of pyrrole derivatives (for example, a 5-membered heterocyclic ligand of exemplary compound (24) shown in Chemical Number No. 24, a terminal 5-membered heterocyclic ligand of exemplary compound (64) shown in Chemical Number No. 28 and a 5-membered heterocyclic ligand of exemplary compound (145) shown in Chemical Number No. 37 in JP-A 2007-103493, etc.), tautomers of imidazole derivatives (for example, a 5-membered heterocyclic ligand of exemplary compound (29) shown in Chemical Number No. 24 in JP-A 2007-103493, etc.), tautomers of thiazole derivatives (for example, a 5-membered heterocyclic ligand of exemplary compound (30) shown in Chemical Number No. 24 in JP-A 2007-103493, etc.) and tautomers of oxazole derivatives (for example, a 5-membered heterocyclic ligand of exemplary compound (31) shown in Chemical Number No. 24 in JP-A 2007-103493, etc.), more preferably tautomers of pyrrole derivatives, tautomers of imidazole derivatives and tautomers of thiazole derivatives, still more preferably tautomers of pyrrole derivatives and tautomers of imidazole derivatives, further more preferably tautomers of pyrrole derivatives.

Y⁵¹ has the same meaning as defined in Y¹¹ in the formula (1), and its preferable scope is also the same as defined therein.

L⁵⁵ has the same meaning as defined in L¹⁵ in the formula (1), and its preferable scope is also the same as defined therein.

n⁵¹ has the same meaning as defined above in n¹¹, and its preferable scope is also the same as defined therein.

W⁵¹ and W⁵² each independently represent a substituted or unsubstituted carbon or nitrogen atom, more preferably an unsubstituted carbon or nitrogen atom, more preferably an unsubstituted carbon atom.

Preferable another mode of the compound represented by the formula (1) is a compound represented by the following formula (15-3):

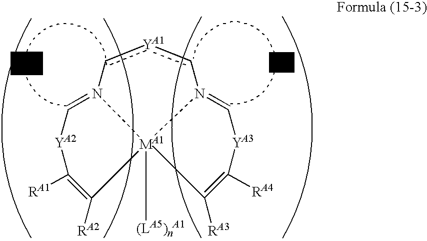

M^{A1}, Q^{A1}, Q^{A2}, Y^{A1}, Y^{A2}, Y^{A3}, R^{A1}, R^{A2}, R^{A3}, R^{A4}, L^{A5} and n^{A1} in the formula (15-3) have the same meanings as defined in M²¹, Q²¹, Q²², Y²¹, Y²², Y²³, R²¹, R²², R²³, R²⁴, L²⁵ and n²¹ in the formula (1), and their preferable scope is also the same as defined therein.

Preferable another mode of the compound represented by the formula (15-3) is a compound represented by the following formula (3-B):

The compound of the formula (3-B) will be described.

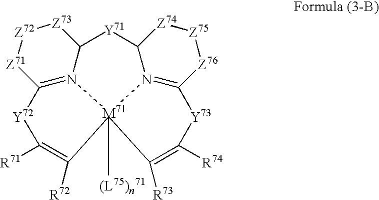

In the formula (3-B), M⁷¹ is a platinum ion.

Y⁷¹, Y⁷² and Y⁷³ each have the same meaning as defined in Y²¹, Y²² and Y²³ in the formula (2), and their preferable scope is also the same as defined above.

L⁷⁵ has the same meaning as defined in L¹⁵ in the formula (1), and its preferable scope is also the same as defined therein.

n⁷¹ has the same meaning as defined in n¹¹ in the formula (1), and its preferable scope is also the same as defined therein.

Z⁷¹, Z⁷², Z⁷³, Z⁷⁴, Z⁷⁵ and Z⁷⁶ each independently represent a substituted or unsubstituted carbon or nitrogen atom, preferably a substituted or unsubstituted carbon atom. A substituent on the carbon includes the group described in R²¹ in the formula (2). R⁷¹ and R⁷², or R⁷³ and R⁷⁴, are bonded to each other via a linking group, to form a ring (for example, a benzene ring, a pyridine ring). R⁷¹ to R⁷⁴ have the same meanings as defined in the substituents R²¹ to R²⁴ in the formula (2), and their preferable range is also the same as defined therein.

Preferable another mode of the compound represented by the formula (3-B) is a compound represented by the following formula (3-C):

The compound of the formula (3-C) will be described.

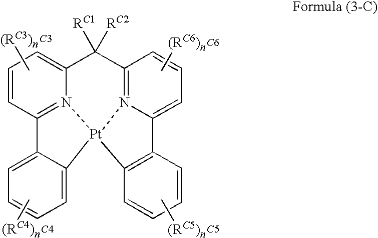

In the formula (3-C), R^{C1} and R^{C2} each independently represent a hydrogen atom or a substituent group, and the substituent represents the alkyl group, aryl group and heterocyclic group described as the substituents R²¹ to R²⁴ in the formula (2) (These may be further substituted. The substituent in this case includes the group mentioned as the substituent represented by R²¹ in the formula (2) can be used) and a halogen atom. The substituent represented by R^{C3}, R^{C4}, R^{C5} or R^{C6} also has the same meaning as the substituents R²¹ to R²⁴ in the formula (2). When n^{C3} and n^{C6} each represent an integer of 0 to 3, n^{C4} and n^{C5} each represent an integer of 0 to 4, and when there are plural R^{C3}, R^{C4}, R^{C5} and R^{C6}, plural R^{C3}, R^{C4}, R^{C5} and R^{C6} may be the same or different and may be bonded to form a ring. R^{C3}, R^{C4}, R^{C5} and R^{C6} are preferably an alkyl group, an aryl group, a heteroaryl group, a cyano group and a halogen atom.

Preferable another mode of the compound represented by the formula (1) is a compound represented by the following formula (15-4):

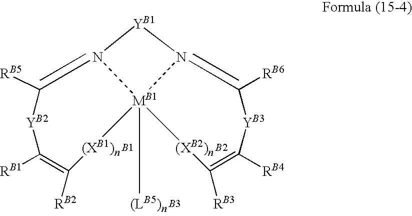

M^{B1}, Y^{B2}, Y^{B3}, R^{B1}, R^{B2}, R^{B3}, R^{B4}, L^{B5}, n^{B3}, X^{B1} and X^{B2} in the formula (15-4) have the same meanings as defined in M²¹, Y²², Y²³, R²¹, R²², R²³, R²⁴, L²⁵, n²¹, X²¹ and X²² in the formula (2), and their preferable scope is the same as defined therein.

Y^{B1} represents a linking group, has the same meaning as in Y²¹ in the formula (2), and preferably represents a vinyl group substituted at position 1 or 2, a phenylene ring substituted at position 1 or 2, a pyridine ring substituted at position 1 or 2, a pyrazine ring substituted at position 1 or 2, a pyrimidine ring substituted at position 1 or 2 or an alkylene group having 2 to 8 carbon atoms substituted at position 1 or 2.

R^{B5} and R^{B6} each independently represent a hydrogen atom or a substituent, and the substituent represents an alkyl group, aryl group and heterocyclic group described as the substituents R²¹ to R²⁴ in the formula (2). However, Y^{B1} is not linked to R^{B5} or R^{B6}. n^{B1} and n^{B2} each independently represent an integer of 0 to 1.

Preferable another mode of the compound represented by the formula (15-4) is a compound represented by the following formula (4-A).

The compound of the formula (4-A) will be described.

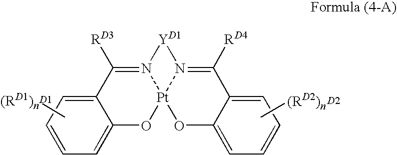

In the formula (4-A), R^{D3} and R^{D4} each independently represent a hydrogen atom or a substituent, R^{D1} and R^{D2} each represent a substituent. The substituent represented by R^{D1}, R^{D2}, R^{D3} or R^{D4} has the same meaning as defined in R^{B5} or R^{B6} in the formula (15-4), and their preferable scope is also the same as defined therein. n^{D1} and n^{D2} each represent an integer of 0 to 4, and there are plural R^{D1} and R^{D2}, the plural R^{D1} and R^{D2} may be the same or different and may be linked to form a ring. Y^{D1} represents a vinyl group substituted at position 1 or 2, a phenylene ring substituted at position 1 or 2, a pyridine ring substituted at position 1 or 2, a pyrazine ring substituted at position 1 or 2, a pyrimidine ring substituted at position 1 or 2, or an alkylene group having 1 to 8 carbon atoms substituted at position 1 or 2.

Preferable another mode of the compound represented by the formula (1) is a compound represented by the following formula (15-5):

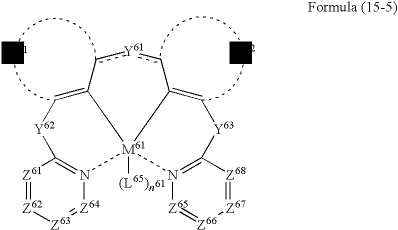

In the formula (15-5), M⁶¹ is a platinum ion.

Q⁶¹ and Q⁶² each independently represent a ring-forming group. The ring formed by Q⁶¹ or Q⁶² is not particularly limited and includes, for example, a benzene ring, a pyridine ring, a pyridazine ring, a pyrimidine ring, a thiophene ring, an isothiazole ring, a furan ring, an isoxazole ring and a condensed ring thereof.

The ring formed by Q⁶¹ or Q⁶² is preferably a benzene ring, a pyridine ring, a thiophene ring, a thiazole ring or a condensed ring thereof, more preferably a benzene ring, a pyridine ring or a condensed ring thereof, more preferably a benzene ring or its condensed ring.

Y⁶¹ has the same meaning as defined in Y¹¹ in the formula (1), and its preferable scope is also the same as defined therein.

Y⁶² and Y⁶³ each independently represent a linking group or a single bond. The linking group is not particularly limited, and examples of such linking group include a carbonyl linking group, a thiocarbonyl linking group, an alkylene group, an alkenylene group, an arylene group, a heteroarylene group, an oxygen atom linking group, a nitrogen atom linking group, and a linking group consisting of a combination thereof.

Y⁶² and Y⁶³ is independently preferably a single bond, a carbonyl linking group, an alkylene linking group or an alkenylene group, more preferably a single bond or an alkenylene group, still more preferably a single bond.

L⁶⁵ has the same meaning as defined in L¹⁵ in the formula (1), and its preferable scope is also the same as defined therein.

n⁶¹ has the same meaning as defined in n¹¹ in the formula (2), and its preferable scope is also the same as defined therein.

Z⁶¹, Z⁶², Z⁶³, Z⁶⁴, Z⁶⁵, Z⁶⁶, Z⁶⁷ or Z⁶⁸ each independently represent a substituted or unsubstituted carbon or nitrogen atom, preferably a substituted or unsubstituted carbon atom. A substituent on the carbon includes the group described in R²¹ in the formula (15), and Z⁶¹ and Z⁶², Z⁶² and Z⁶³, Z⁶³ and Z⁶⁴, Z⁶⁵ and Z⁶⁶, Z⁶⁶ and Z⁶⁷, or Z⁶⁷ and Z⁶⁸ may be bonded to each other via a linking group, to form a condensed ring (for example, a benzo condensed ring, a pyridine condensed ring etc.). The ring formed by Q⁶¹ or Q⁶² may be bonded via a linking group to Z⁶¹ or Z⁶⁸, to form a ring.

A substituent on the carbon is preferably an alkyl group, an alkoxy group, an alkylamino group, an aryl group, a group forming a condensed ring (for example, a benzo condensed ring, a pyridine condensed ring or the like), or a halogen atom, more preferably an alkylamino group, an aryl group or a group forming a condensed ring (for example, a benzo condensed ring, a pyridine condensed ring or the like), still more preferably an aryl group or a group forming a condensed ring (for example, a benzo condensed ring, a pyridine condensed ring or the like), further more preferably a group forming a condensed ring (for example, a benzo condensed ring, a pyridine condensed ring or the like).

The luminescence material of the invention is preferably a platinum complex of a tetradentate ligand containing a partial structure represented by the formula (3):

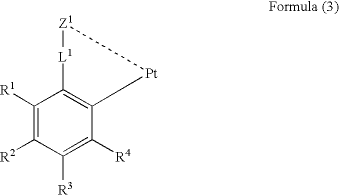

In the formula (3), Z¹ represents a nitrogen-containing heterocycle coordinated via a nitrogen atom to platinum. L¹ represents a single bond or a linking group. R¹, R³ and R⁴ each represent a hydrogen atom or a substituent, and R² represents a substituent.

Z¹ represents a nitrogen-containing heterocycle coordinated via a nitrogen atom to platinum. Z¹ includes, for example, a pyridine ring, a pyrazine ring, a pyrimidine ring, a pyridazine ring, a triazine ring, a pyrazole ring, an imidazole ring, an oxazole ring, a thiazole ring, a triazole ring, an oxadiazole ring, a thiadiazole ring, their benzo condensed ring and pyrido condensed ring, preferably a pyridine ring, a pyrazine ring, a pyrimidine ring, a pyrazole ring or a triazole ring, more preferably a pyridine ring, a pyrazine ring or a pyrimidine ring, even more preferably a pyridine ring. These may have a substituent, and the substituent may be the substituent mentioned as L¹ described later.

L¹ represents a single bond or a linking group. The linking group is not particularly limited, but is preferably a linking group consisting of a carbon atom, a nitrogen atom, an oxygen atom, a sulfur atom or a silicon atom and includes, but is not limited to, the following examples.

Liking Groups

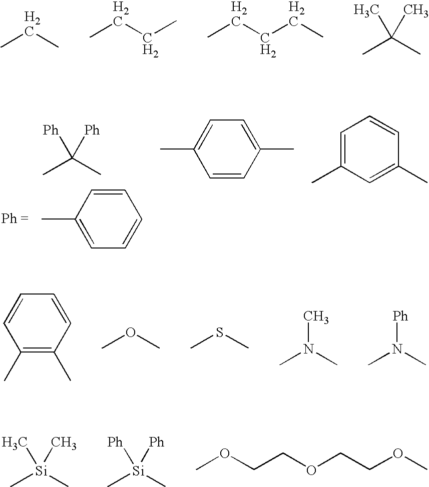

These linking groups may if possible have a substituent, and the introducible substituent includes an alkyl group (preferably having 1 to 30 carbon atoms, more preferably 1 to 20 carbon atoms, and still more preferably 1 to 10 carbon atoms, for example, methyl, ethyl, iso-propyl, tert-butyl, n-octyl, n-decyl, n-hexadecyl, cyclopropyl, cyclopentyl, and cyclohexyl), an alkenyl group (preferably having 2 to 30 carbon atoms, more preferably 2 to 20 carbon atoms, and still more preferably 2 to 10 carbon atoms, for example, vinyl, allyl, 2-butenyl, and 3-pentenyl), an alkynyl group (preferably having 2 to 30 carbon atoms, more preferably 2 to 20 carbon atoms, and still more preferably 2 to 10 carbon atoms, for example, propargyl and 3-pentynyl), an aryl group (preferably having 6 to 30 carbon atoms, more preferably 6 to 20 carbon atoms, and still more preferably 6 to 12 carbon atoms, for example, phenyl, p-methylphenyl, naphthyl and anthranyl), an amino group (preferably having 0 to 30 carbon atoms, more preferably 0 to 20 carbon atoms, and still more preferably 0 to 10 carbon atoms, for example, amino, methylamino, dimethylamino, diethylamino, dibenzylamino, diphenylamino and ditolylamino), an alkoxy group (preferably having 1 to 30 carbon atoms, more preferably 1 to 20 carbon atoms, and still more preferably 1 to 10 carbon atoms, for example, methoxy, ethoxy, butoxy, and 2-ethylhexyloxy), an aryloxy group (having 6 to 30 carbon atoms, more preferably 6 to 20 carbon atoms, and still more preferably 6 to 12 carbon atoms, for example, phenyloxy 1-naphthyloxy, and 2-naphthyloxy),

a heterocyclic oxy group (preferably having 1 to 30 carbon atoms, more preferably 1 to 20 carbon atoms, and still more preferably 1 to 12 carbon atoms, for example, pyridyloxy, pyrazyloxy, pyrimidyloxy and quinolyloxy), an acyl group (preferably having 1 to 30 carbon atoms, more preferably 1 to 20 carbon atoms, and still more preferably 1 to 12 carbon atoms, for example, acetyl, benzoyl, formyl, and pivaloyl), an alkoxycarbonyl group (preferably having 2 to 30 carbon atoms, more preferably 2 to 20 carbon atoms, and still more preferably 2 to 12 carbon atoms, for example, methoxycarbonyl and ethoxycarbonyl), an aryloxycarbonyl group (preferably having 7 to 30 carbon atoms, more preferably 7 to 20 carbon atoms, and still more preferably 7 to 12 carbon atoms, for example, phenyloxycarbonyl), an acyloxy group (preferably having 2 to 30 carbon atoms, more preferably 2 to 20 carbon atoms, and still more preferably 2 to 10 carbon atoms, for example, acetoxy and benzoyloxy), an acylamino group (preferably having 2 to 30 carbon atoms, more preferably 2 to 20 carbon atoms, and still more preferably 2 to 10 carbon atoms, for example, acetylamino and benzoylamino), an alkoxycarbonylamino group (preferably having 2 to 30 carbon atoms, more preferably 2 to 20 carbon atoms, and still more preferably 2 to 12 carbon atoms, for example, methoxycarbonylamino), an aryloxycarbonylamino group (preferably having 7 to 30 carbon atoms, more preferably 7 to 20 carbon atoms, and still more preferably 7 to 12 carbon atoms, for example, phenyloxycarbonylamino), a sulfonylamino group (preferably having 1 to 30 carbon atoms, more preferably 1 to 20 carbon atoms, and still more preferably 1 to 12 carbon atoms, for example, methanesulfonylamino and benzenesulfonylamino),

a sulfamoyl group (preferably having 0 to 30 carbon atoms, more preferably 0 to 20 carbon atoms, and still more preferably 0 to 12 carbon atoms, for example, sulfamoyl, methylsulfamoyl, dimethylsulfamoyl, and phenylsulfamoyl), a carbamoyl group (preferably having 1 to 30 carbon atoms, more preferably 1 to 20 carbon atoms, and still more preferably 1 to 12 carbon atoms, for example, carbamoyl, methylcarbamoyl, diethylcarbamoyl, and phenylcarbamoyl), an alkylthio group (preferably having 1 to 30 carbon atoms, more preferably 1 to 20 carbon atoms, and still more preferably 1 to 12 carbon atoms, for example, methylthio and ethylthio), an arylthio group (preferably having 6 to 30 carbon atoms, more preferably 6 to 20 carbon atoms, and still more preferably 6 to 12 carbon atoms, for example, phenylthio), a heterocyclic thio group (preferably having 1 to 30 carbon atoms, more preferably 1 to 20 carbon atoms, and still more preferably 1 to 12 carbon atoms, for example, pyridylthio, 2-benzimidazolylthio, 2-benzoxazolylthio, and 2-benzothiazolylthio), a sulfonyl group (preferably having 1 to 30 carbon atoms, more preferably 1 to 20 carbon atoms, and still more preferably 1 to 12 carbon atoms, for example, mesyl and tosyl), a sulfinyl group (preferably having 1 to 30 carbon atoms, more preferably 1 to 20 carbon atoms, and still more preferably 1 to 12 carbon atoms, for example, methanesulfinyl and benzenesulfinyl),

an ureido group (preferably having 1 to 30 carbon atoms, more preferably 1 to 20 carbon atoms, and still more preferably 1 to 12 carbon atoms, for example, ureido, methylureido, and phenylureido), an phosphoric amide group (preferably having 1 to 30 carbon atoms, more preferably 1 to 20 carbon atoms, and still more preferably 1 to 12 carbon atoms, for example, diethylphosphoric amide and phenylphosphoric amide), a hydroxy group, a mercapto group, a halogen atom (for example, a fluorine atom, a chlorine atom, a bromine atom, and an iodine atom), a cyano group, a sulfo group, a carboxyl group, a nitro group, a hydroxamic group, a sulfino group, a hydrazino group, an imino group, a heterocycle group (preferably having 1 to 30 carbon atoms, more preferably 1 to 12 carbon atoms and having for example a nitrogen atom, an oxygen atom or a sulfur atom as a heteroatom, for example imidazolyl, pyridyl, quinolyl, furyl, thienyl, piperidyl, morpholino, benzoxazolyl, benzimidazolyl, benzthiazolyl, carbazolyl and azepinyl groups), a silyl group (preferably having 3 to 40 carbon atoms, more preferably 3 to 30 carbon atoms, and still more preferably 3 to 24 carbon atoms, for example, trimethylsilyl and triphenylsilyl), and a silyloxy group (preferably having 3 to 40 carbon atoms, more preferably 3 to 30 carbon atoms, and still more preferably 3 to 24 carbon atoms, for example, trimethylsilyloxy and triphenylsilyloxy). Each of these substituents may be further substituted. A substituent on these substituents is preferably an alkyl group, an aryl group, a heterocyclic group, a halogen atom or a silyl group, more preferably an alkyl group, an aryl group, a heterocyclic group or a halogen atom, even more preferably an alkyl group, an aryl group, an aromatic heterocyclic group or a fluorine atom.

L¹ is preferably a single bond, a methylene group, a dimethylmethylene group or a diphenylmethylene group.

R¹, R³ and R⁴ each represent a hydrogen atom or a substituent. When R¹, R³ and R⁴ each represent a substituent, the substituent may be one illustrated as the substituent for the linking group L¹. R¹, R³ or R⁴ is preferably a hydrogen atom, an alkyl group, an aryl group, an amino group, an alkoxy group, an aryloxy group, a heterocyclic oxy group, an acyl group, an alkoxycarbonyl group, an aryloxycarbonyl group, an alkylthio group, an arylthio group, a heterocyclic thio group, a sulfonyl group, a halogen atom, a cyano group, a heterocyclic group, a silyl group or a silyloxy group, more preferably a hydrogen atom, an alkyl group, an aryl group, an amino group, an alkoxy group, an acyl group, an alkylthio group, a sulfonyl group, a halogen atom, a cyano group, a heterocyclic group or a silyl group, still more preferably a hydrogen atom, an alkyl group, an aryl group, an alkoxy group, an acyl group, a sulfonyl group, a fluorine atom, a cyano group, a heterocyclic group or a silyl group, further more preferably a hydrogen atom, an alkyl group, an aryl group, a sulfonyl group, a fluorine atom, a cyano group or a heterocyclic group, even more preferably a hydrogen atom, an alkyl group, an aryl group, a fluorine atom, a cyano group or a heterocyclic group, most preferably a hydrogen atom, an alkyl group, a fluorine atom, a fluoroalkyl group or a cyano group. These substituents may further be substituted with other substituent groups.

R² represents a substituent. The substituent represented by R² may be one illustrated as the substituent represented by R¹, R³ or R⁴. The substituent represented by R² is preferably an alkyl group, an aryl group, an amino group, an alkoxy group, an aryloxy group, a heterocyclic oxy group, an acyl group, an alkoxycarbonyl group, an aryloxycarbonyl group, an alkylthio group, an arylthio group, a heterocyclic thio group, a sulfonyl group, a halogen atom, a cyano group, a heterocyclic group, a silyl group or a silyloxy group, more preferably an alkyl group, an aryl group, an amino group, an alkoxy group, an acyl group, an alkylthio group, a sulfonyl group, a halogen atom, a cyano group, a heterocyclic group or a silyl group, still more preferably an alkyl group, an aryl group, an alkoxy group, an acyl group, a sulfonyl group, a fluorine atom, a cyano group, a heterocyclic group or a silyl group, further more preferably an alkyl group, an aryl group, a sulfonyl group, a fluorine atom, a cyano group or a heterocyclic group, even more preferably an alkyl group, an aryl group, a fluorine atom, a cyano group or a heterocyclic group, most preferably an alkyl group, a fluorine atom, a fluoroalkyl group or a cyano group. These substituents may further be substituted with other substituents.

A platinum complex compound of a tetradentate ligand containing the partial structure represented by the formula (3) is preferably a platinum complex represented by the following formula (4):

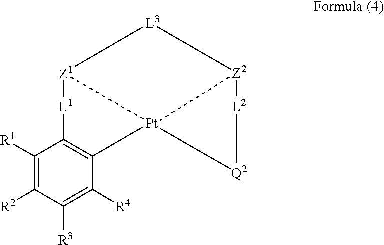

In the formula (4), Z¹ and Z² each represent a nitrogen-containing heterocycle coordinated via a nitrogen atom to platinum. Q² represents a group bonded to platinum via a carbon atom, an oxygen atom, a sulfur atom, a nitrogen atom or a phosphorus atom. L¹, L² and L³ each represent a single bond or a linking group. R¹, R³ and R⁴ each represent a hydrogen atom or a substituent, and R² represents a substituent.

The formula (4) will be described. Z¹ and Z² have the same meaning as defined in Z¹ in the formula (3), and their preferable range is also the same as defined therein. Z¹ and Z² may be the same or different. L¹, L² and L³ have the same meaning defined in L¹ in the formula (3), and their preferable range is also the same as defined therein. L¹, L² and L³ may be the same or different. Q² represents a group bonded to platinum via a carbon atom, an oxygen atom, a sulfur atom, a nitrogen atom or a phosphorus atom.

Q² bonded to platinum via a carbon atom includes, for example, an imino group, an aromatic hydrocarbon group (a phenyl group, a naphthyl group or the like), an aromatic heterocyclic group (a pyridine ring, a pyrazine ring, a pyrimidine ring, a pyridazine group, a triazine ring, a triazole ring, an imidazole ring, a pyrazole ring, a thiophene ring, a furan ring or the like) and condensed rings containing the same. These groups may further be substituted.

Q² bonded to platinum via a nitrogen atom includes, for example, a nitrogen-containing heterocyclic group (a pyrrole ring, a pyrazole ring, an imidazole ring, a triazole ring or the like), an amino group (an alkylamino group, an arylamino group, an acylamino group, an alkoxycarbonylamino group, an aryloxycarbonylamino group, a sulfonylamino group or the like). These groups may further be substituted.

Q² bonded to platinum via an oxygen atom includes, for example, an oxy group, a carbonyloxy group, an alkoxy group, an aryloxy group, a heterocyclic oxy group, an acyloxy group, a silyloxy group etc.

Q² bonded to platinum via a sulfur atom includes, for example, a thio group, an alkylthio group, an arylthio group, a heterocyclic thio group, a carbonylthio group etc.

Q² bonded to platinum via a phosphorus atom includes, for example, a diarylphosphine group.

The group represented by Q² is preferably an aromatic hydrocarbon group bonded via carbon to platinum, an aromatic heterocyclic group bonded via carbon to platinum, a nitrogen-containing heterocyclic group bonded via nitrogen to platinum, an aryloxy group or a carbonyloxy group, more preferably an aromatic hydrocarbon group bonded via carbon to platinum, an aromatic heterocyclic group bonded via carbon to platinum, an aryloxy group or a carbonyloxy group, even more preferably an aromatic hydrocarbon group bonded via carbon to platinum, an aromatic heterocyclic group bonded via carbon to platinum, or a carbonyloxy group. Q² may if possible have a substituent. The substituent may be one illustrated as the substituent for the linking group L¹ in the formula (3).

R¹, R², R³ and R⁴ have the same meanings as defined in the formula (3), and their preferable scope is the same as defined therein.

Another mode of the platinum complex compound of a tetradentate ligand containing the partial structure represented by the formula (3) is a platinum complex represented by the following formula (5):

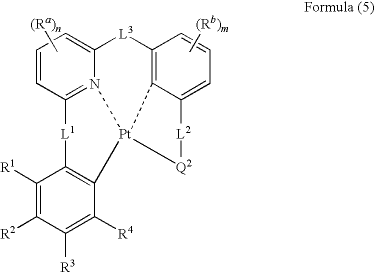

In the formula (5), Q² represents a group bonded to platinum via a carbon atom, an oxygen atom, a sulfur atom, a nitrogen atom or a phosphorus atom. L¹, L² and L³ each represent a single bond or a linking group. R¹, R³ and R⁴ each represent a hydrogen atom or a substituent, and R² represents a substituent. R^{a} and R^{b} each represent a substituent, and n and m each represent an integer of 0 to 3.

The formula (5) will be described. Q², L¹, L², L³, R¹, R², R³ and R⁴ each have the same meanings as defined in the formula (4), and their preferable scope is the same as defined therein. R^{a} and R^{b} each represent a hydrogen atom or a substituent. The substituent may be one illustrated as the substituent L¹. R^{a} or R^{b} is preferably a hydrogen atom, an alkyl group, an aryl group, an amino group, an alkoxy group or a fluorine atom, more preferably an alkyl group or an aryl group, still more preferably an alkyl group. n and m each represent an integer of 0 to 3.

The platinum complex represented by the formula (4) is preferably a platinum complex represented by the formula (6):

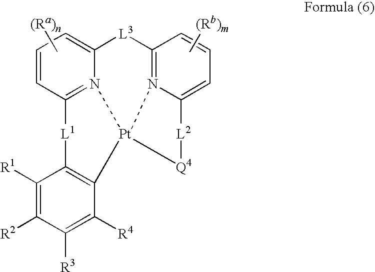

In the formula (6), Q⁴ represents an aromatic hydrocarbon cyclic group or an aromatic heterocyclic group which is bonded to platinum via a carbon atom or a nitrogen atom. L¹, L² and L³ each represent a single bond or a linking group. R¹, R³ and R⁴ each represent a hydrogen atom or a substituent, and R² represents a substituent. R^{a} and R^{b} each represent a substituent, and n and m each represent an integer of 0 to 3.

The formula (6) will be described. L¹, L², L³, R¹, R², R³, R⁴, R^{a}, R^{b}, n and m each have the same meanings as defined in the formula (5), and their preferable scope is the same as defined therein. Q⁴ represents an aromatic hydrocarbon cyclic group or an aromatic heterocyclic group which is bonded to platinum via a carbon atom or a nitrogen atom. Q⁴ bonded via a carbon atom to platinum includes a benzene ring, a pyridine ring, a pyrimidine ring, a pyridazine group, a pyrazine ring, a triazole ring, a pyrazole ring, an imidazole ring, a thiophene ring, a furan ring or their benzo condensed ring and pyrido condensed ring. Q⁴ bonded via a nitrogen atom to platinum includes a pyrrole ring, an imidazole ring, a pyrazole ring, a triazole ring or their benzo condensed ring and pyrido condensed ring. Q⁴ may if possible have a substituent. The substituent may be one illustrated as the substituent for the linking group L¹ in the formula (3).

Among the platinum complexes represented by the formula (6), one preferable mode is a platinum complex represented by the formula (7):

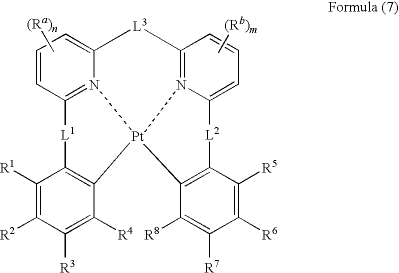

In the formula (7), L¹, L² and L³ each represent a single bond or a linking group. R¹, R³, R⁴, R⁵, R⁷ and R⁸ each represent a hydrogen atom or a substituent, and R² and R⁶ each represent a substituent. R^{a} and R^{b} each represent a substituent, and n and m each represent an integer of 0 to 3.

The formula (7) will be described. L¹, L², L³, R¹, R², R³, R⁴, R^{a}, R^{b}, n and m have the same meanings as defined in the formula (6), and their preferable scope is the same as defined therein. R⁵, R⁶, R⁷ and R⁸ have the same meanings as defined in R¹, R², R³ and R⁴, and their preferable scope is the same as defined therein and may be the same or different.

Hereinafter, specific examples of the platinum complex will be enumerated, but the invention is not limited to these compounds.

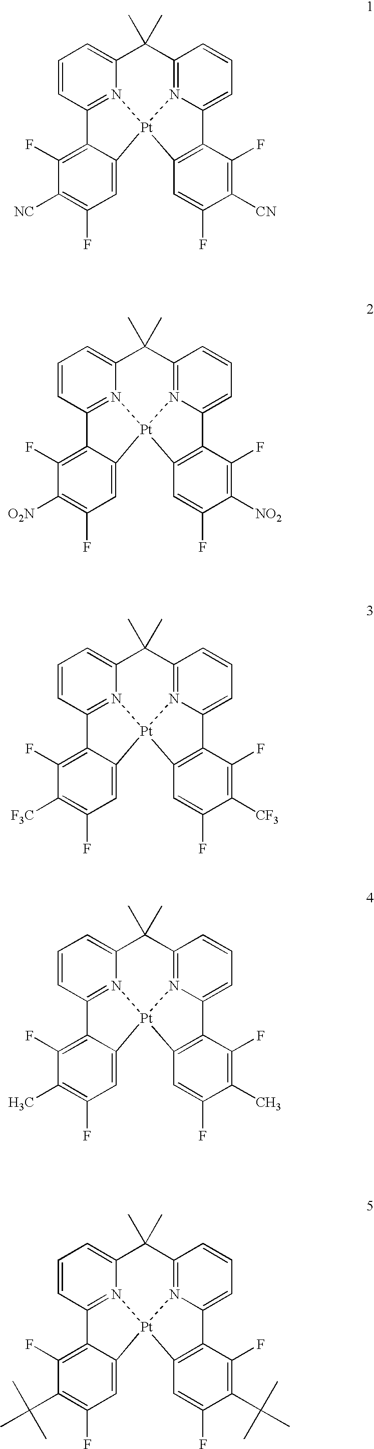

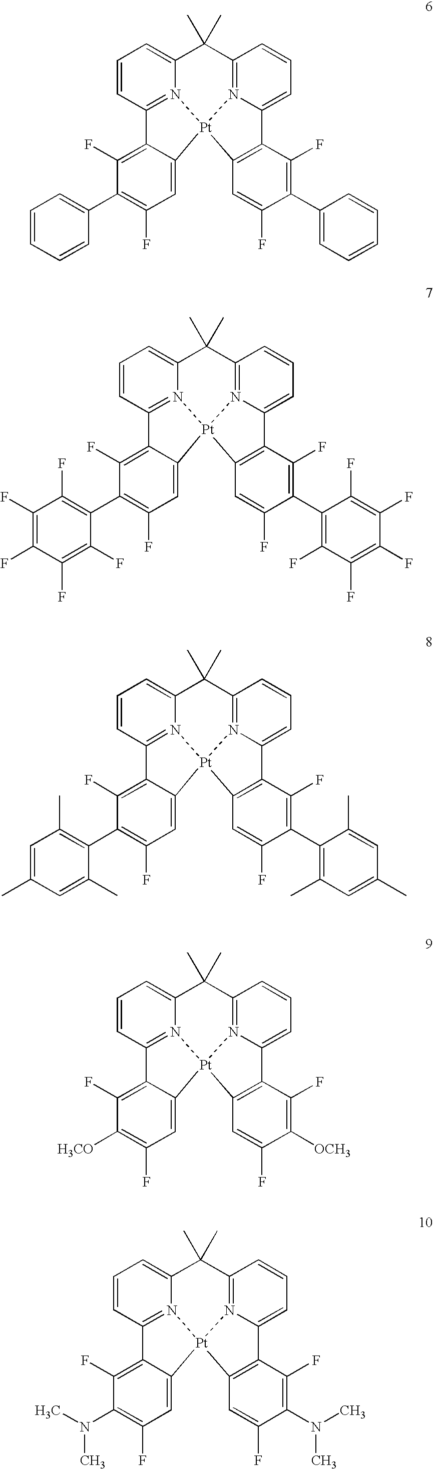

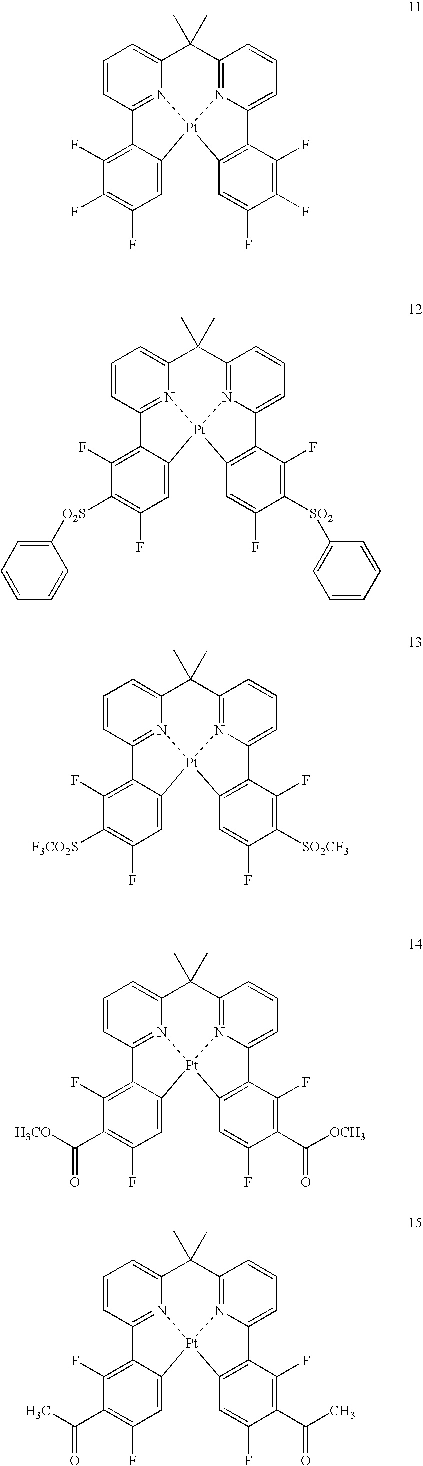

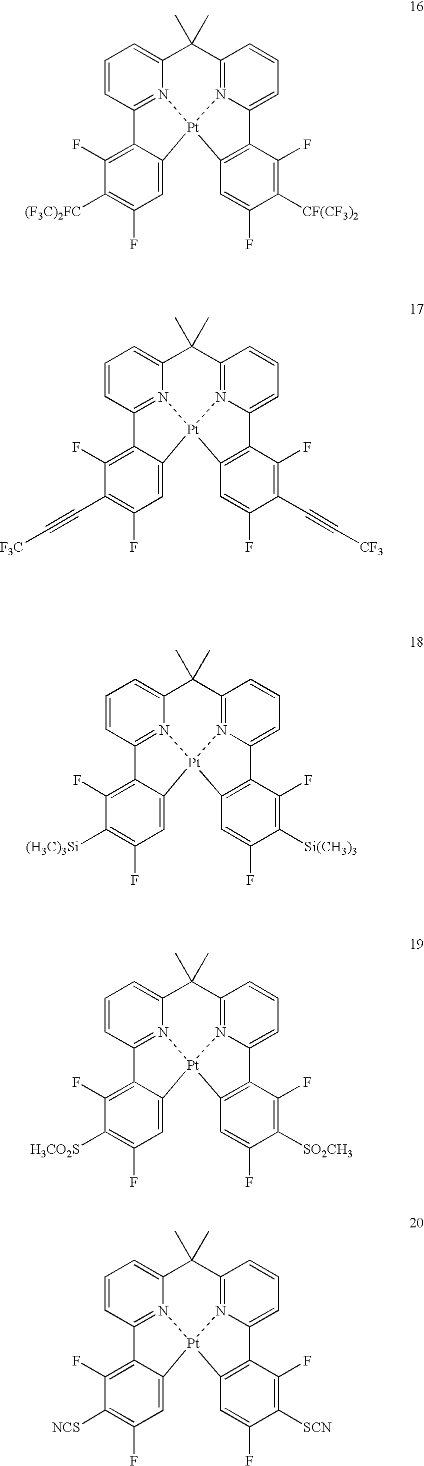

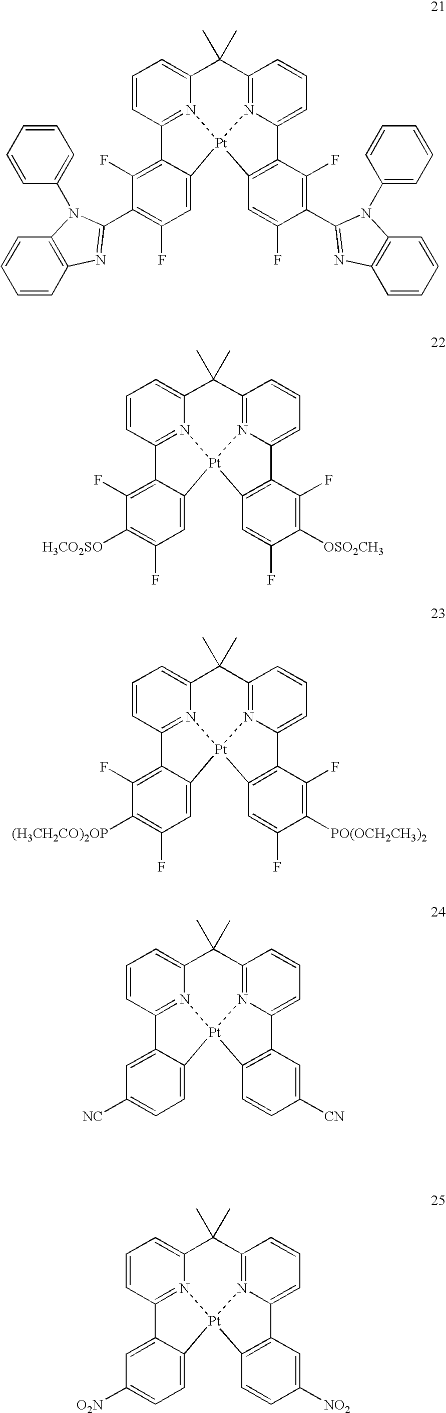

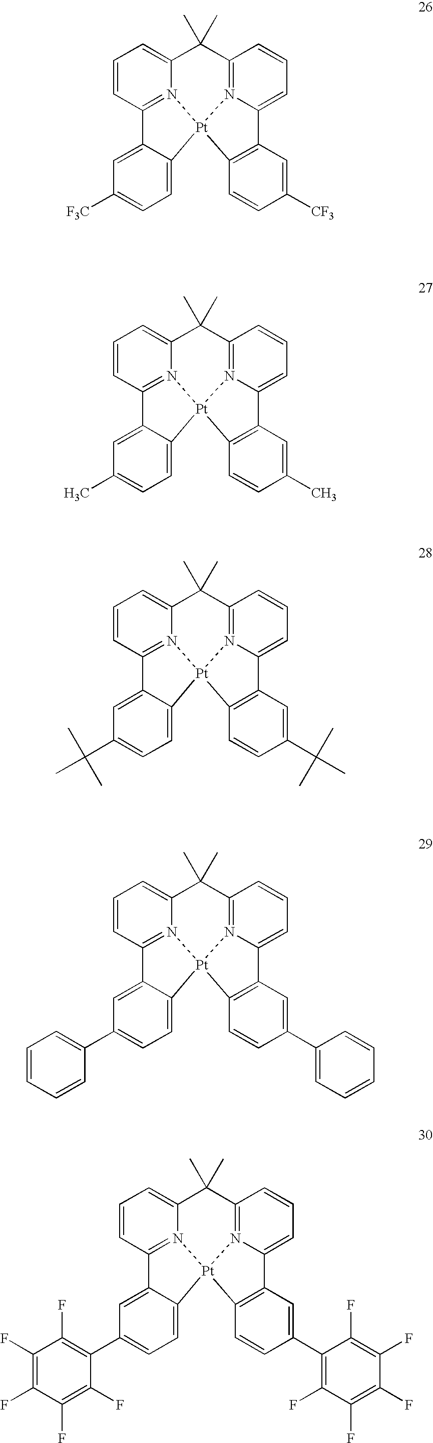

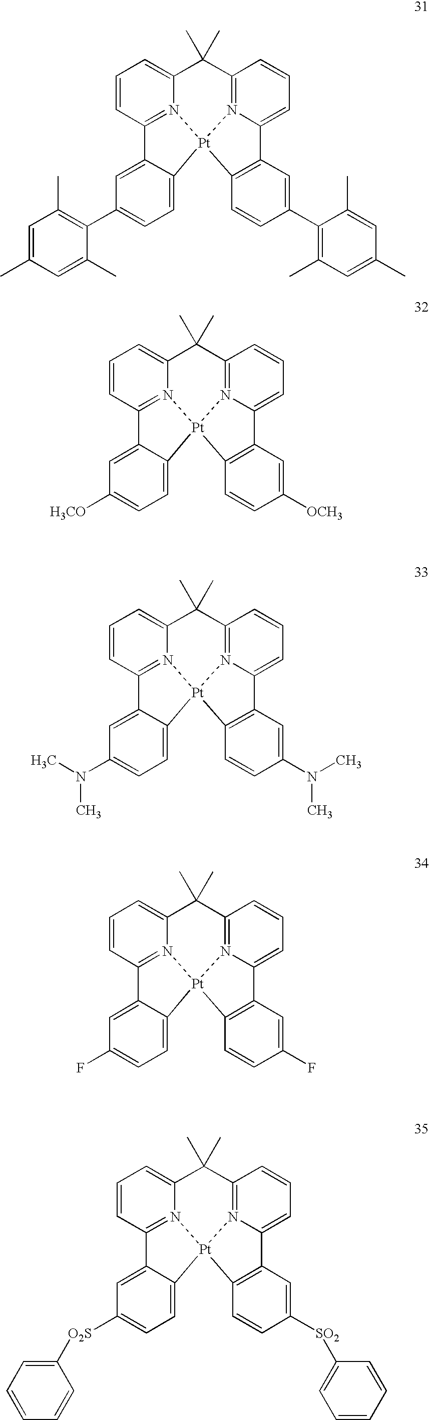

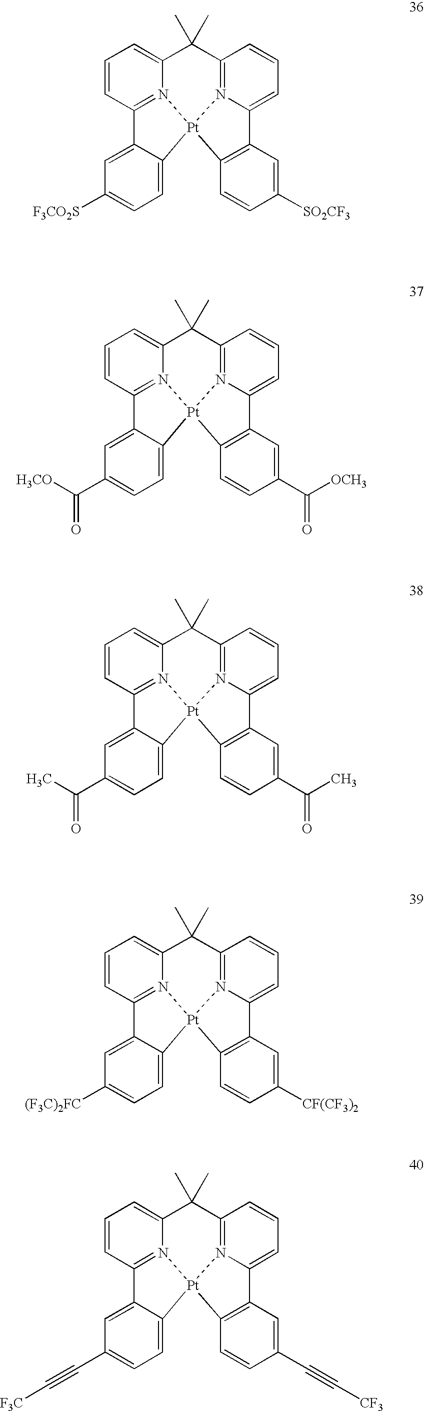

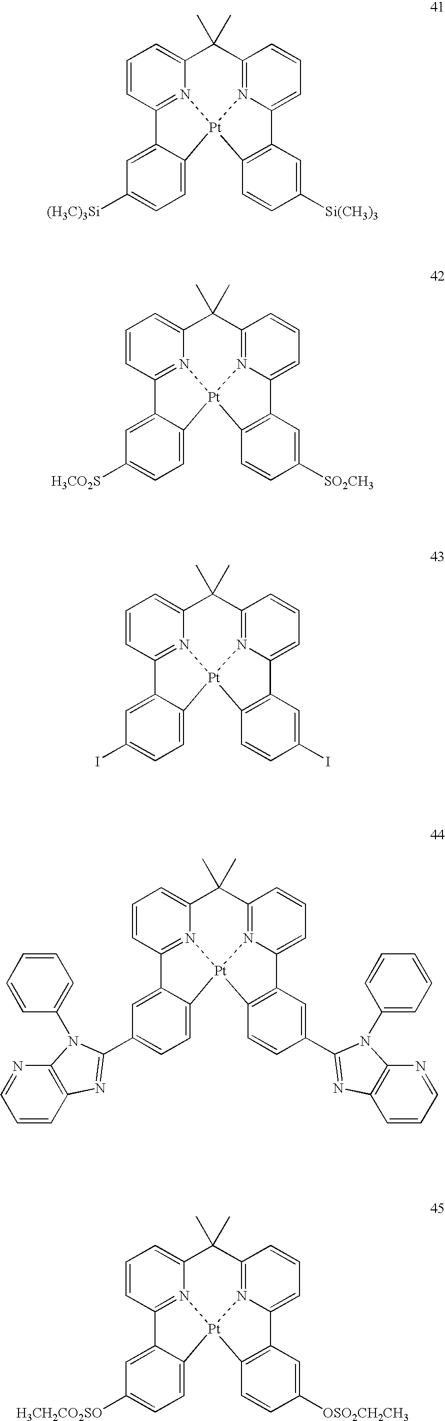

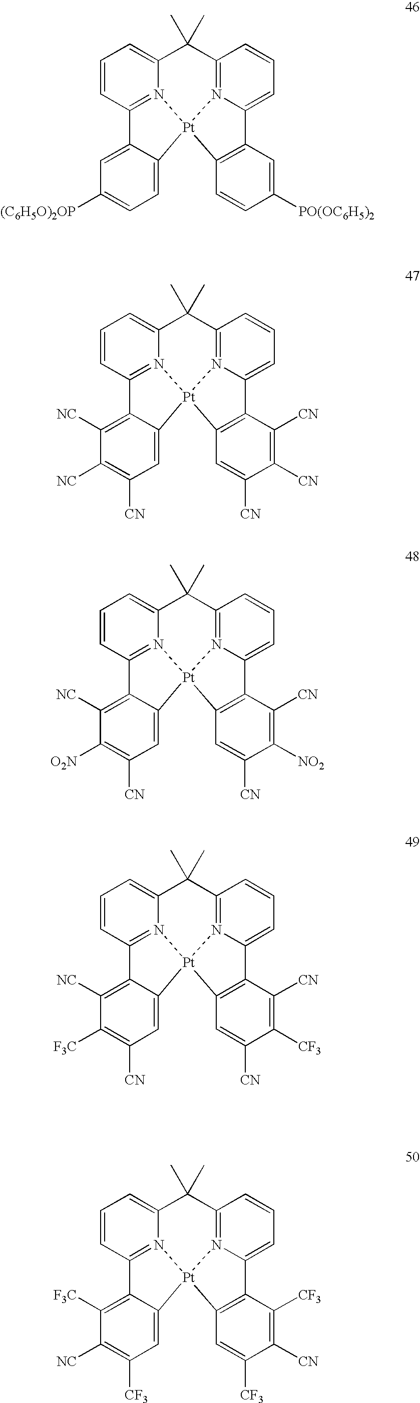

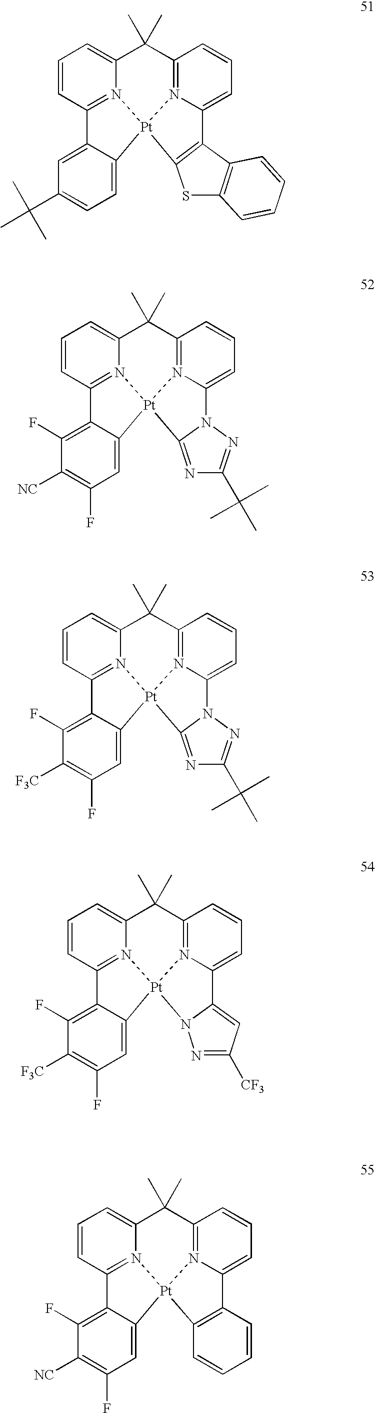

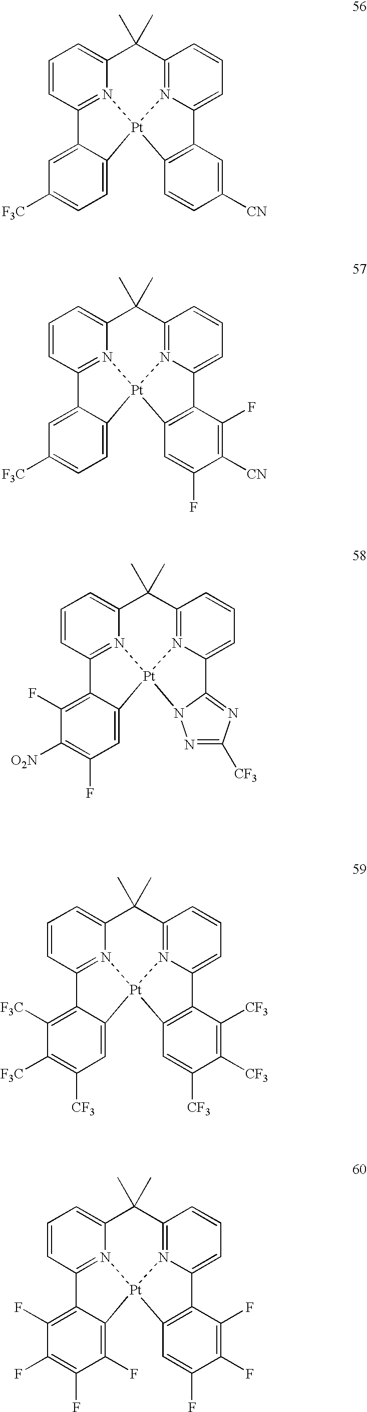

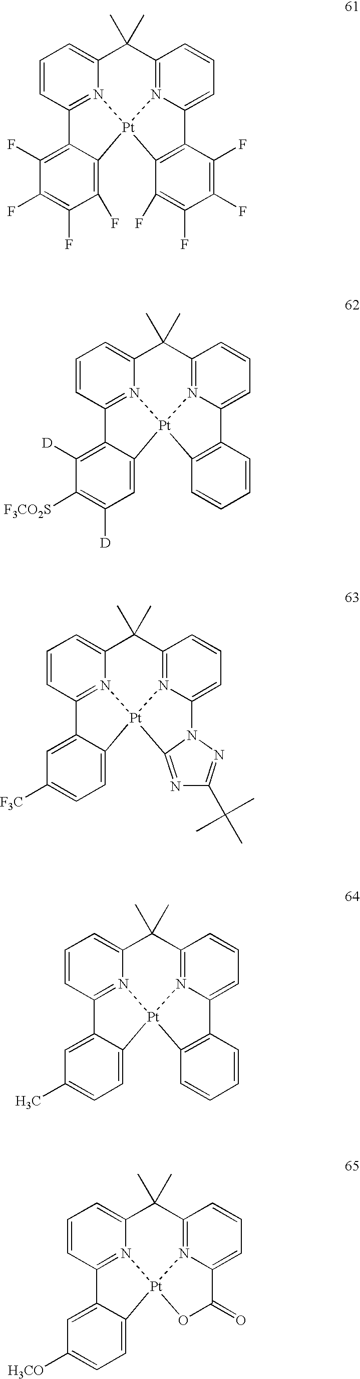

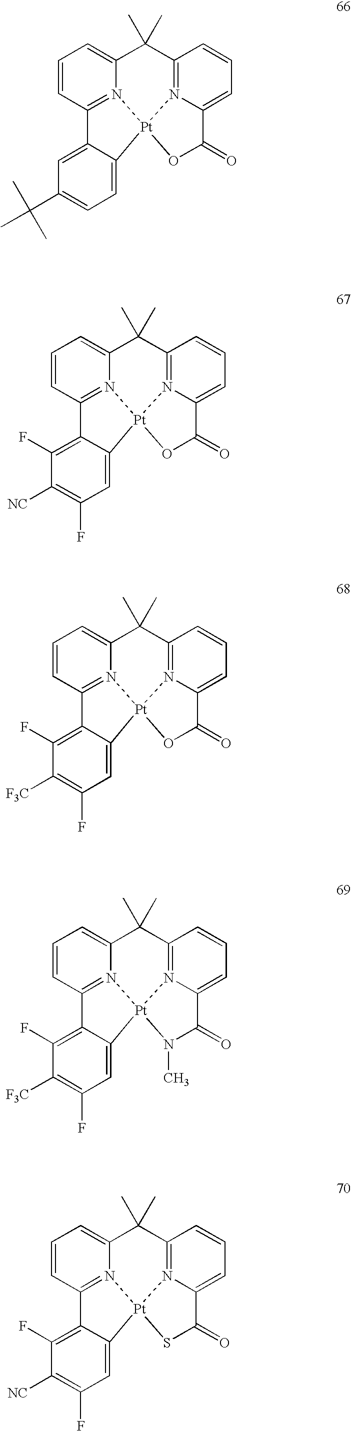

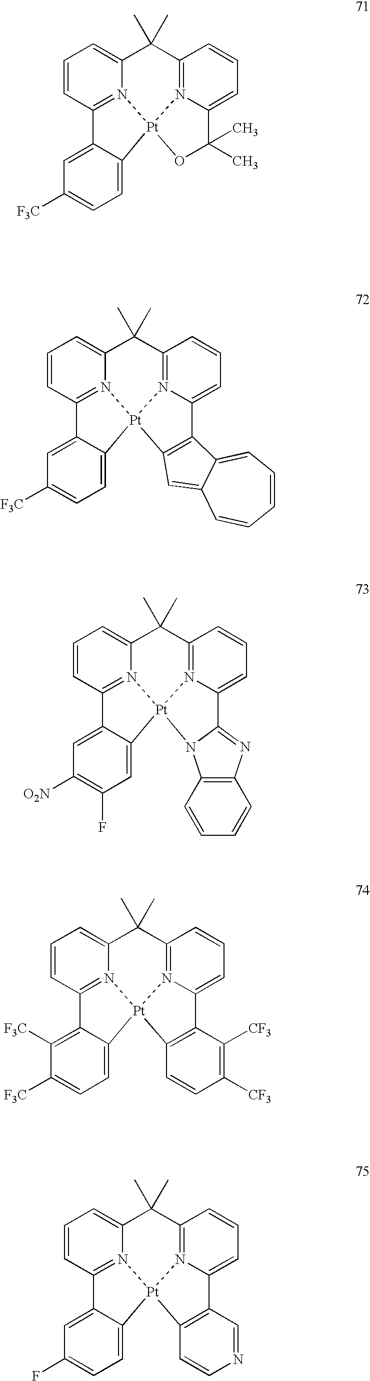

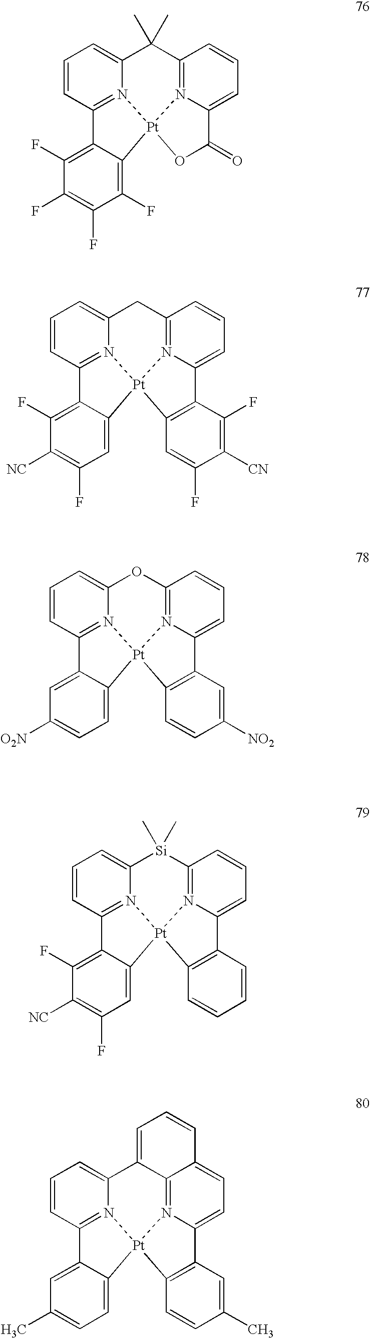

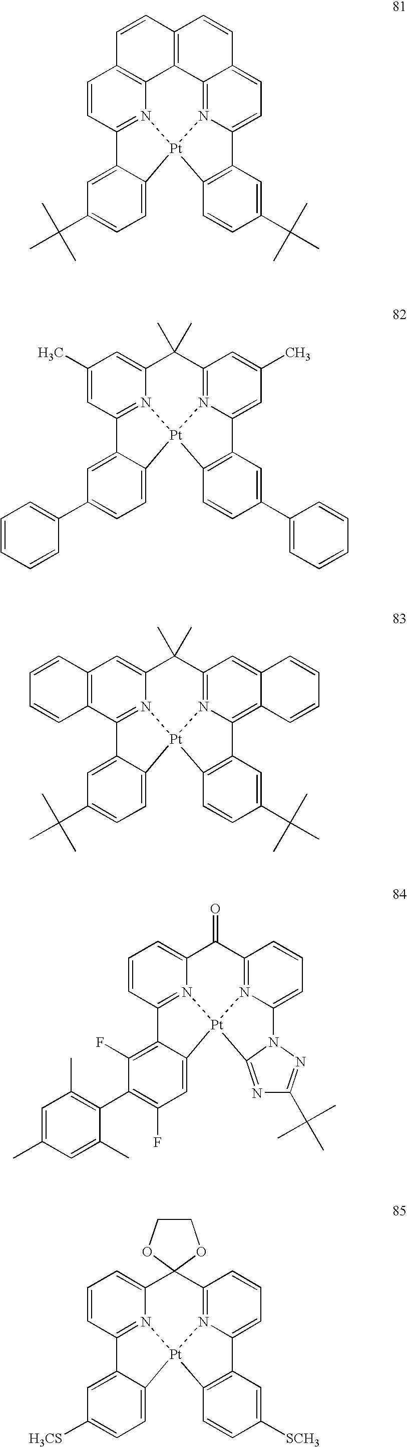

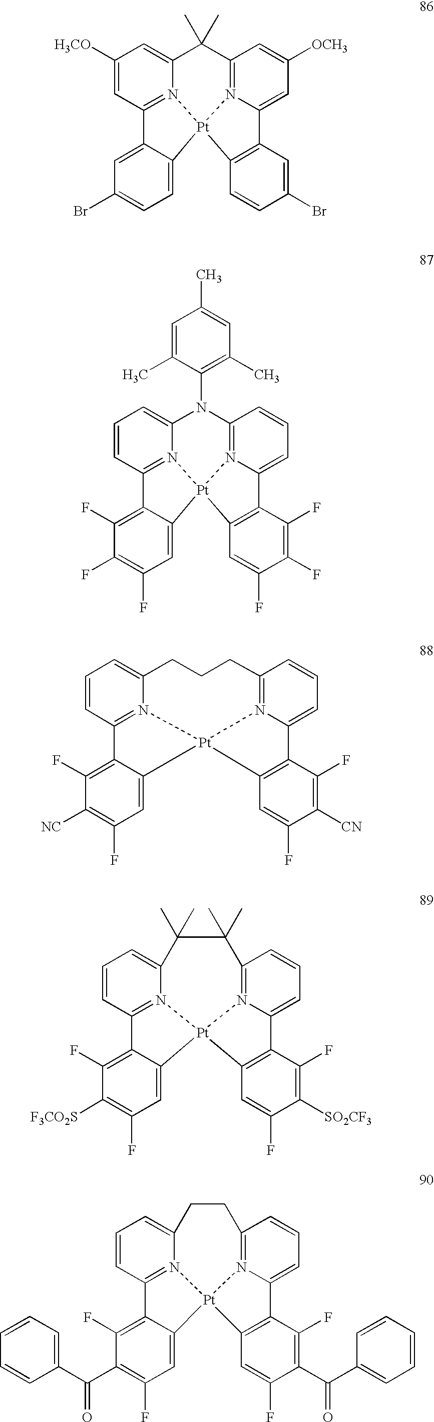

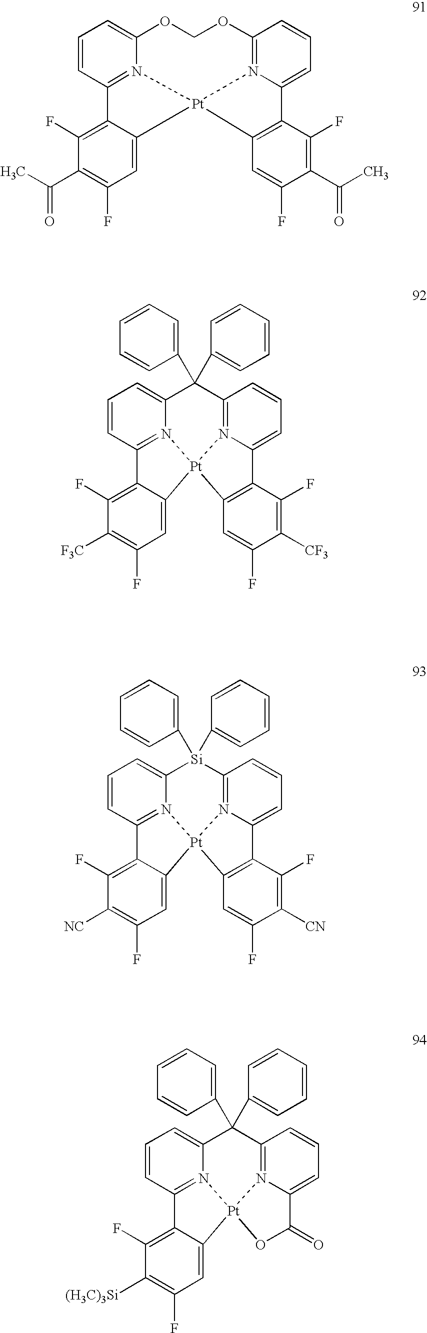

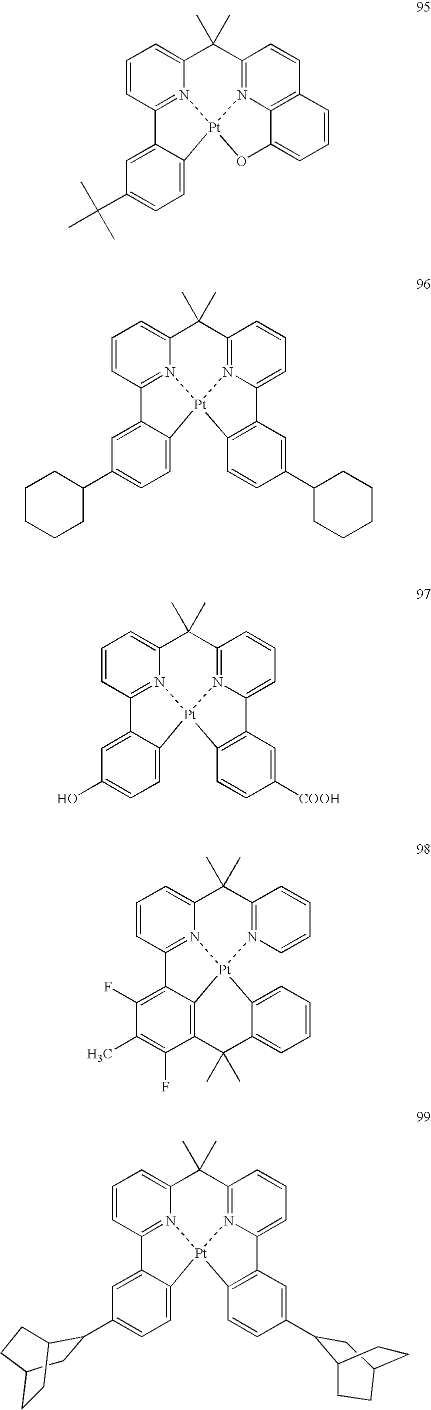

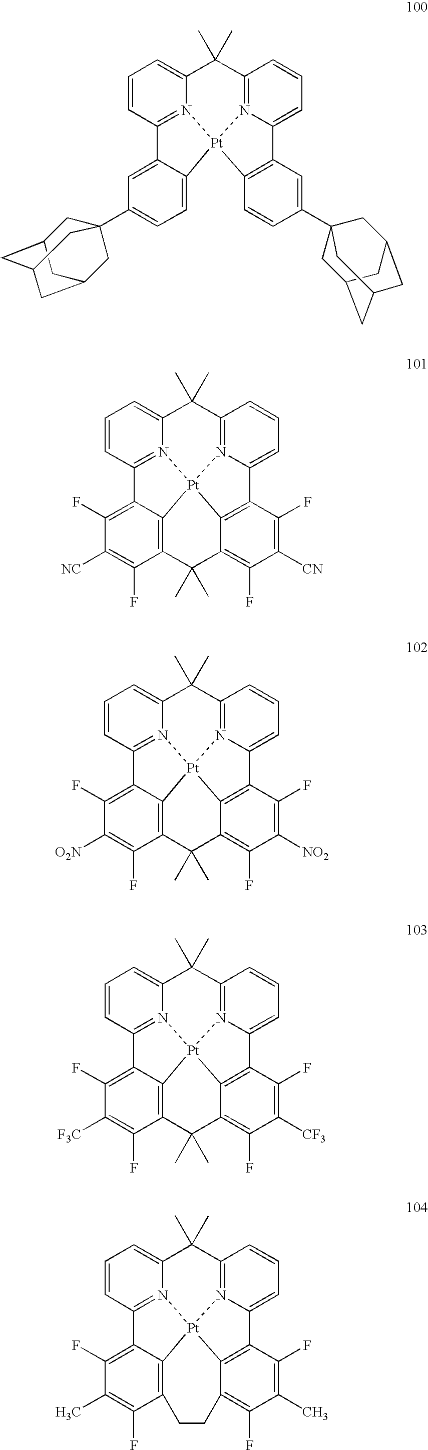

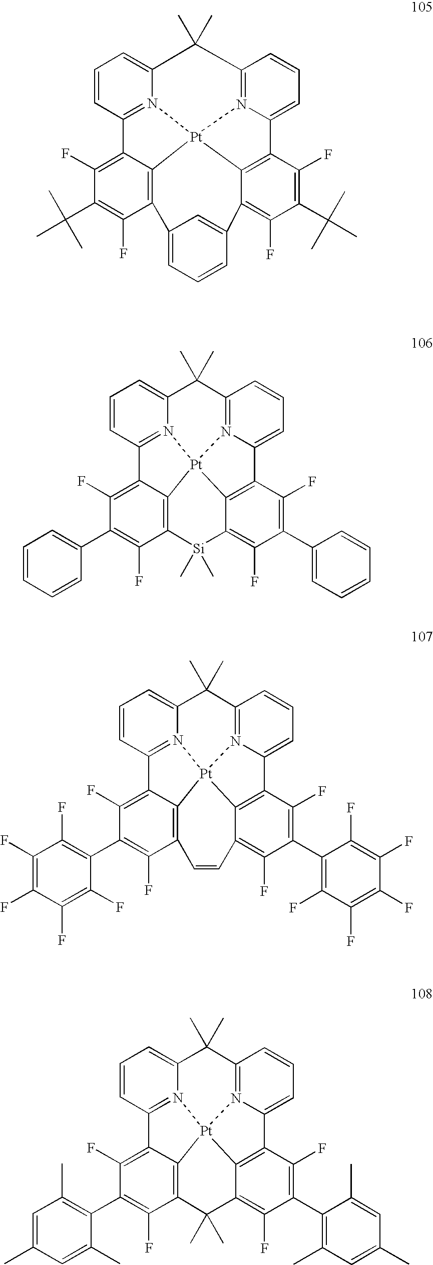

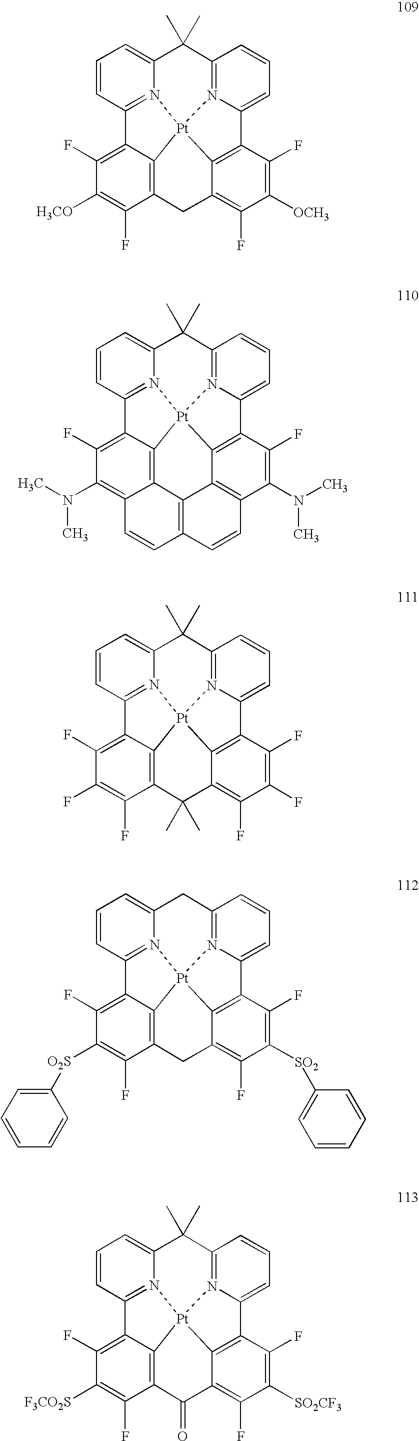

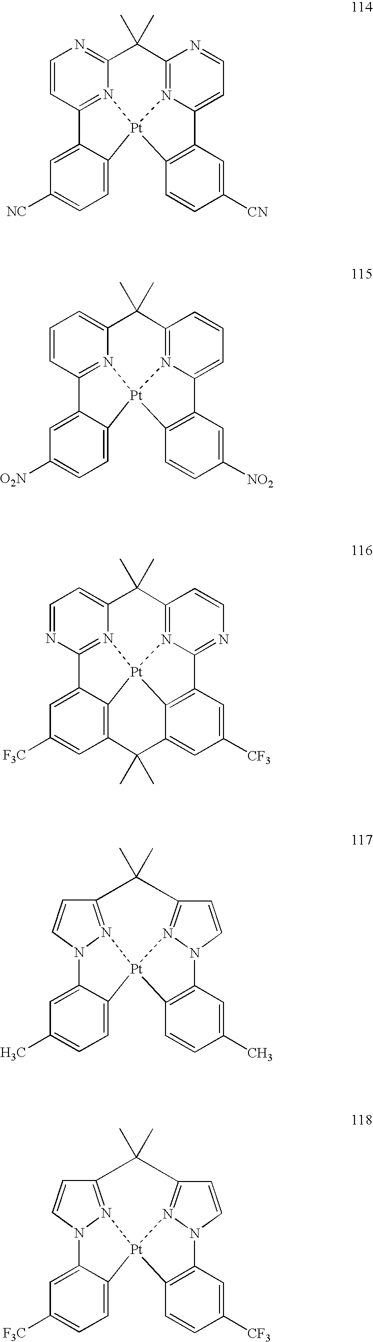

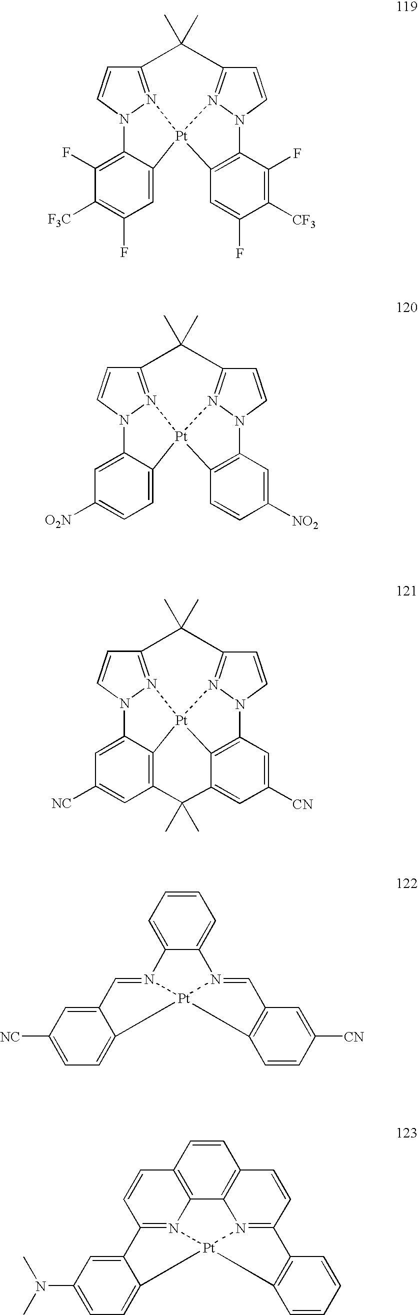

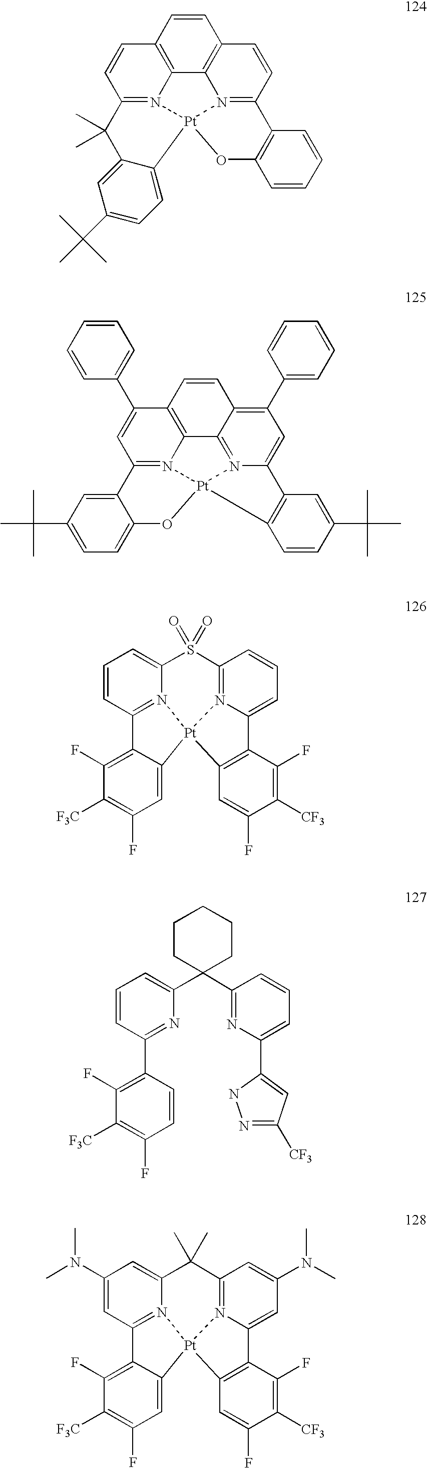

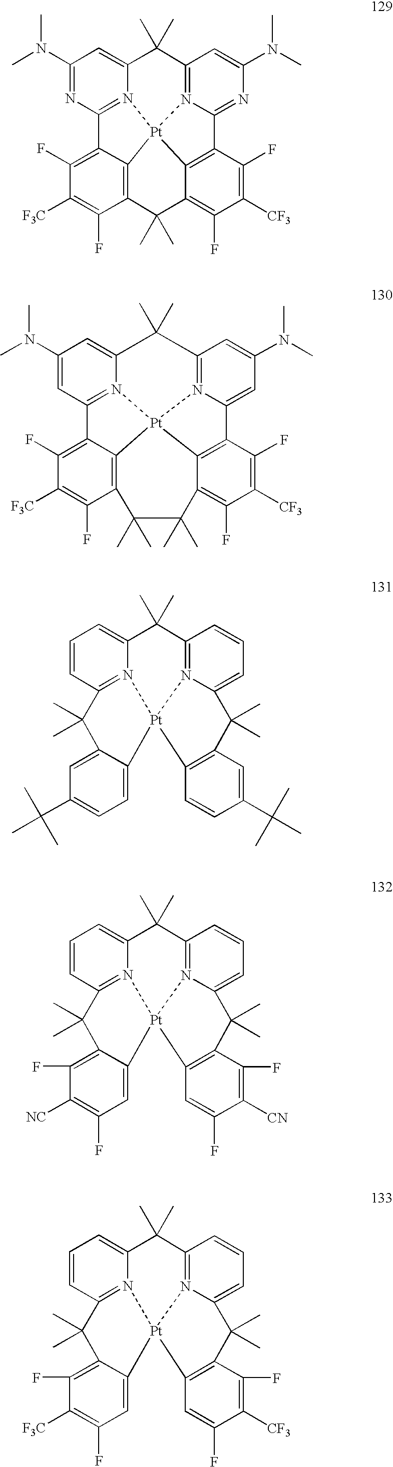

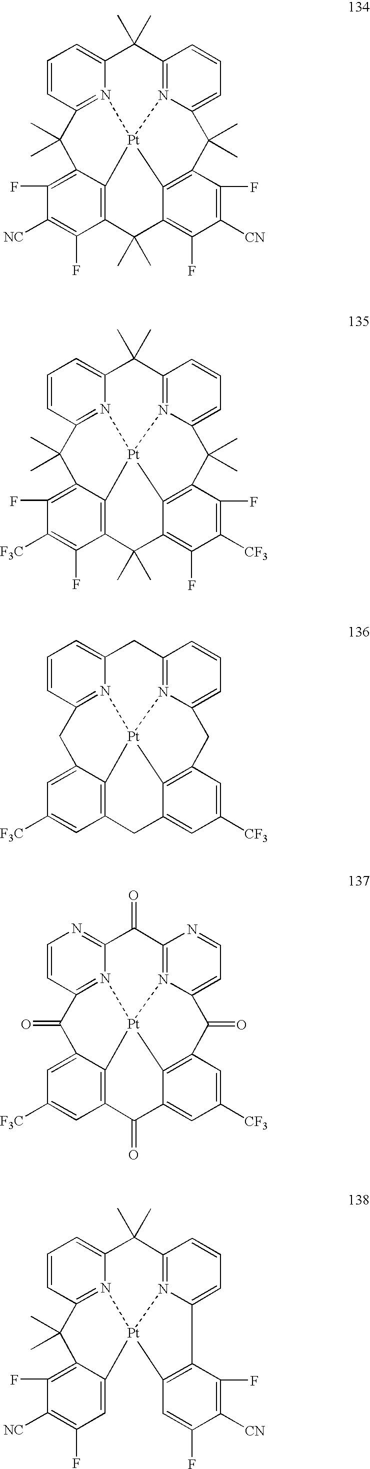

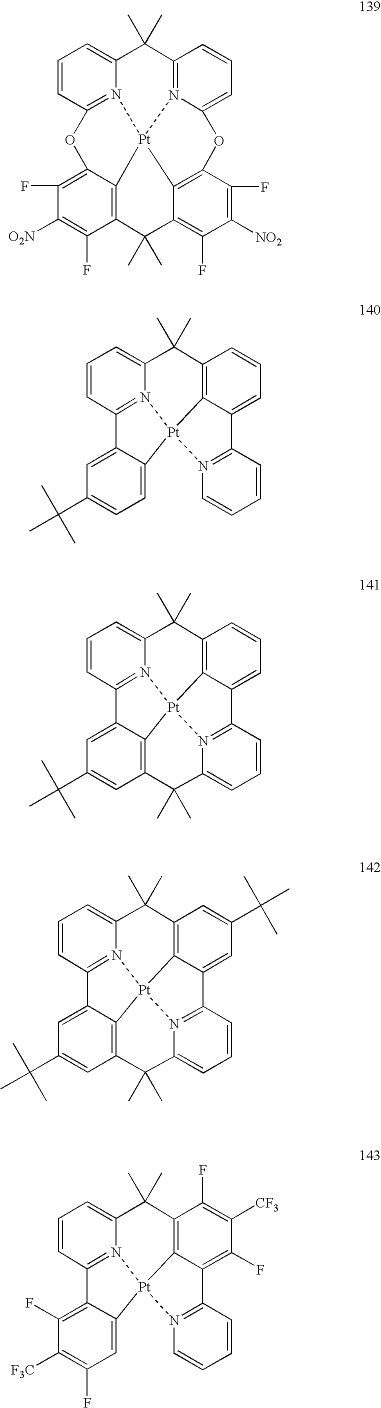

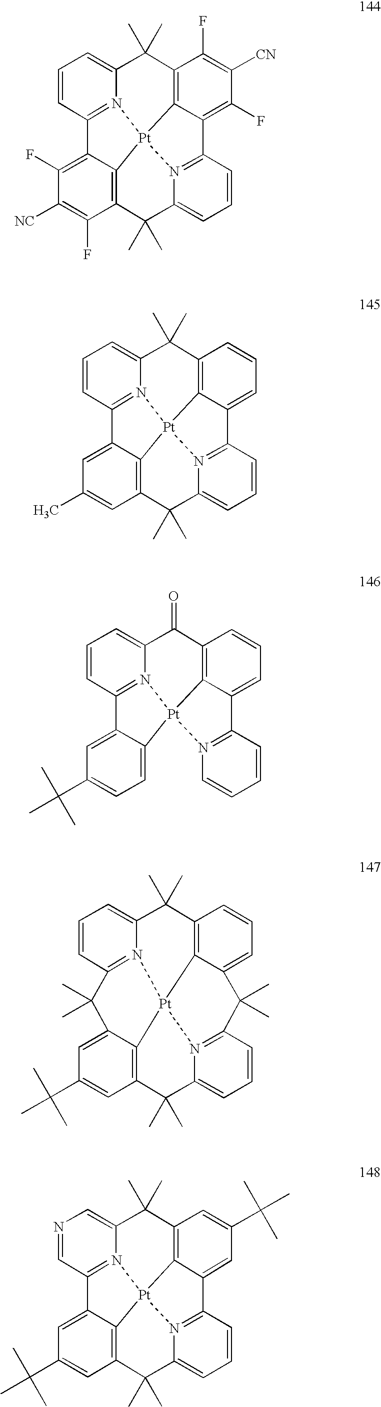

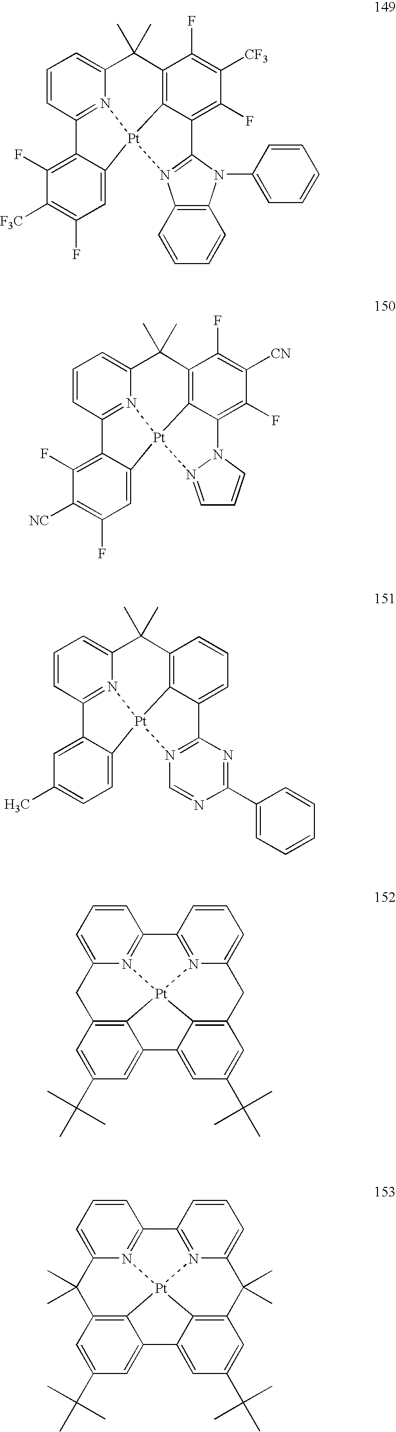

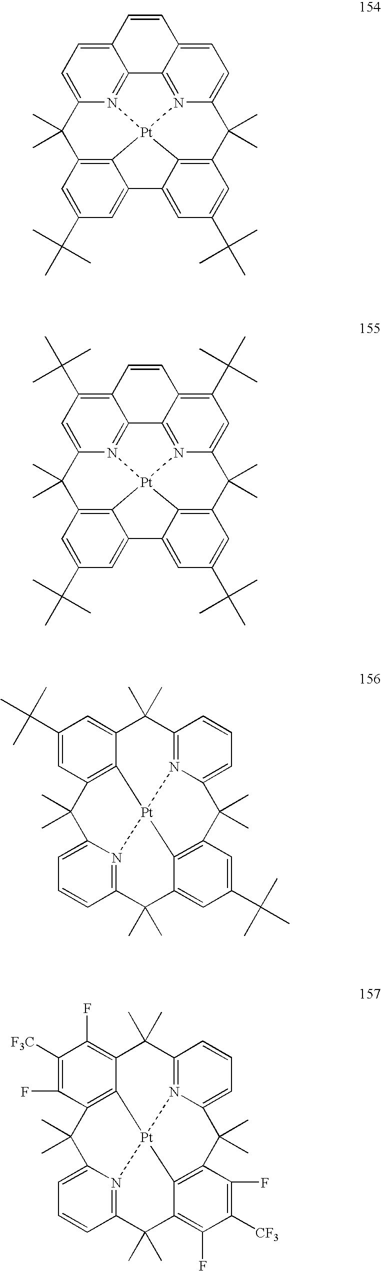

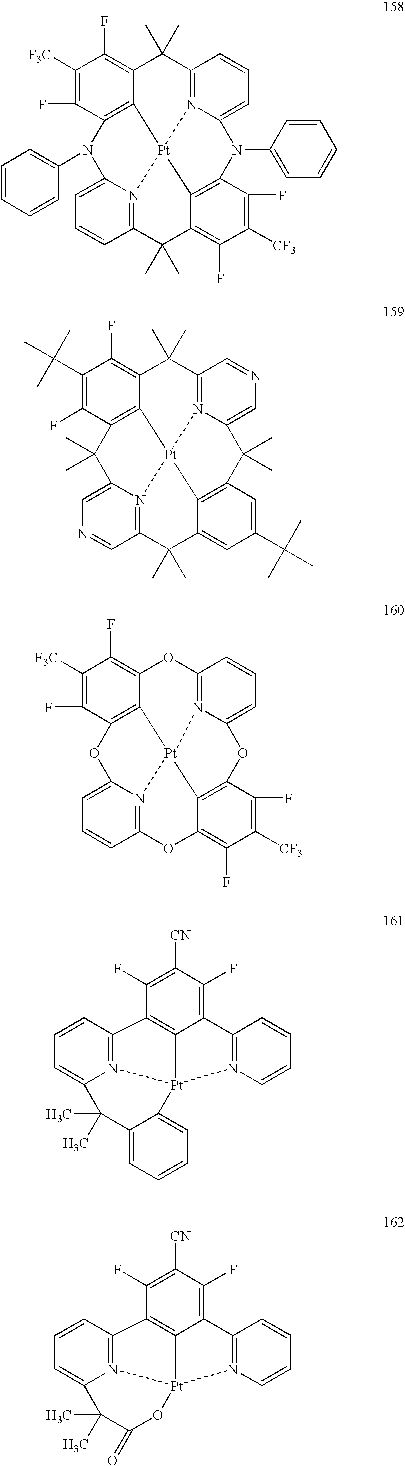

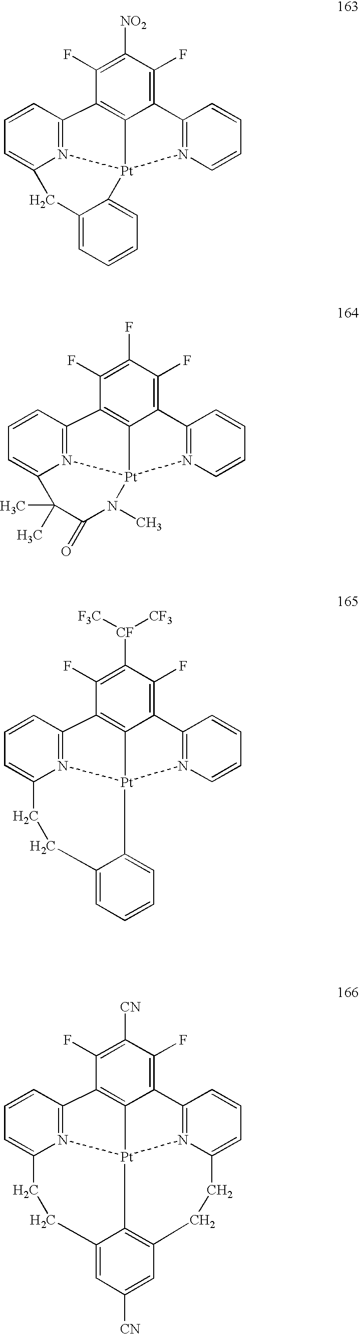

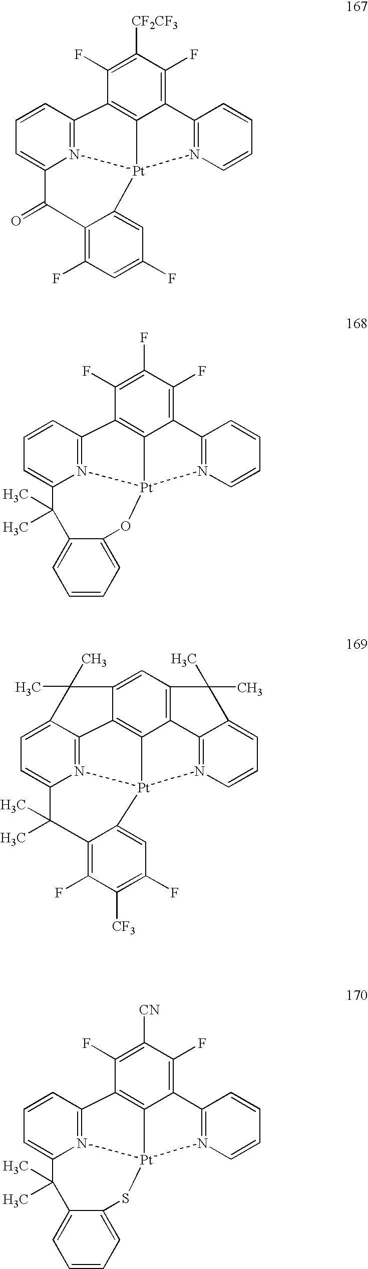

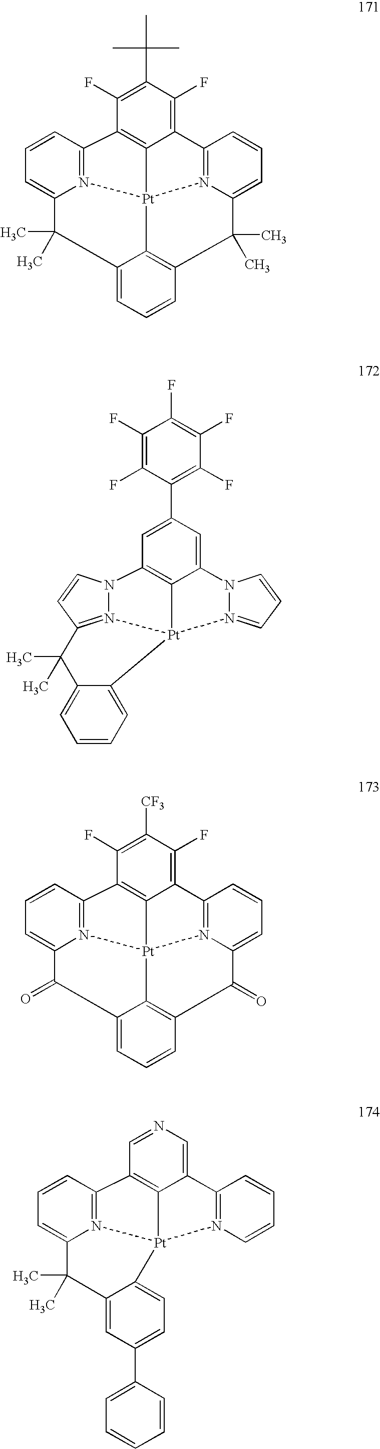

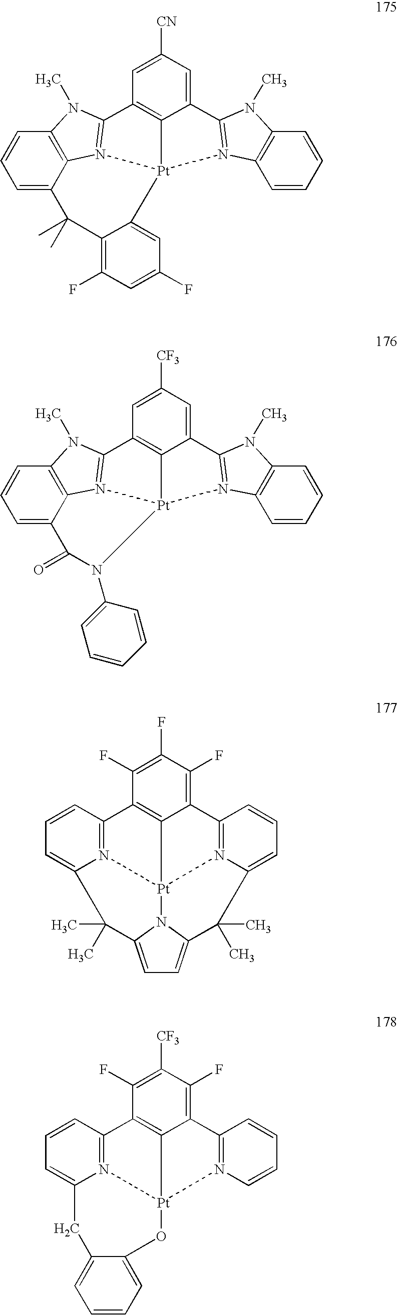

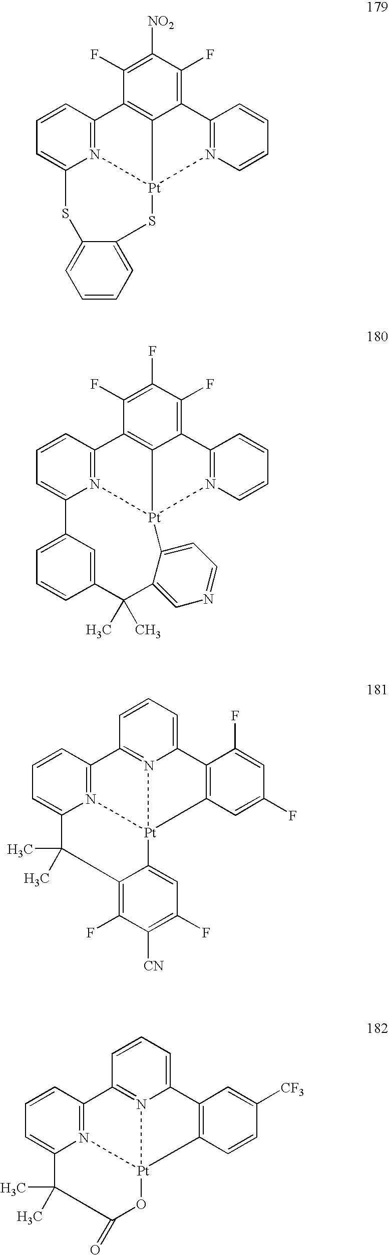

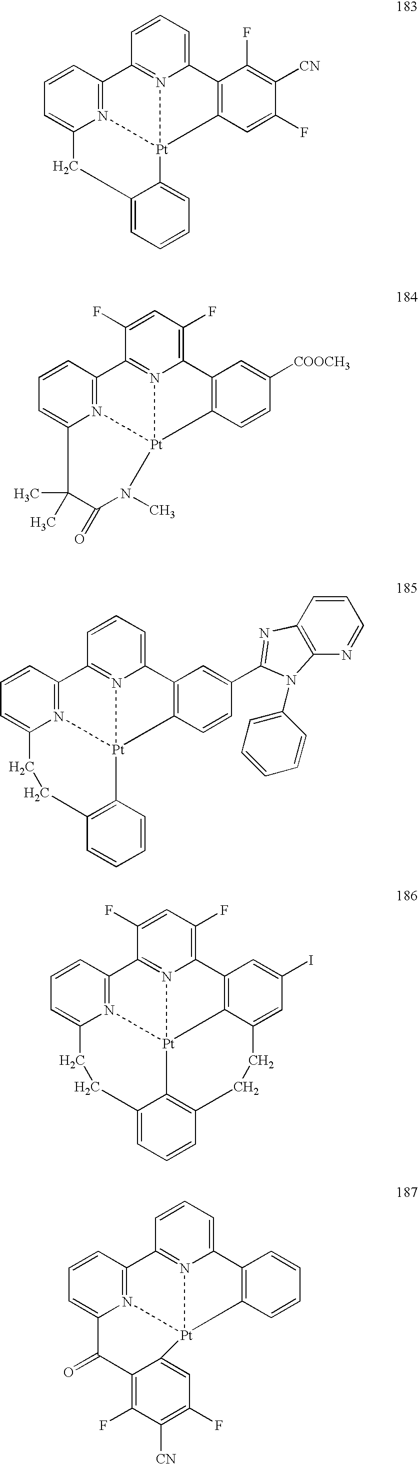

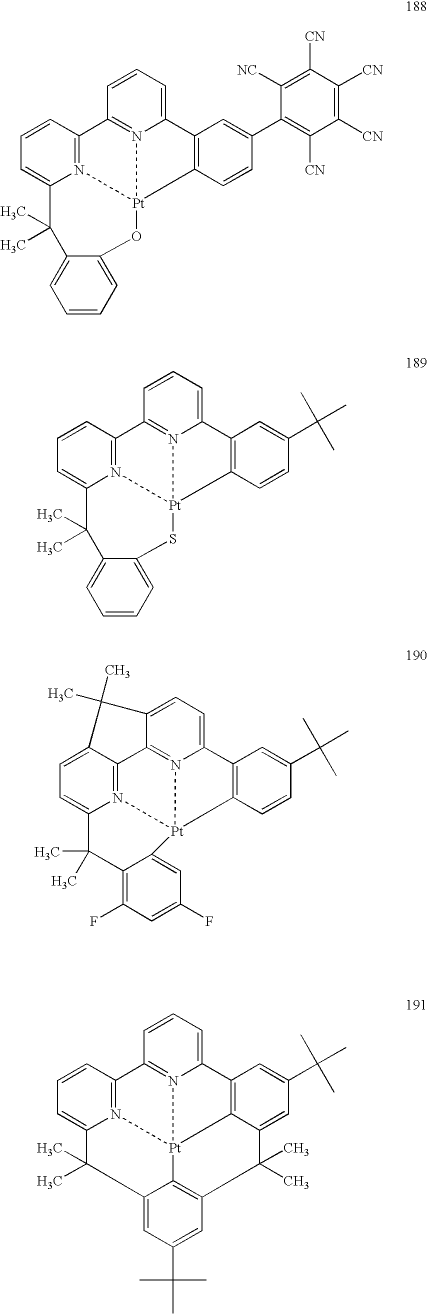

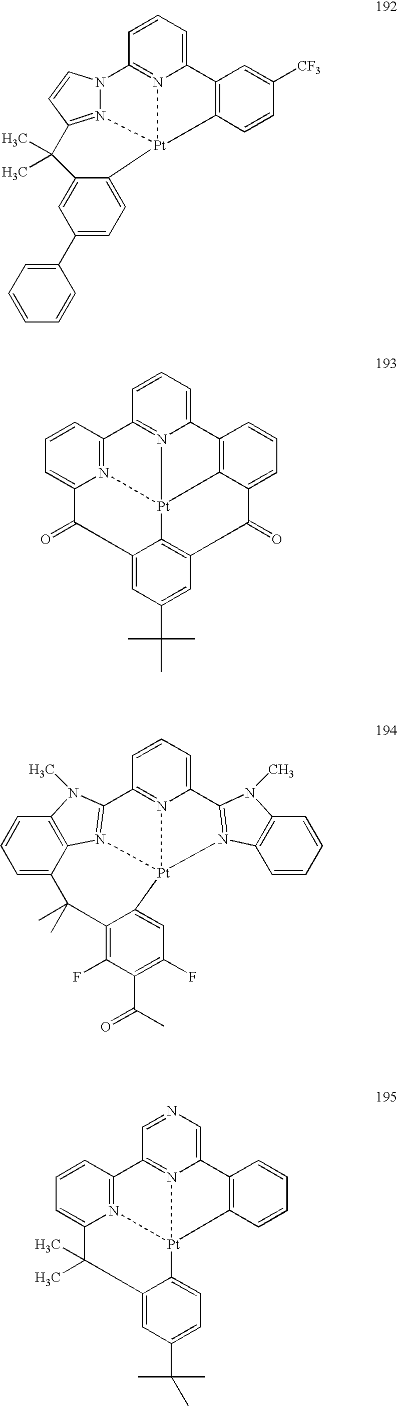

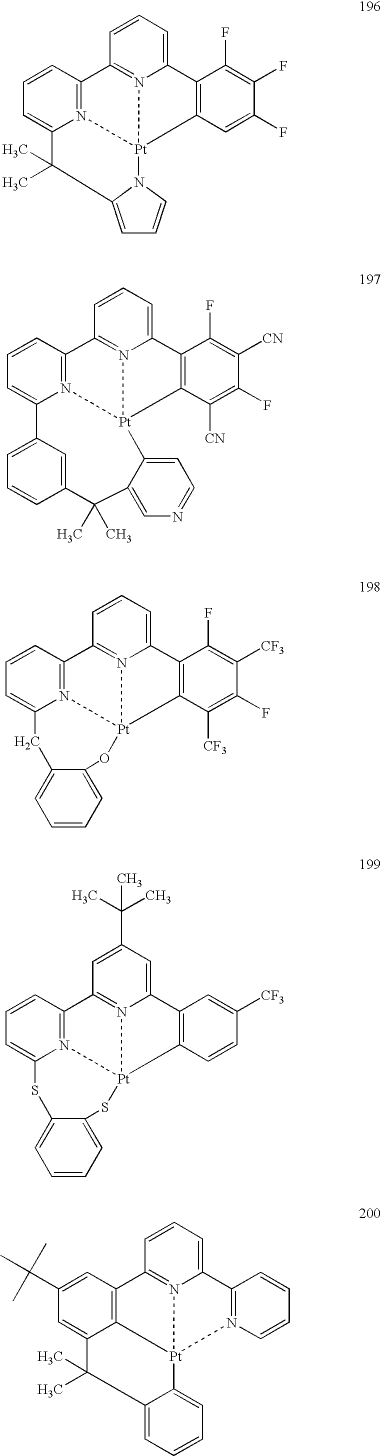

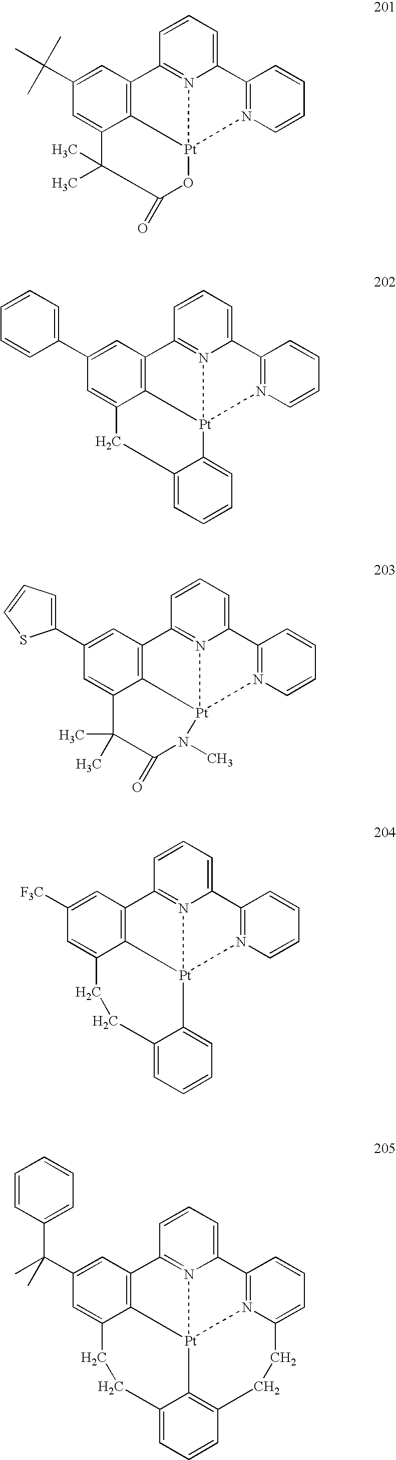

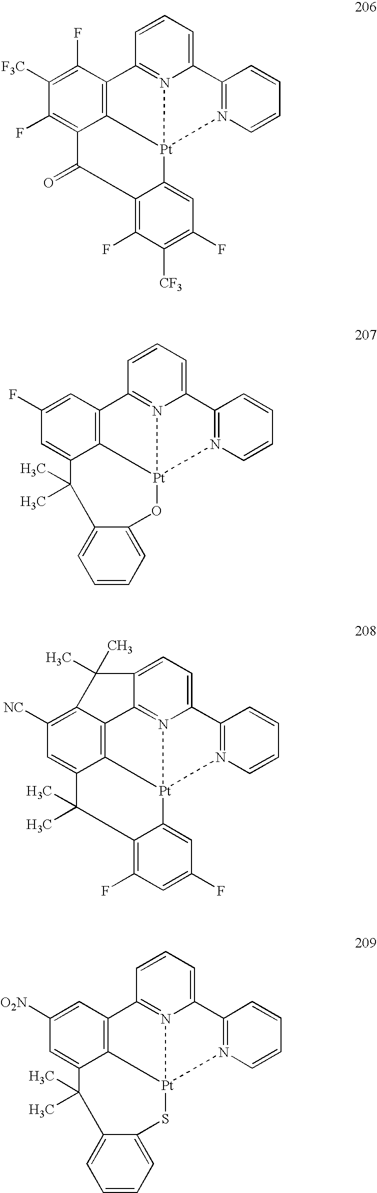

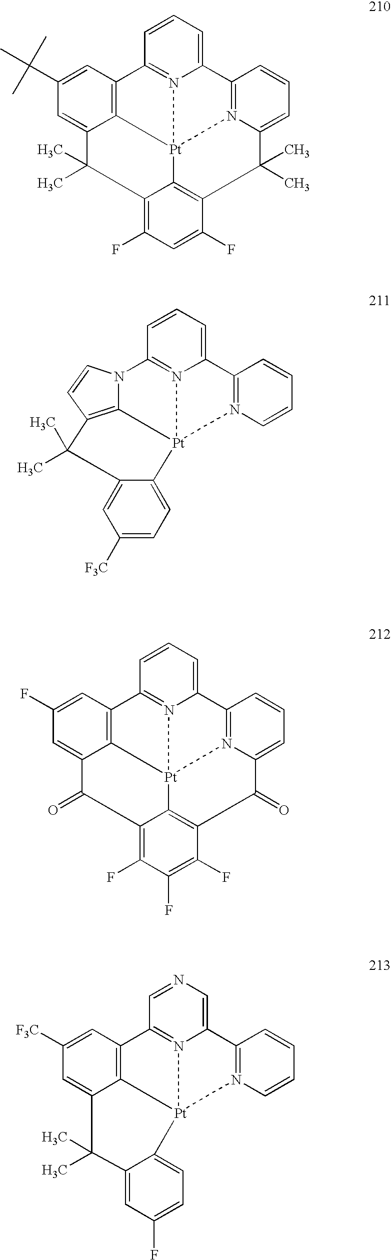

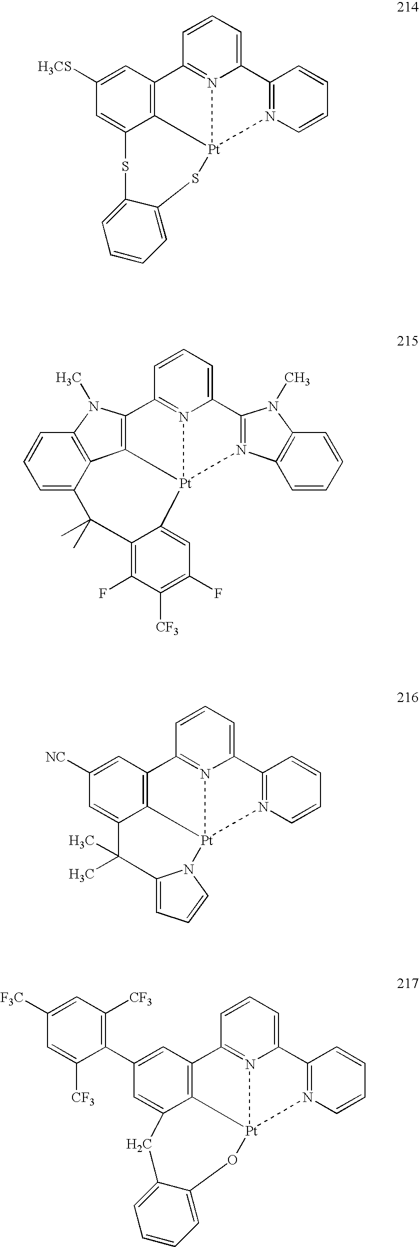

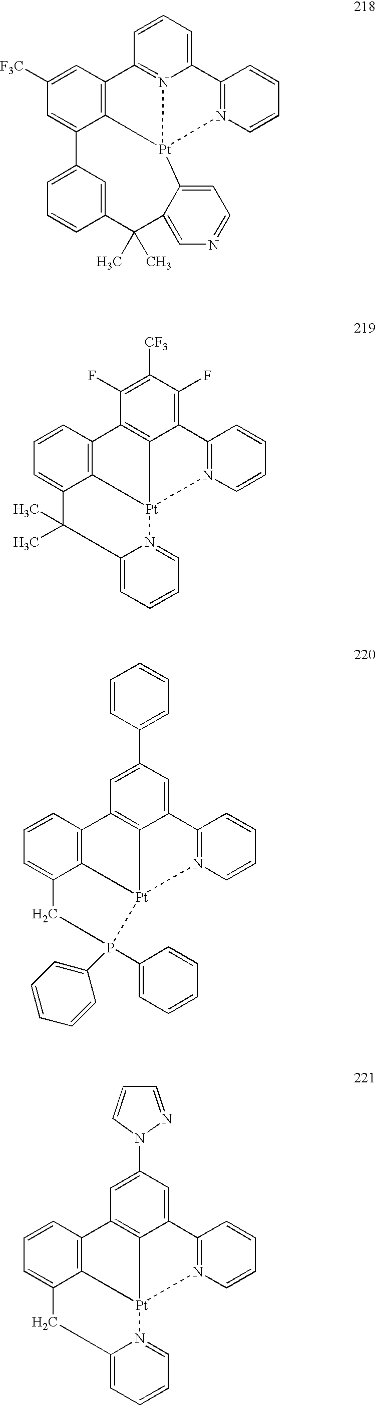

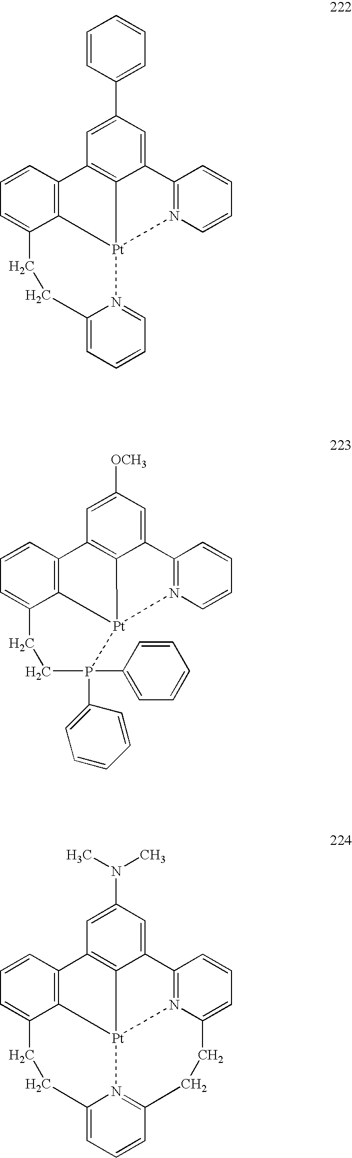

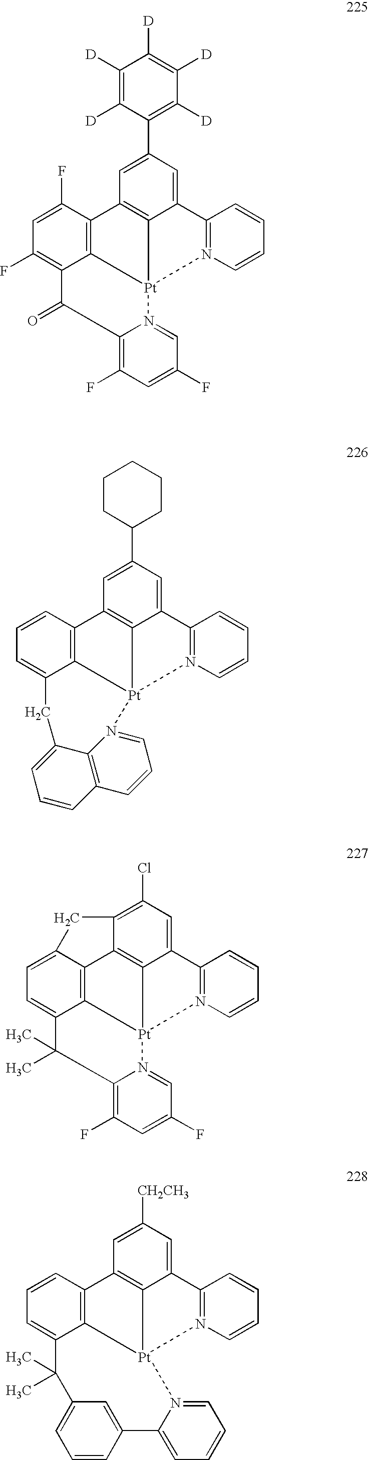

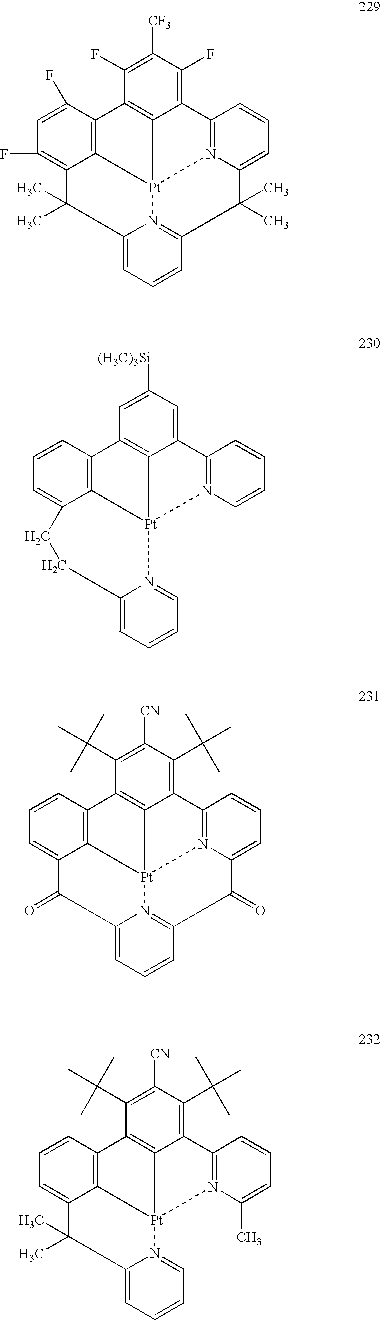

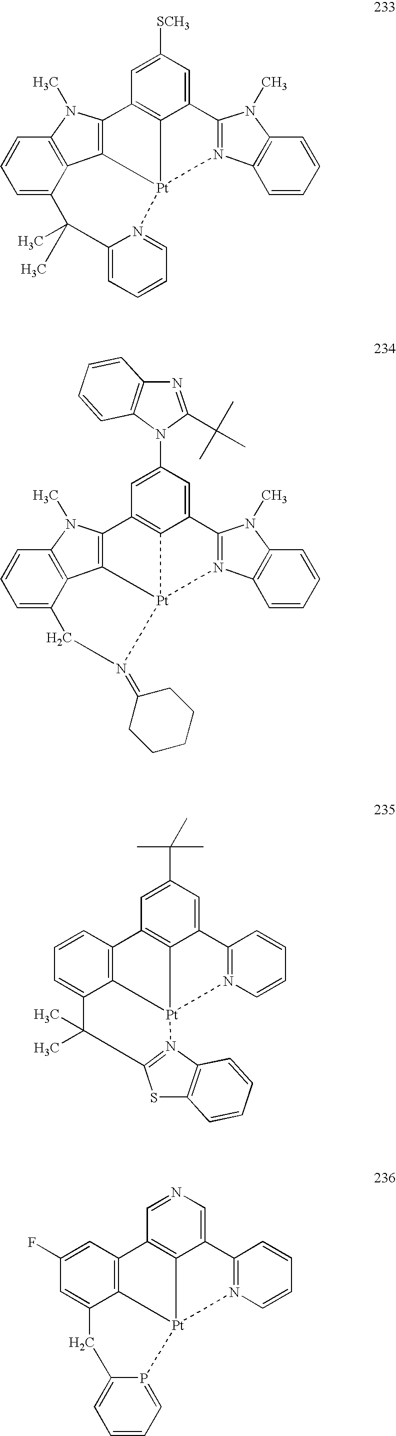

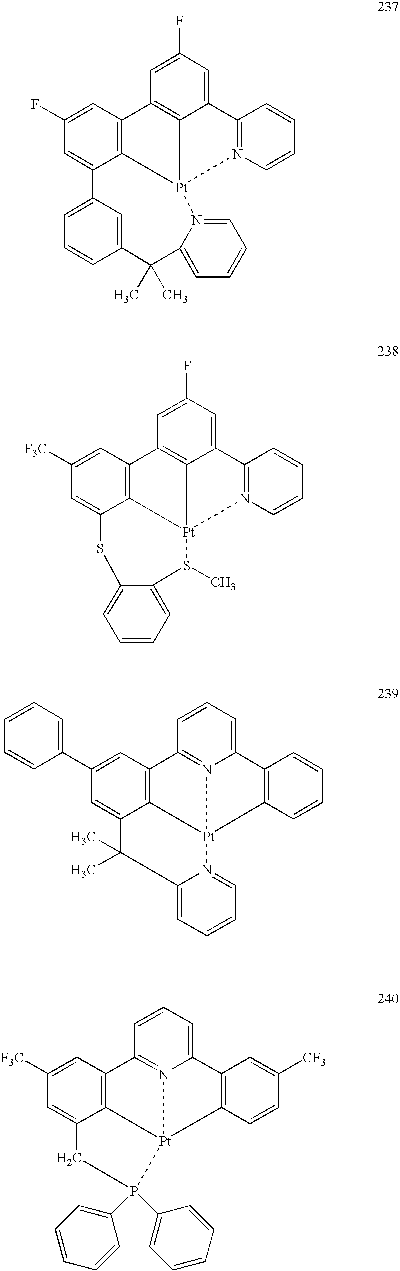

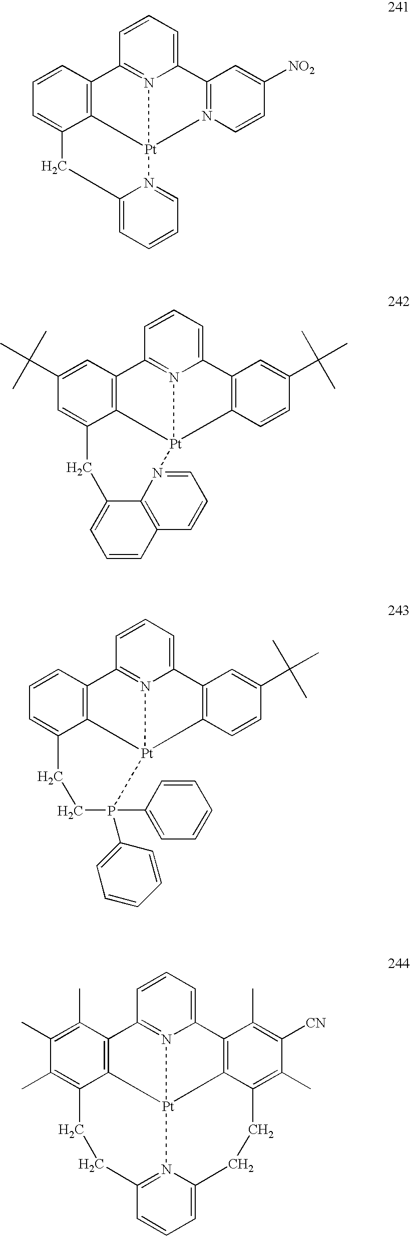

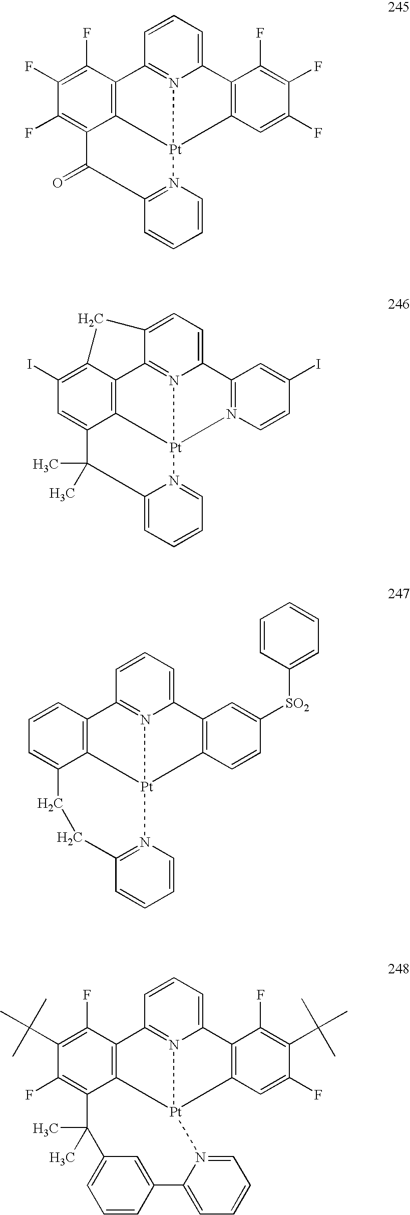

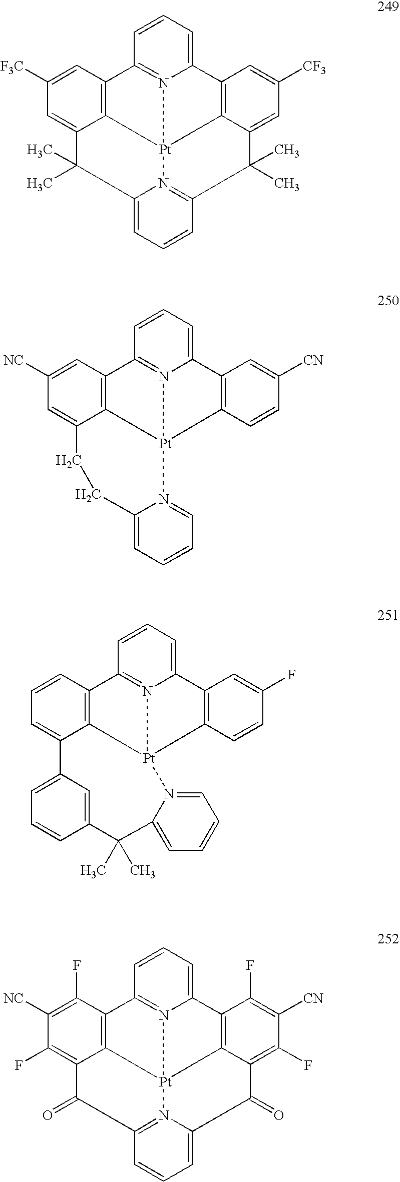

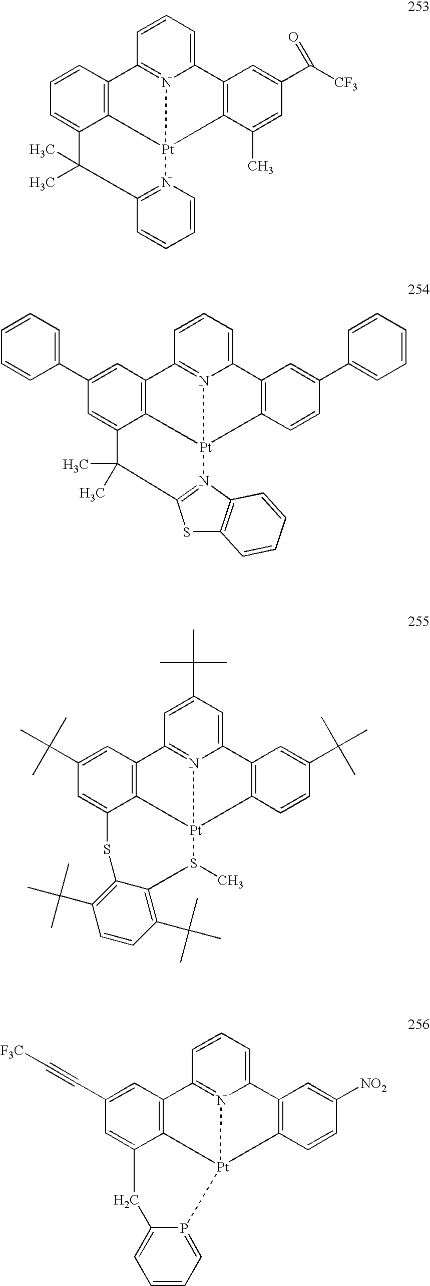

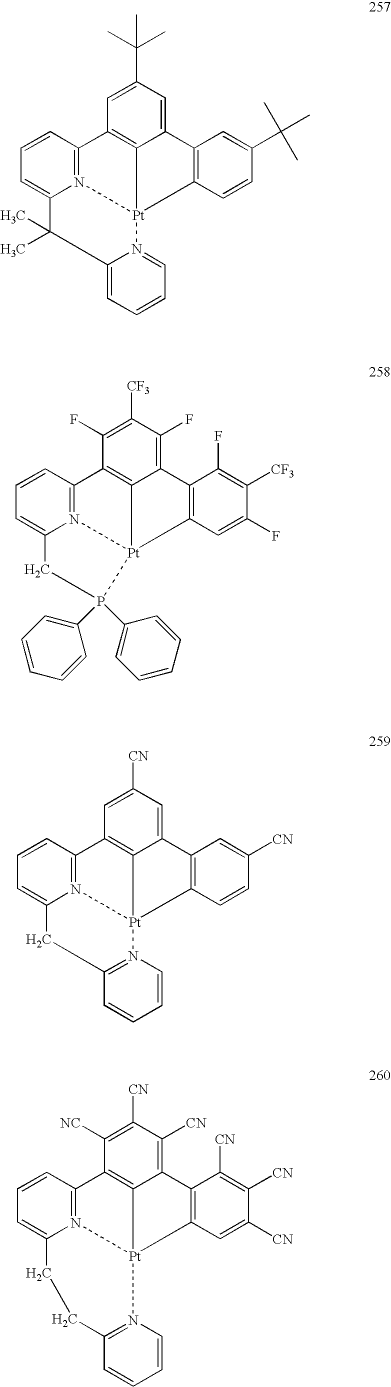

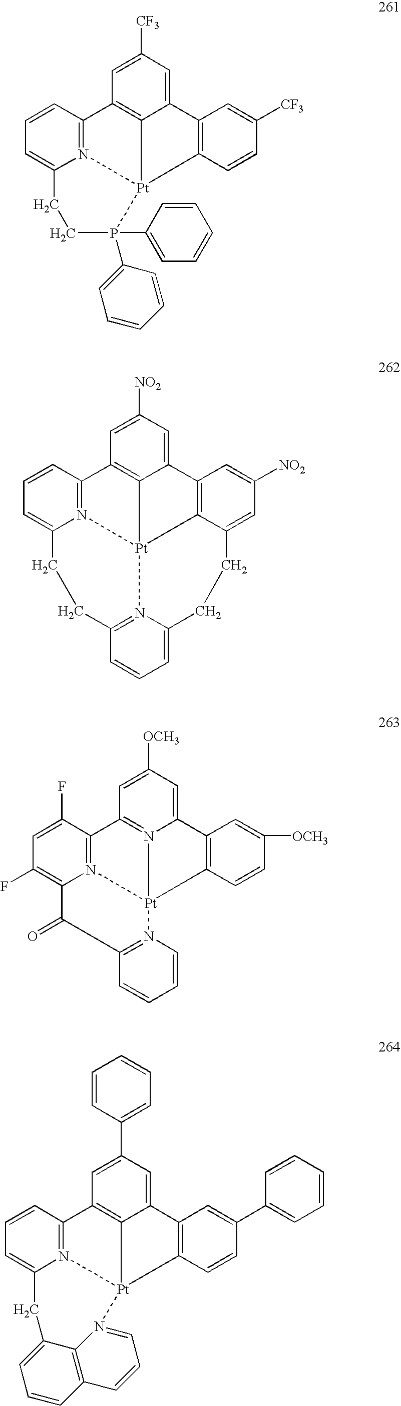

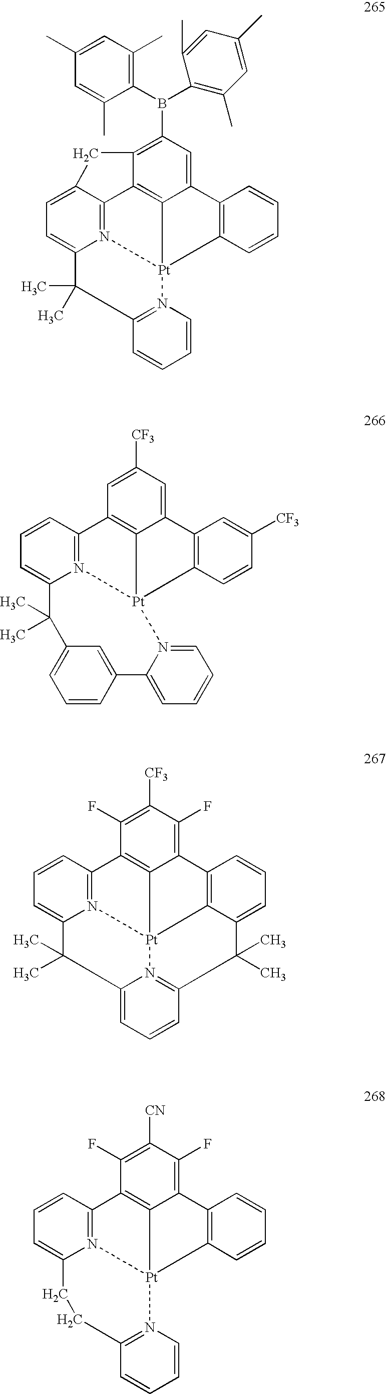

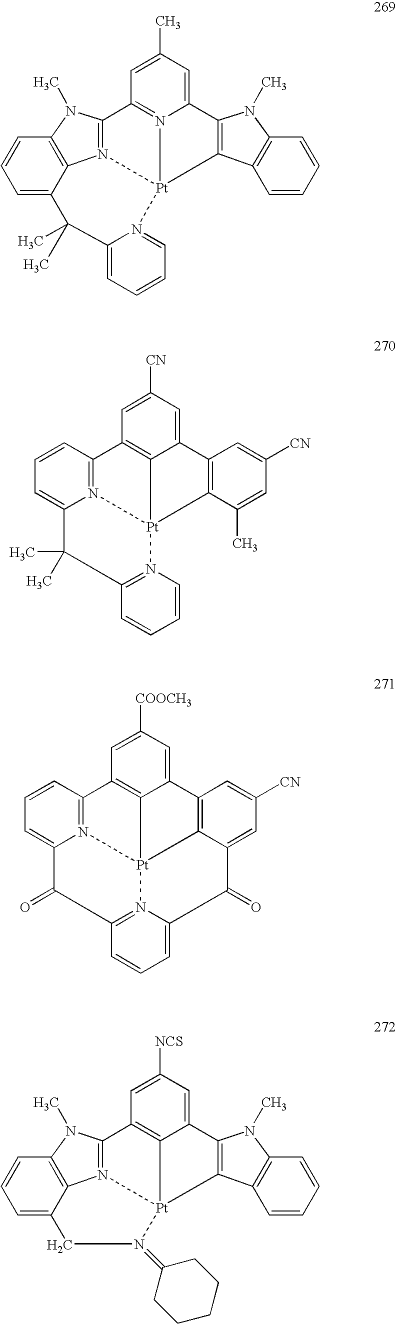

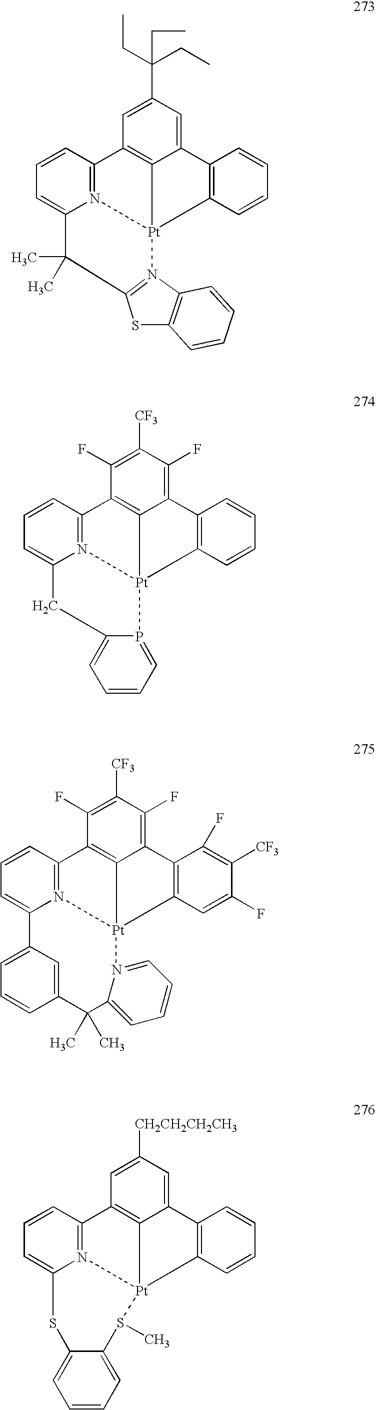

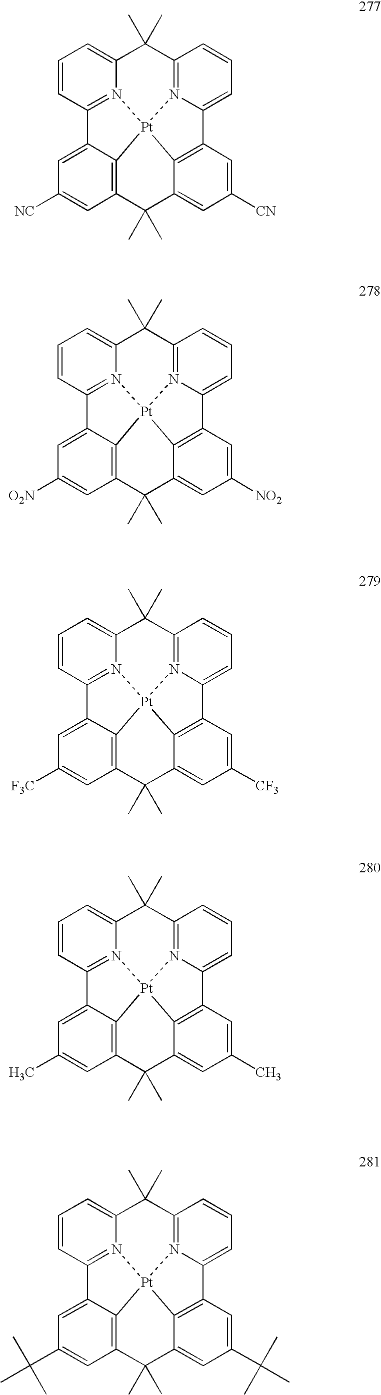

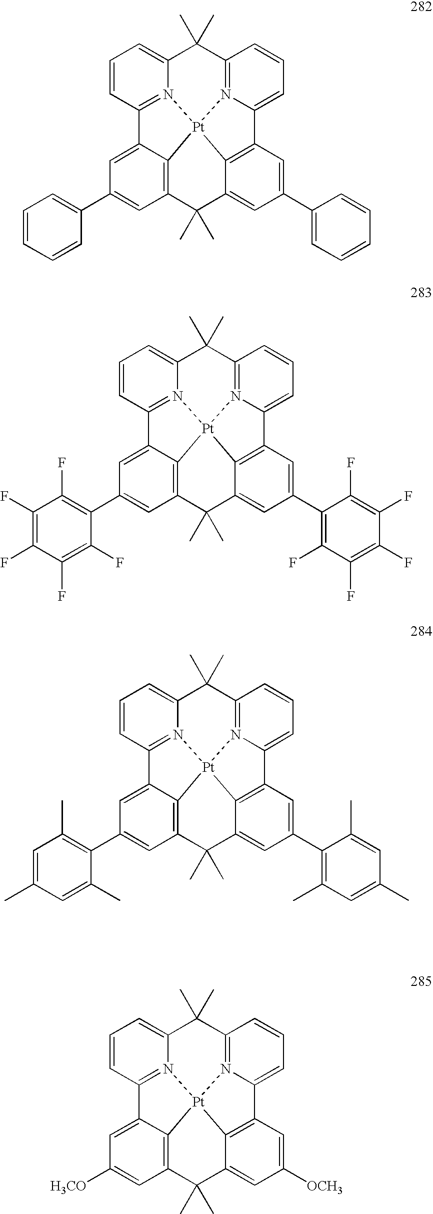

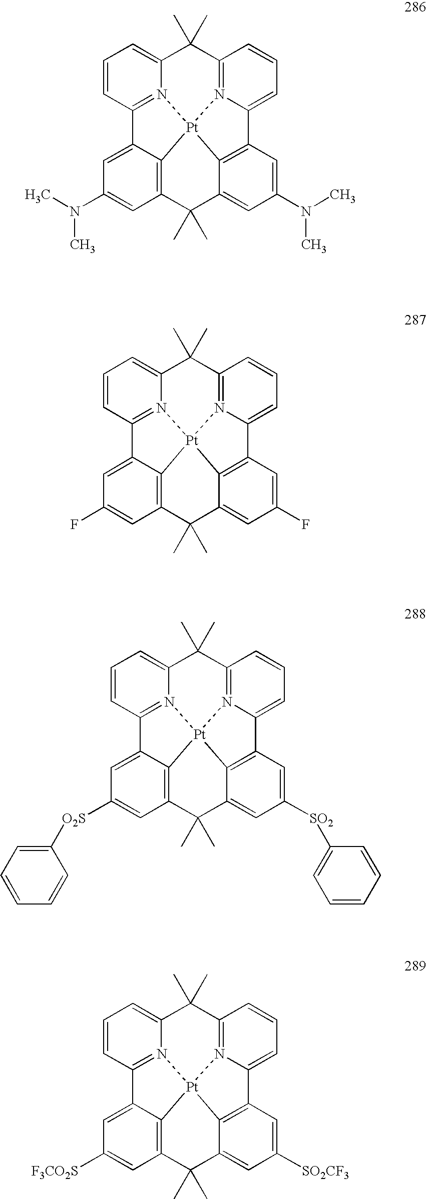

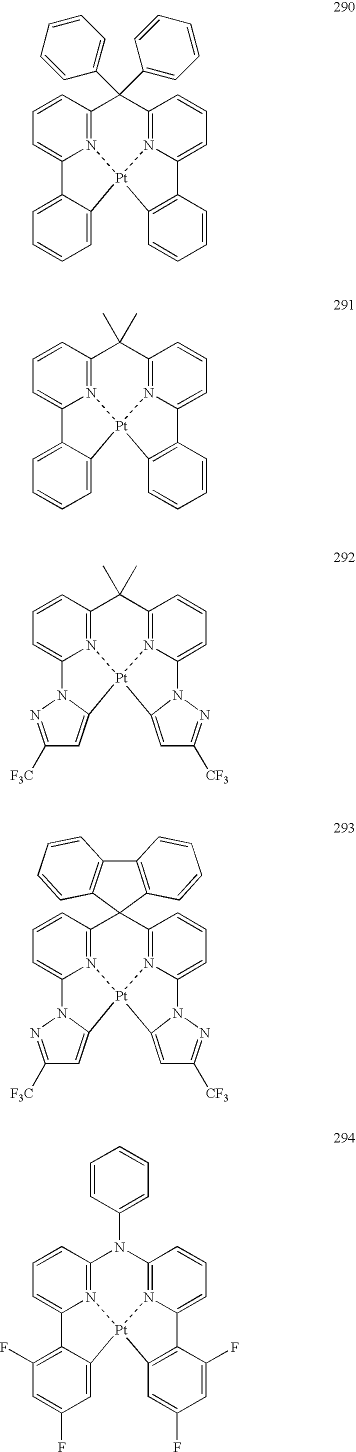

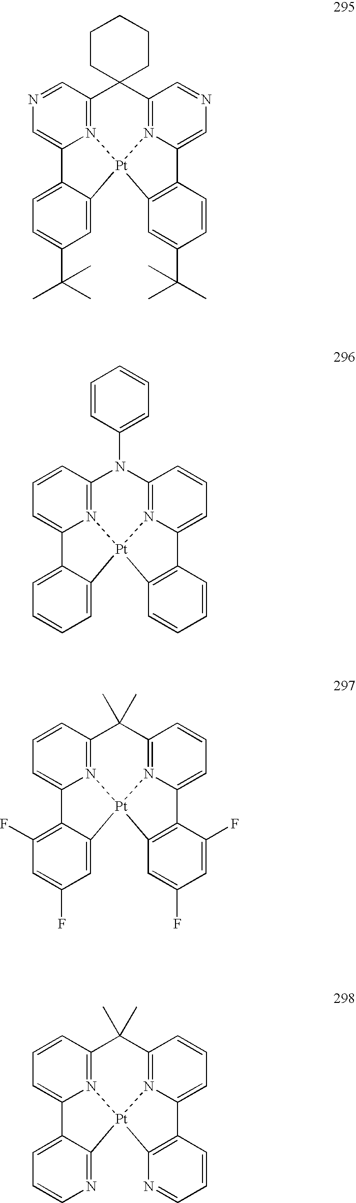

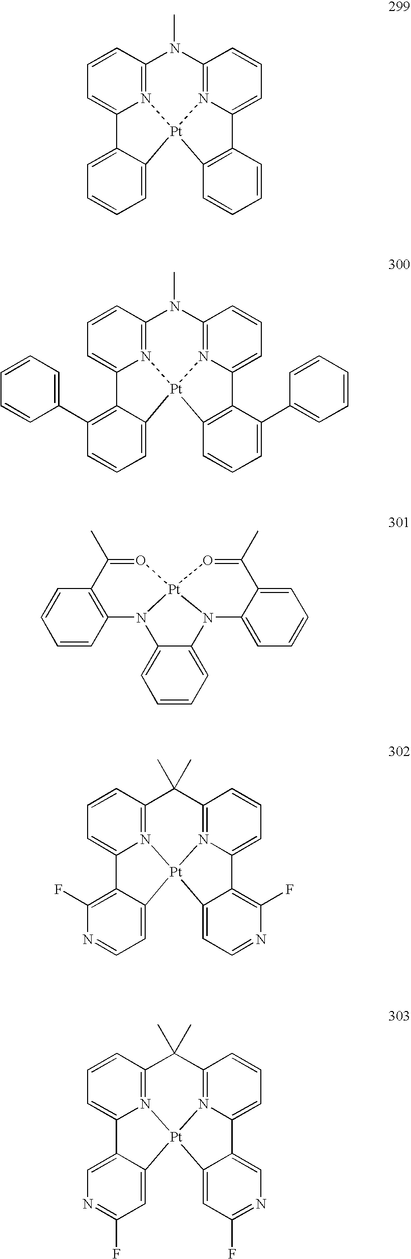

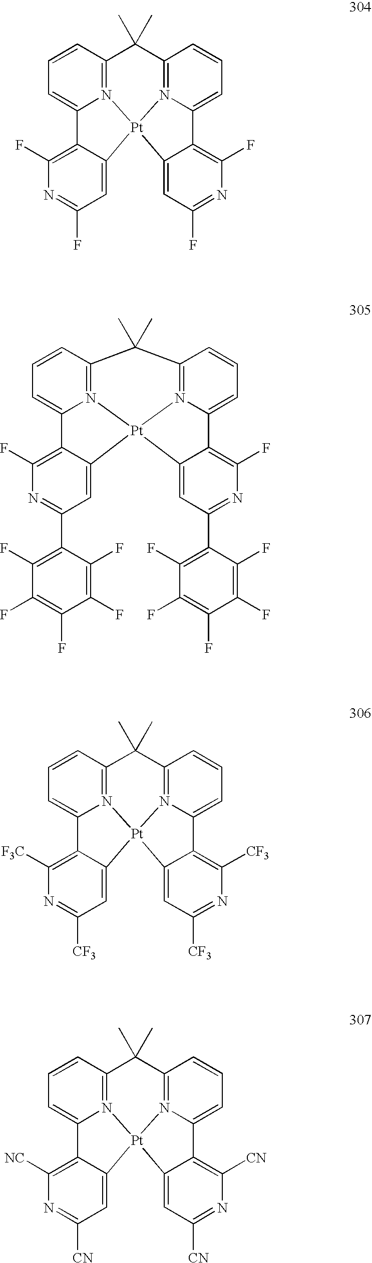

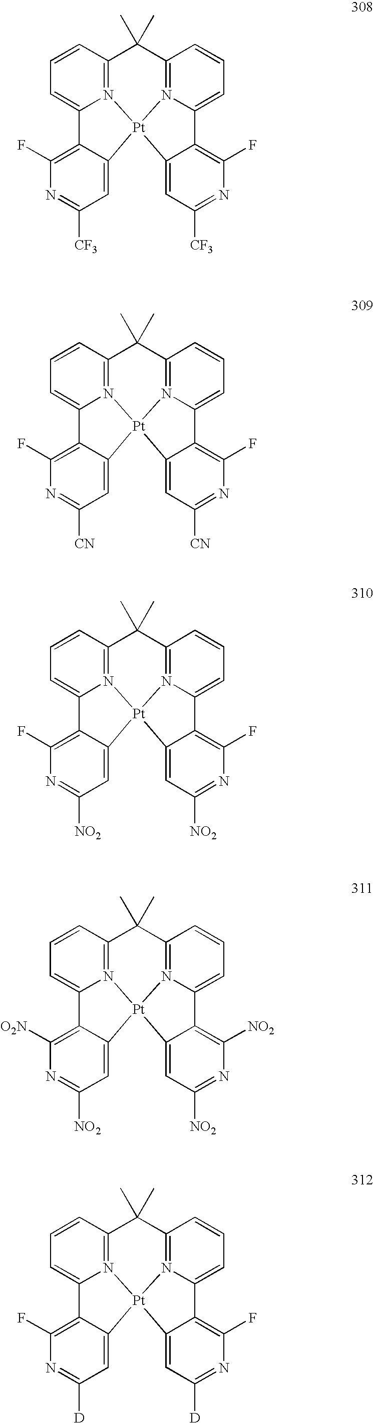

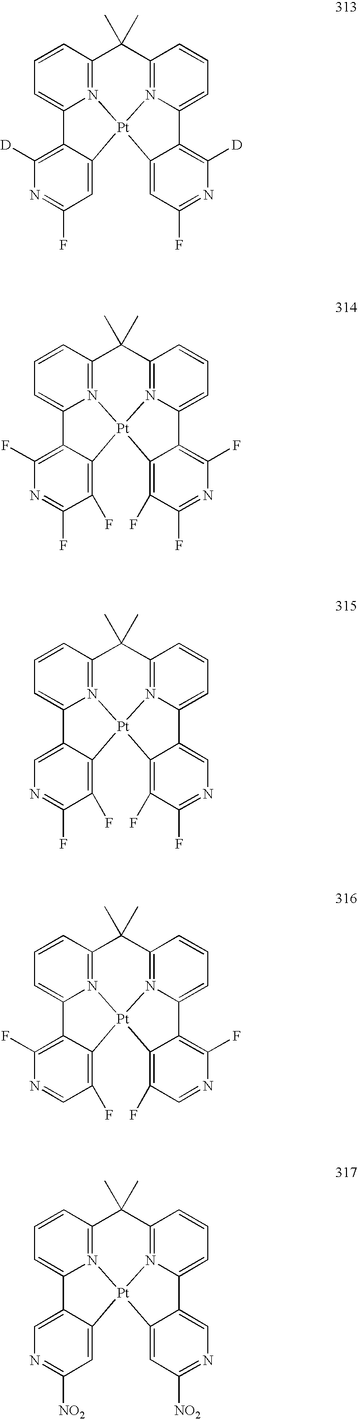

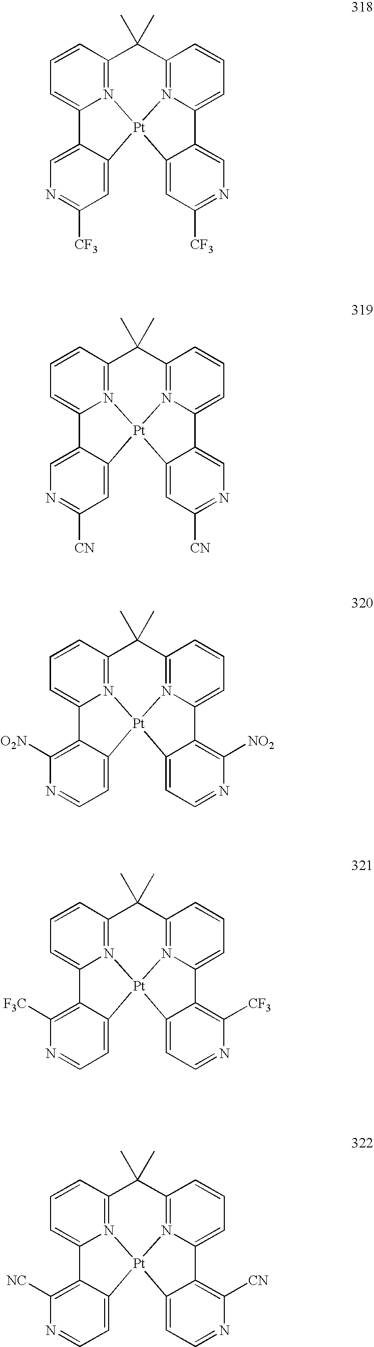

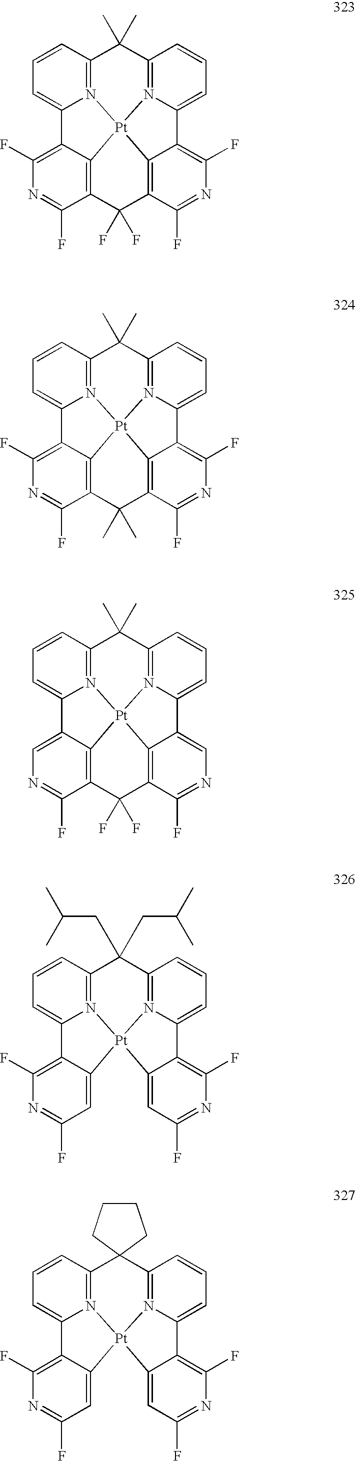

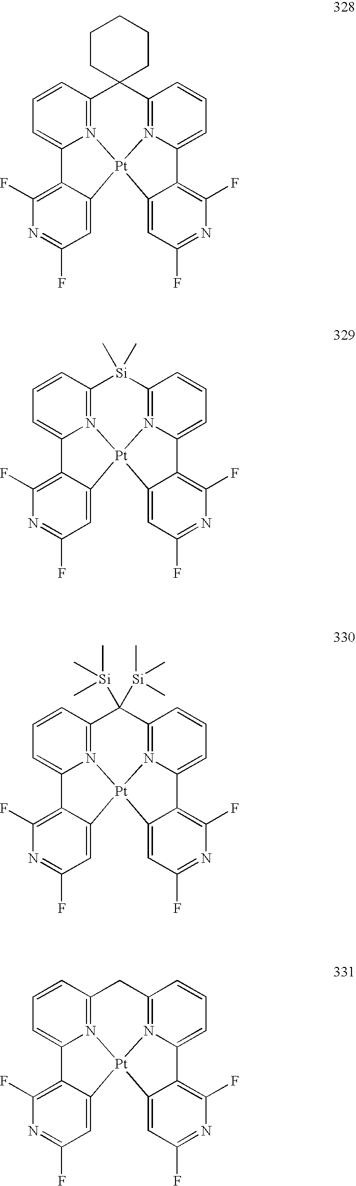

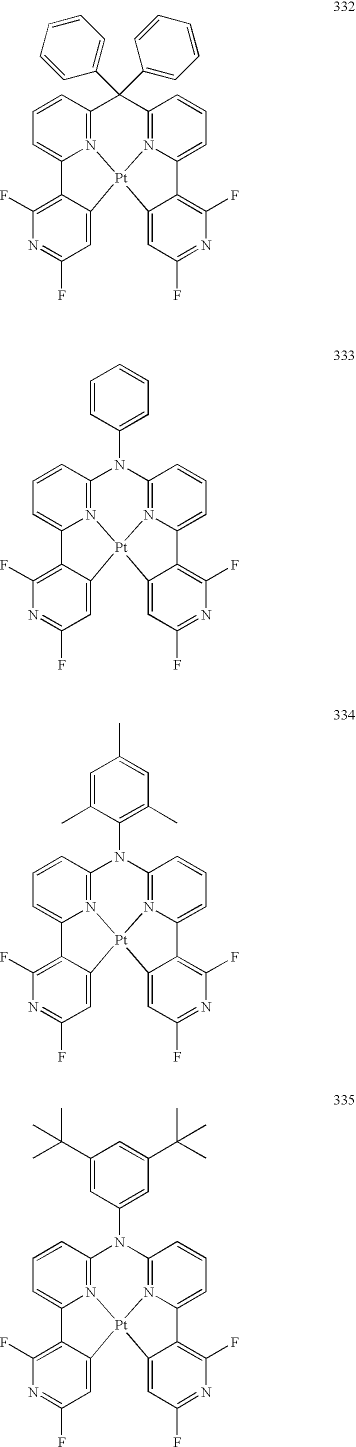

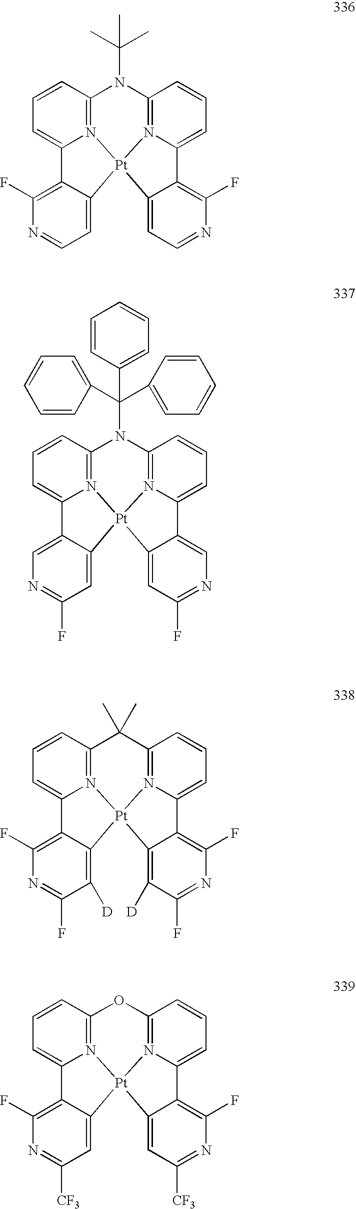

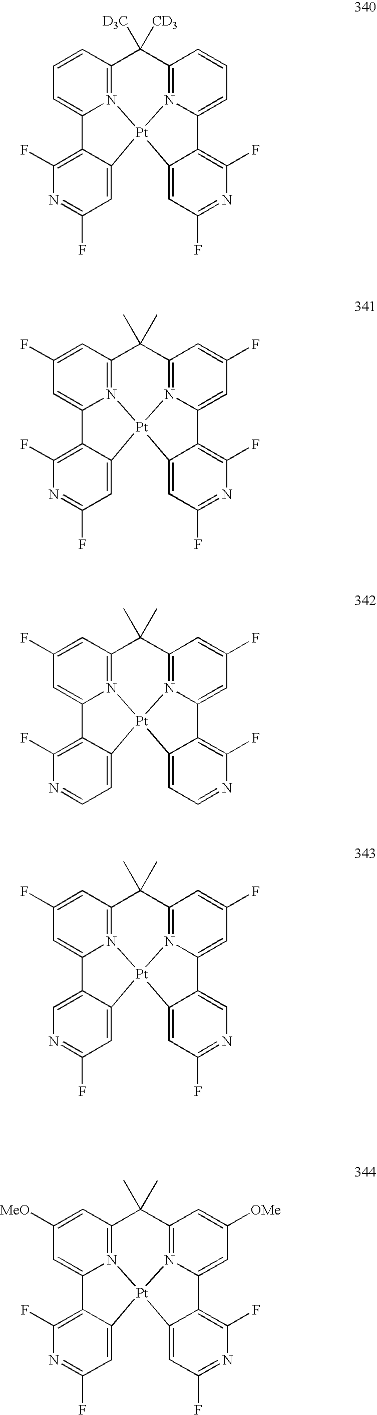

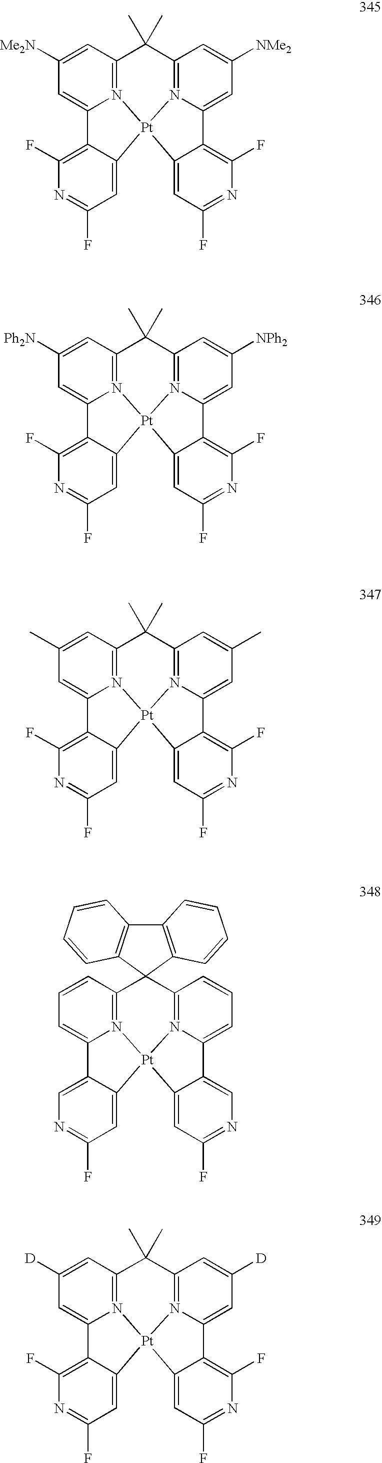

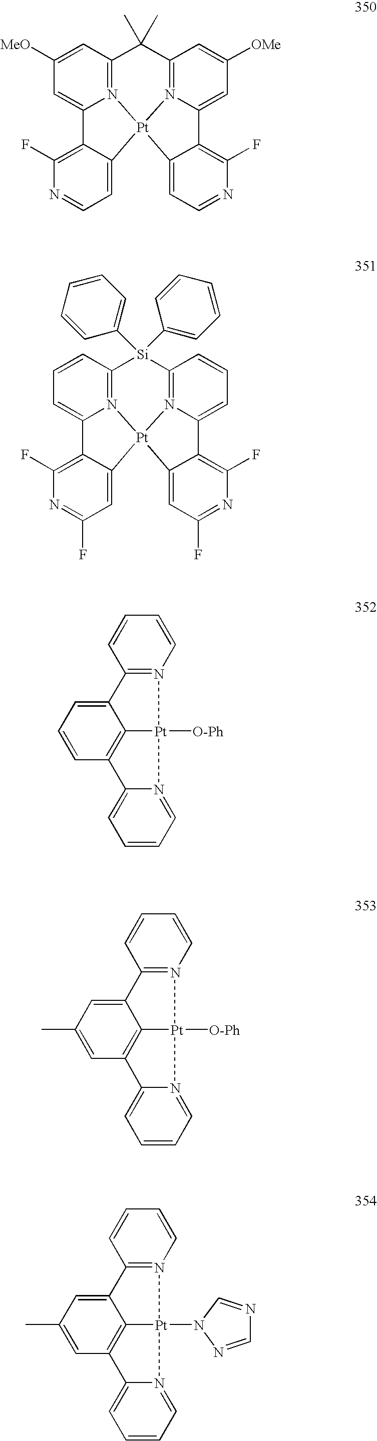

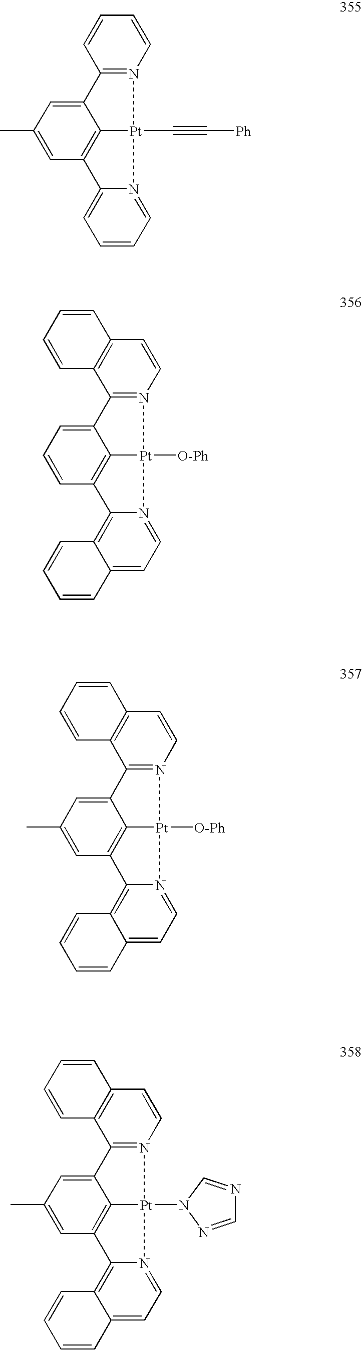

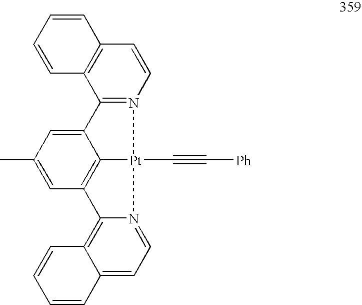

At least 3 luminescence materials used in the invention can be selected from the compounds described above, and specific examples of the blue luminescence material having a luminescence peak wavelength of 400 nm or more and less than 500 nm, the green luminescence material having a luminescence peak wavelength of 500 nm or more and less than 570 nm, and the red luminescence material having a luminescence peak wavelength of 570 to 670 nm include the following exemplary compounds, but the invention is not limited thereto.

<Specific Examples of the Blue Luminescence Material Having a Luminescence Peak Wavelength of 400 Nm or More and Less than 500 Nm>

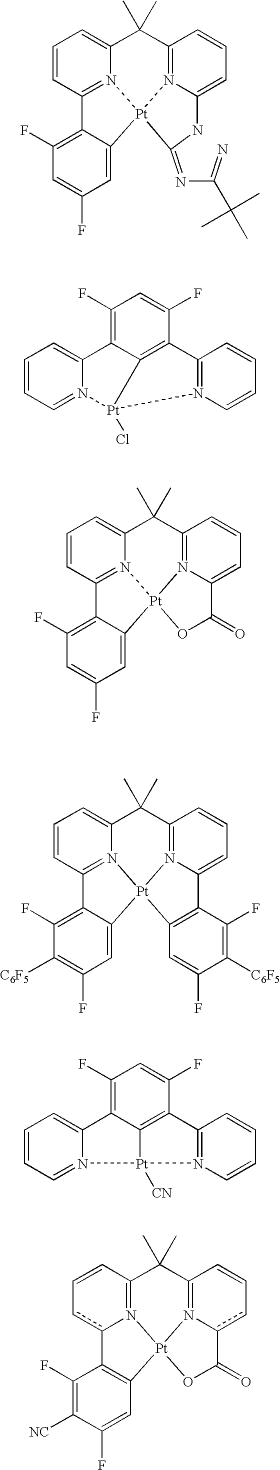

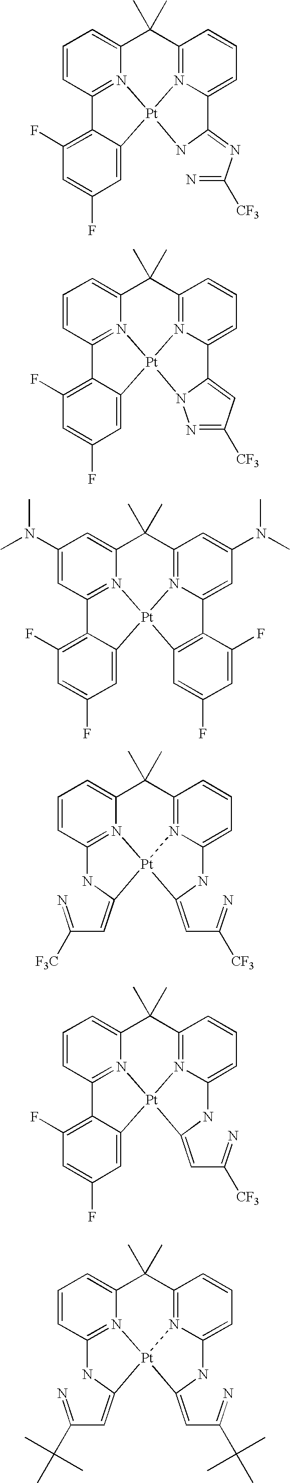

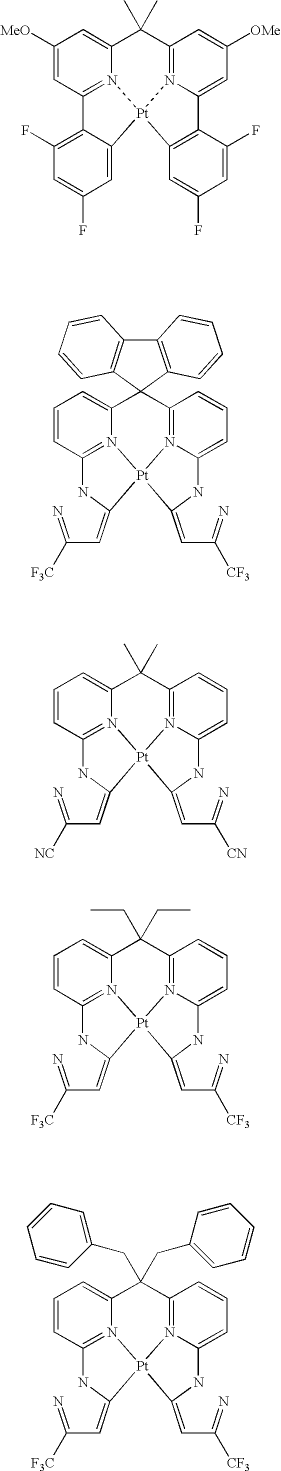

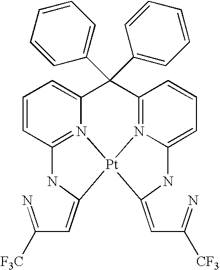

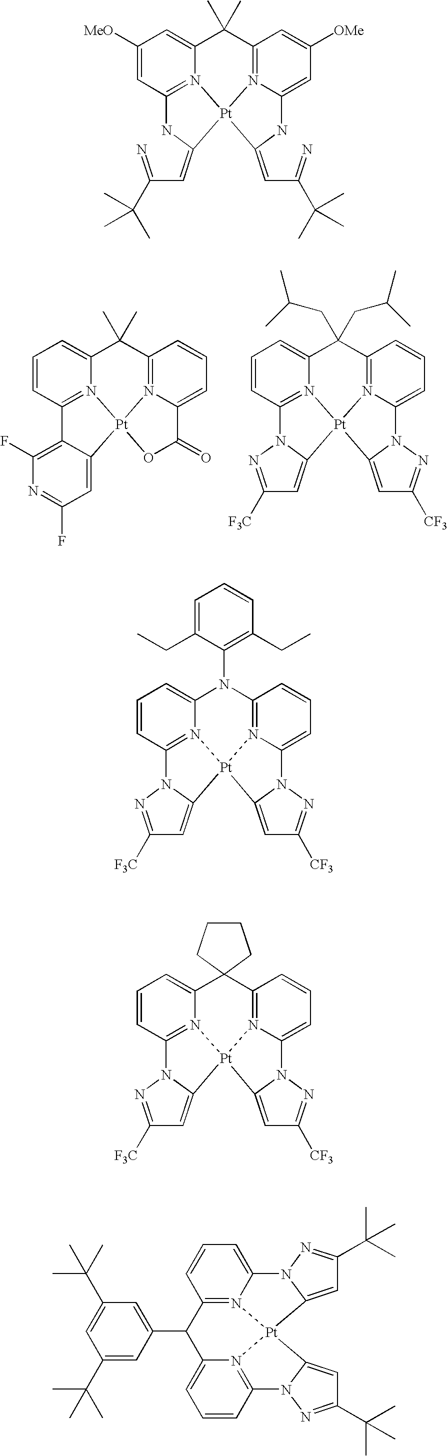

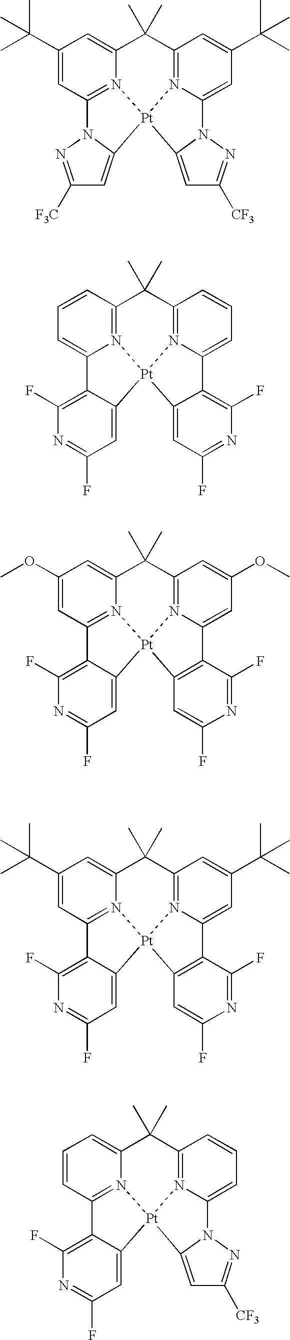

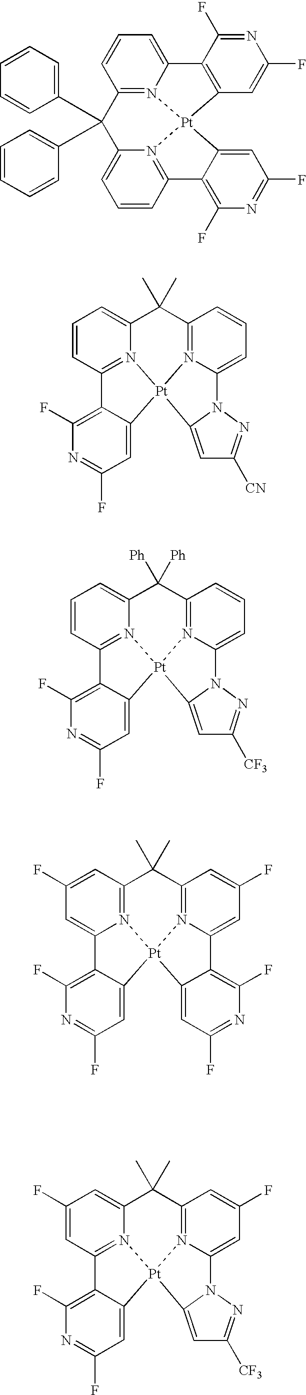

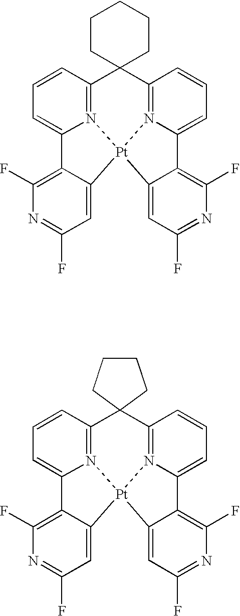

<Specific Examples of the Green Luminescence Material Having a Luminescence Peak Wavelength of 500 Nm or More and Less than 570 Nm>

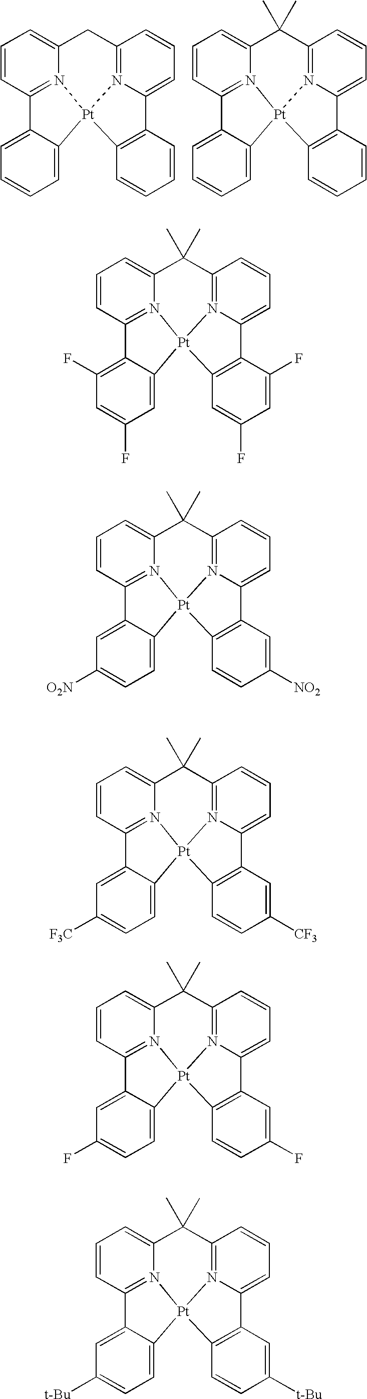

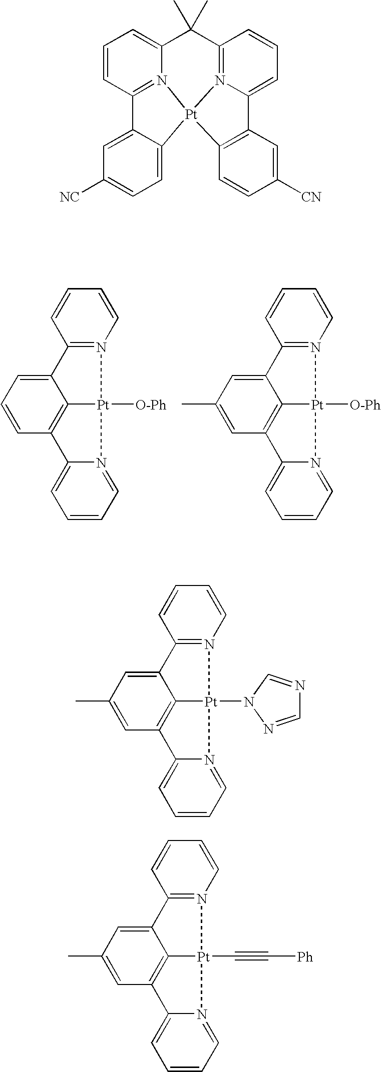

<Specific Examples of the Red Luminescence Material Having a Luminescence Peak Wavelength of 570 to 670 Nm>

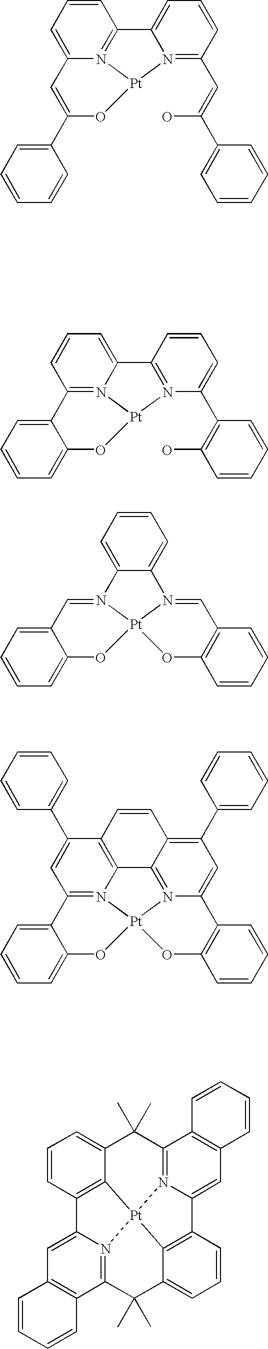

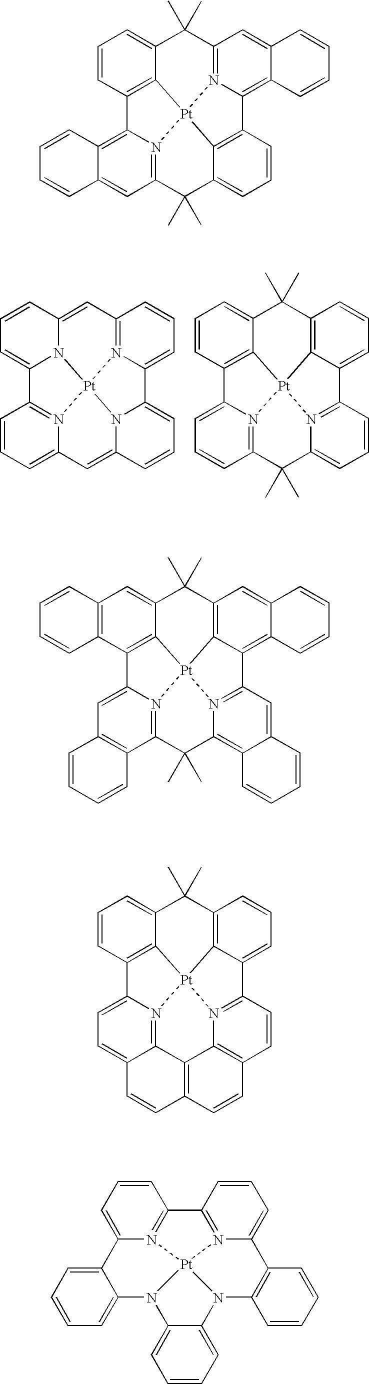

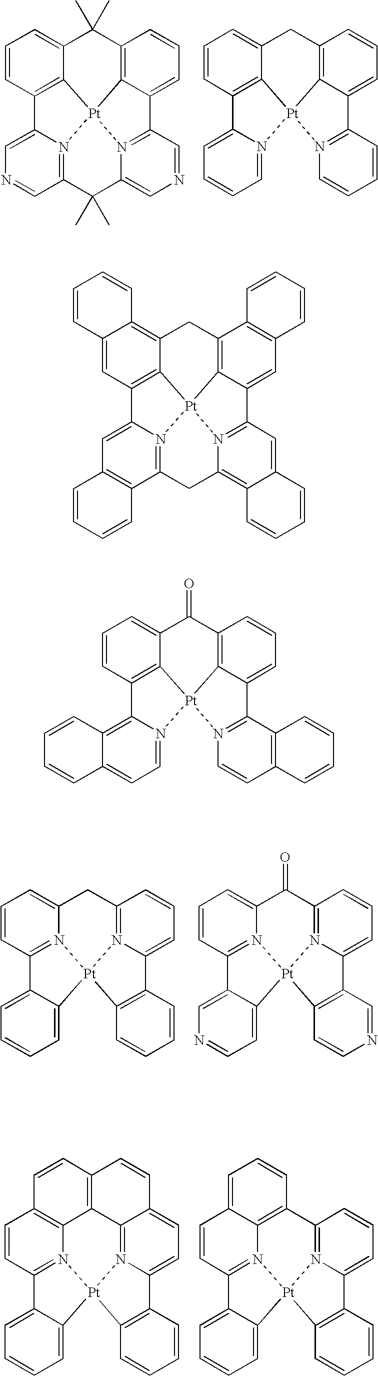

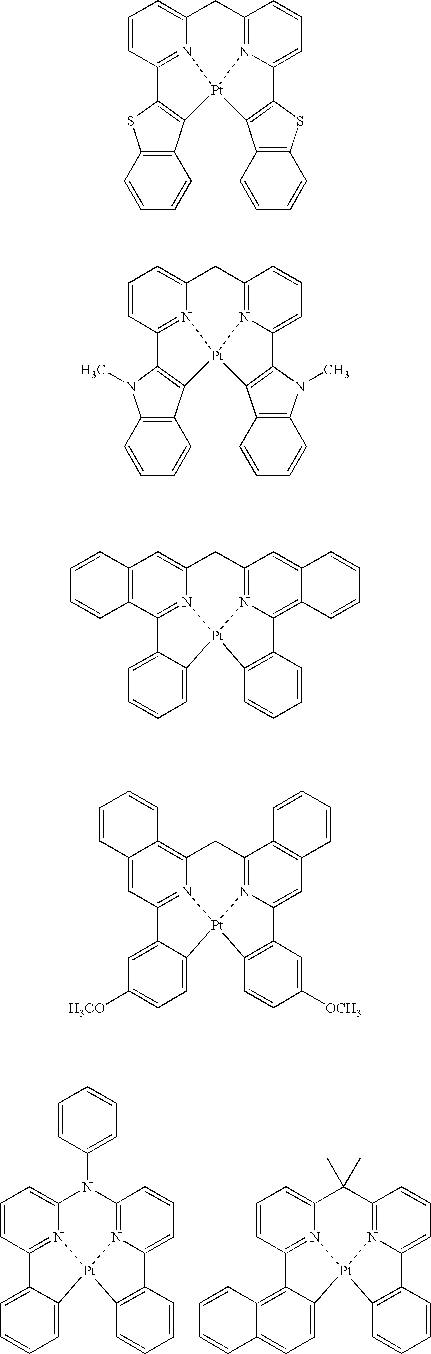

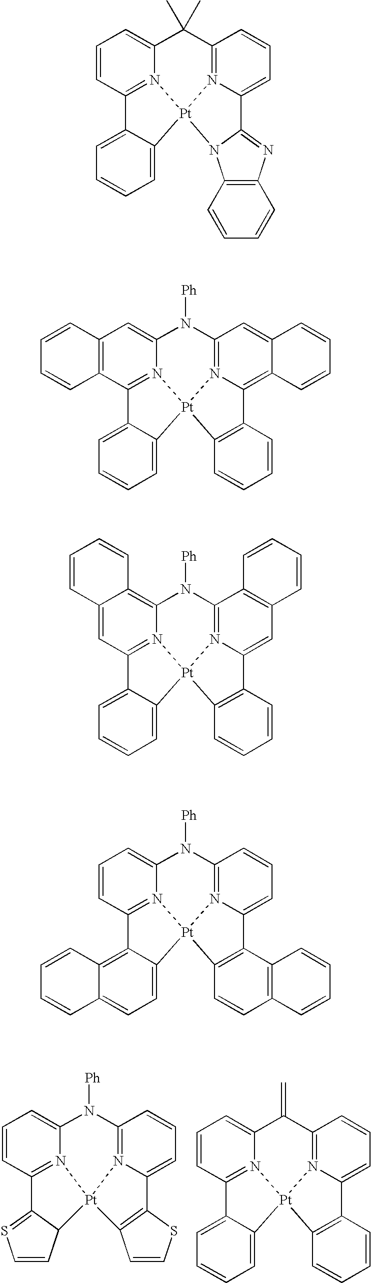

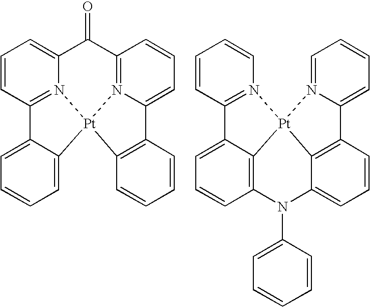

<Host Material>

The luminescence layer in the invention preferably contains a host material with the above described luminescence material as a guest. As the host material, either an electron transporting host material or a hole transporting host material may be used in the invention.

The luminescence material in the invention is an electron transporting fluorescence material, and the luminescence layer containing the electron transporting fluorescence material preferably contains a hole transporting host material.

Hereinafter, the hole transporting host material will be described.

<<Hole Transporting Host Material>>

From the viewpoint of improving durability and of reducing driving voltage, the hole transporting host material used in the luminescence layer of the invention, the ionization potential Ip is preferably 5.1 eV to 6.4 eV, more preferably 5.4 eV to 6.2 eV, even more preferably 5.6 eV to 6.0 eV. From the viewpoint of improving durability and of reducing driving voltage, the electron affinity Ea is preferably 1.2 eV to 3.1 eV, more preferably 1.4 eV to 3.0 eV, even more preferably 1.8 eV to 2.8 eV.

Such hole transporting host material can include, for example, conductive polymer oligomers such as pyrrole, carbazole, indole, pyrazole, imidazole, polyaryl alkane, pyrazoline, pyrazolone, phenylene diamine, arylamine, amino-substituted chalcone, styryl anthracene, fluorenone, hydrazone, stilbene, silazane, aromatic tertiary amine compounds, styryl amine compounds, aromatic dimethylidine compounds, porphyrin compounds, polysilane compounds, poly(N-vinylcarbazole), aniline copolymers, thiophene oligomers, and polythiophene, and organic silane, carbon film and derivatives thereof.

Among them, carbazole derivatives, indole derivatives, aromatic tertiary amine compounds and thiophene derivatives are preferable, and particularly those having in a molecule plural carbazole skeletons and/or indole skeletons and/or aromatic tertiary amine skeletons are preferable. Those having carbazole skeletons and/or indole skeletons are more preferable.

Specific compounds of such hole transporting host materials include, but are not limited to, the following compounds:

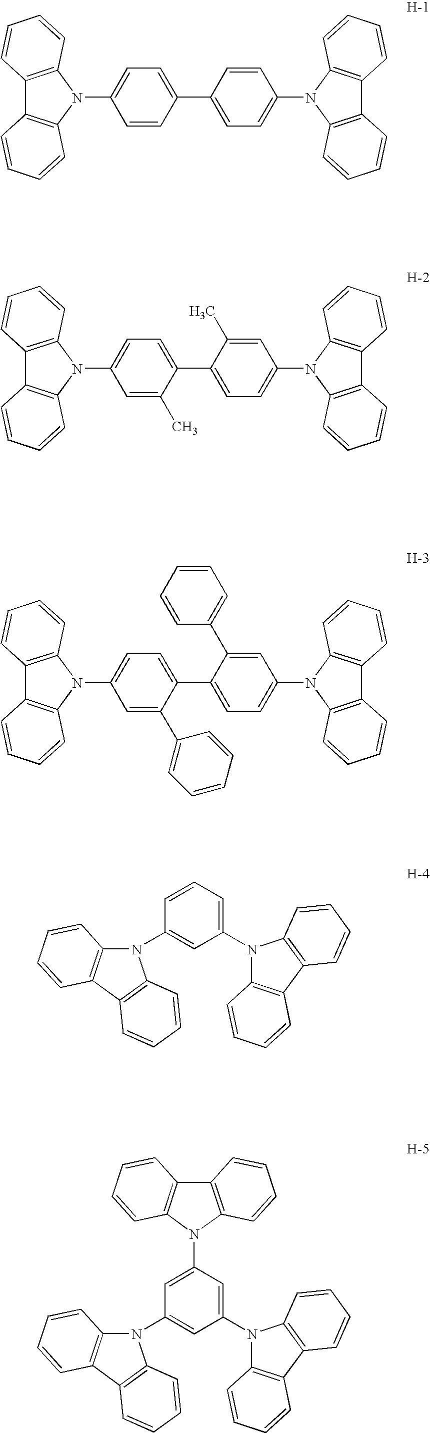

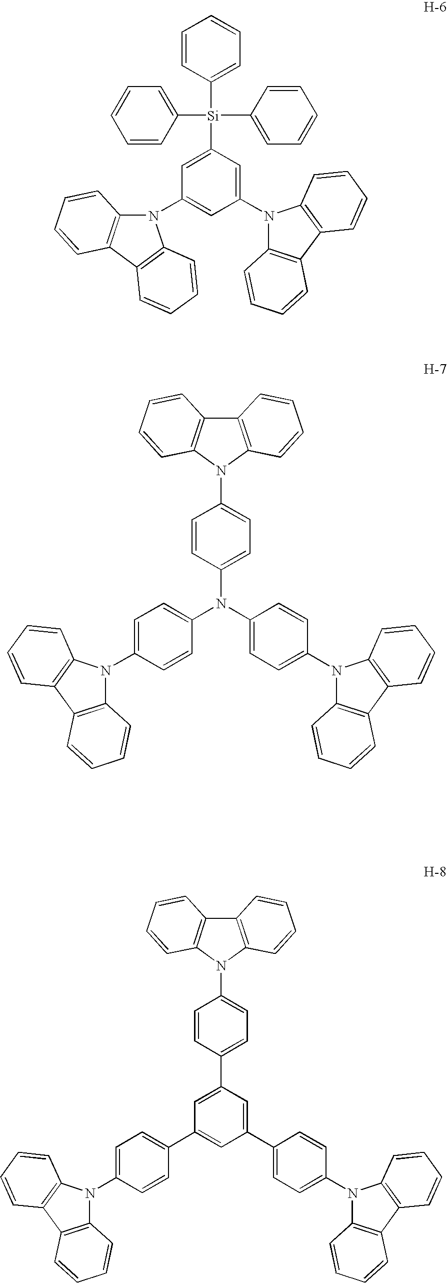

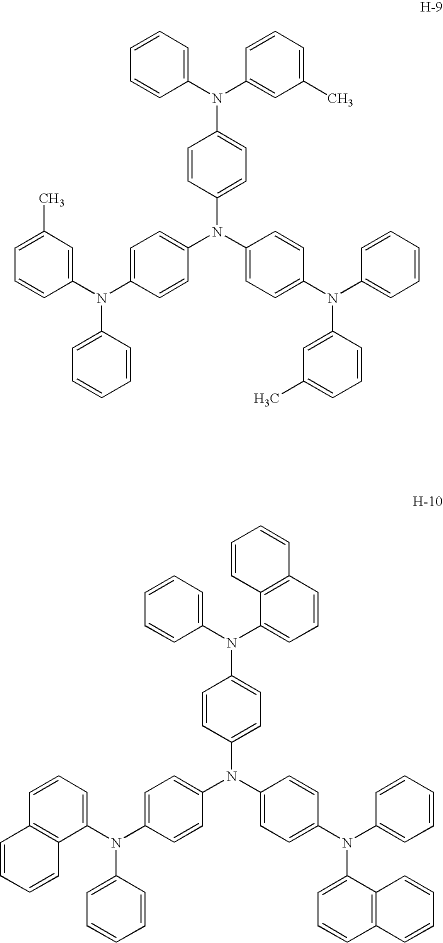

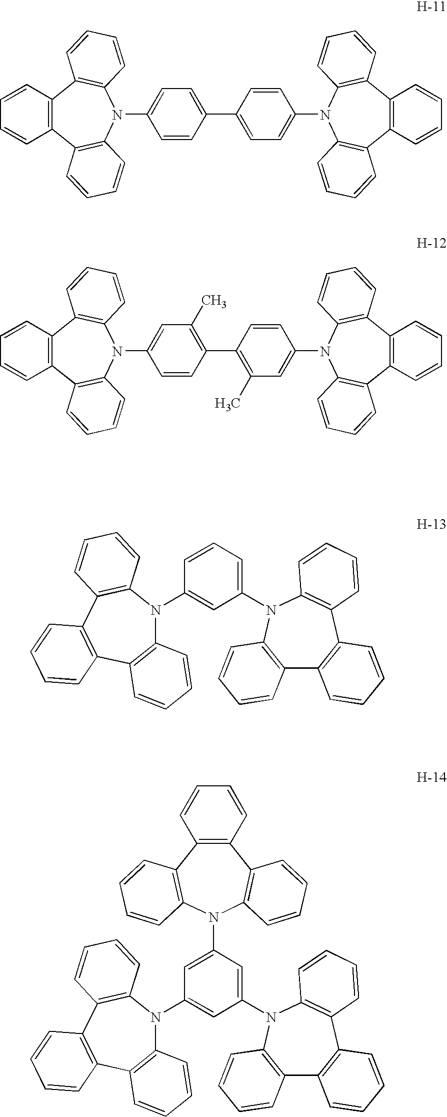

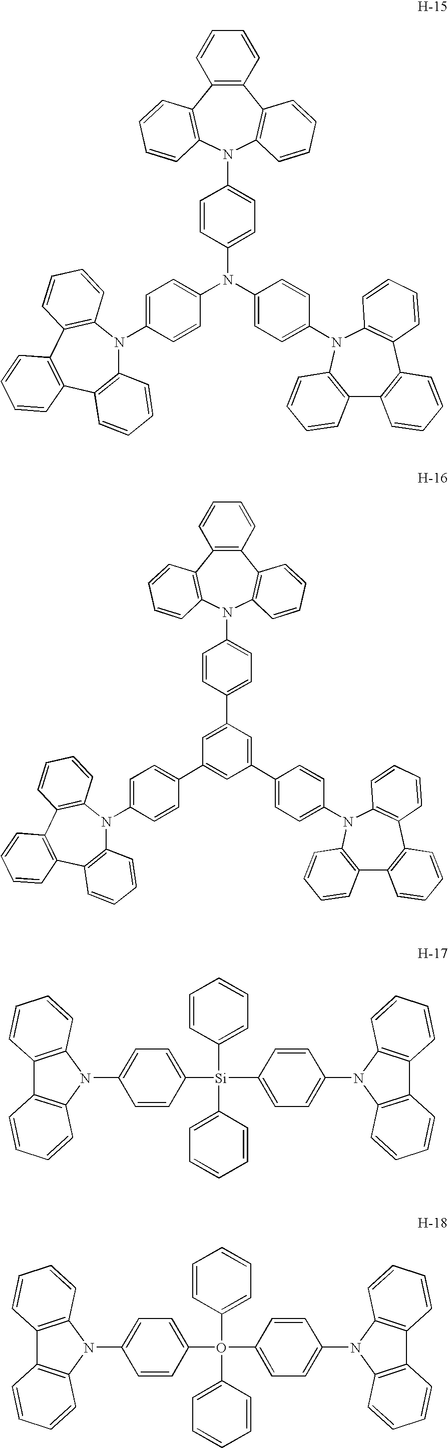

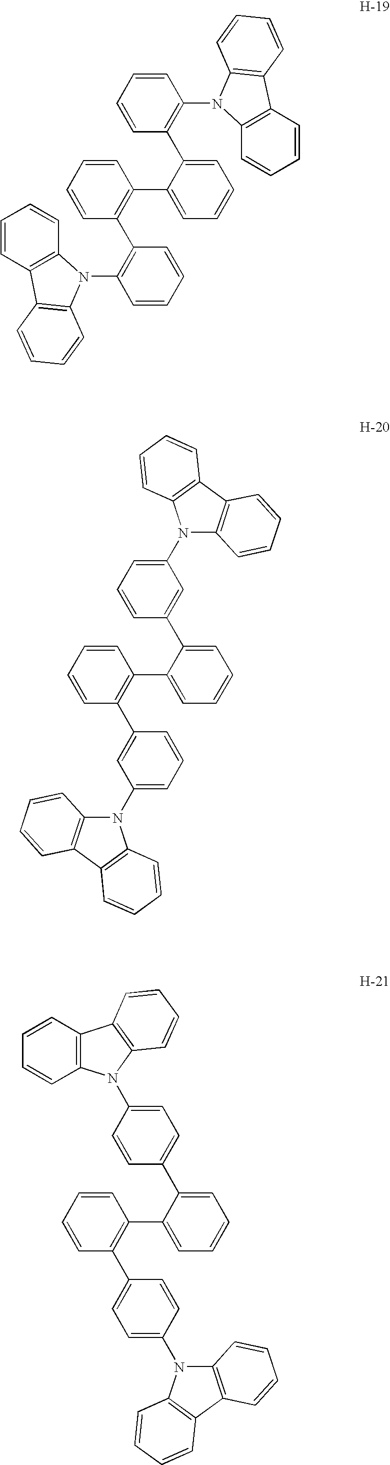

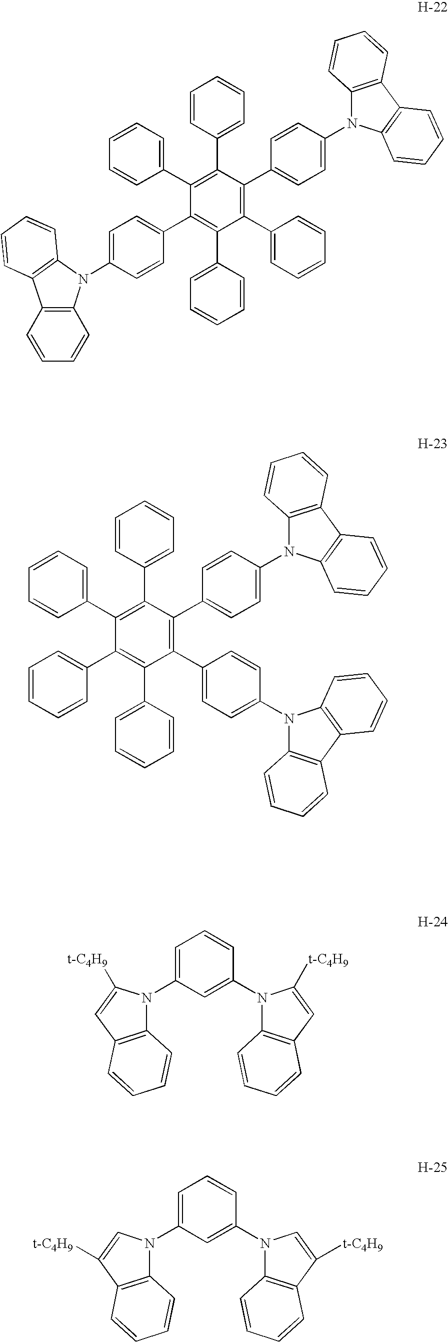

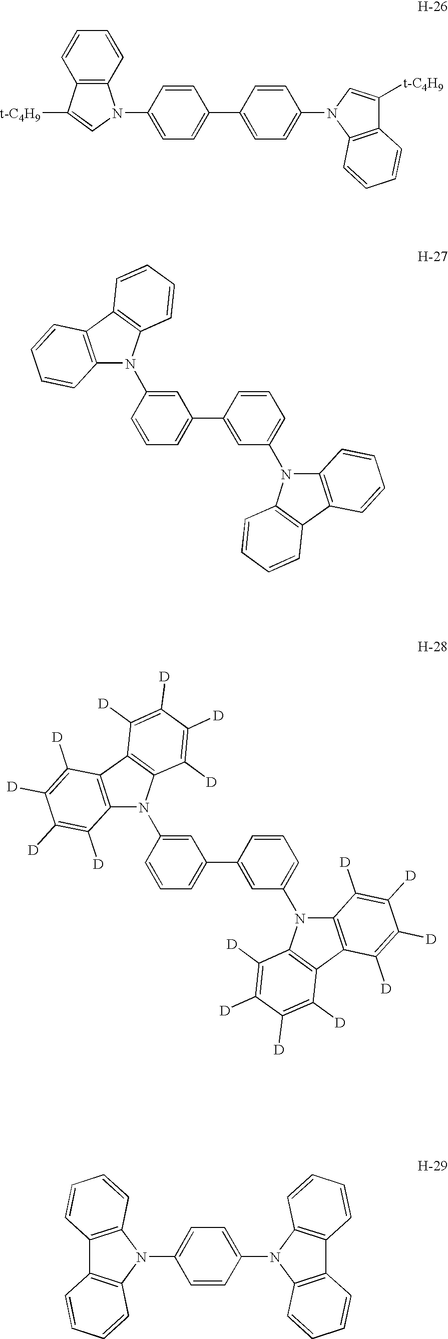

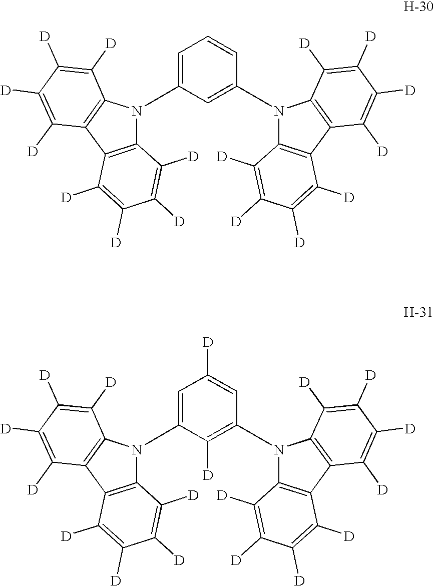

(Hole Injecting Layer, Hole Transporting Layer)

The hole injecting layer and the hole transporting layer are layers having a function of accepting holes from the anode or from the side of the anode and transporting them to the side of the cathode. The material used in the hole injecting layer and hole transporting layer in the invention includes not only interlocked compounds but also other hole injecting materials and hole transporting materials. These hole injecting materials and hole transporting materials may be low-molecular or high-molecular compounds

The hole injecting layer and the hole transporting layer are preferably layers containing specifically, for example, pyrrole derivatives, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stylbene derivatives, silazene derivatives, aromatic tertiary amine compounds, styrylamine compounds, aromatic dimethylidine compounds, phthalocyanine compounds, porphiline compounds, thiophene derivatives, organic silane derivatives, and carbon.

The hole injecting layer or hole transporting layer in the organic EL device of the invention may contain an electron accepting dopant. The electron accepting dopant introduced into the hole injecting layer or the hole transporting layer may be an inorganic or organic compound as long as accepting electrons and having a property of oxidizing an organic compound.

Specifically, the inorganic compound includes metal halides such as ferric chloride, aluminum chloride, gallium chloride, indium chloride, and antimony pentachloride, and metal halides such as vanadium pentaoxide and molybdenum trioxide.

In the case of the organic compound, a compound having, as a substituent, a nitro group, halogen, a cyano group or a trifluoromethyl group, or a quinone compound, an acid anhydride compound, or fullerene can be preferably used.

Compounds described in JP-A Nos. 6-212153, 11-111463, 11-251067, 2000-196140, 2000-286054, 2000-315580, 2001-102175, 2001-160493, 2002-252085, 2002-25985, 2003-157981, 2003-217862, 2003-229278, 2004-342614, 2005-72012, 2005-166637 and 2005-209643 can also be used.

These electron accepting dopants may be used alone or as two or more thereof. The amount of the electron accepting dopant used varies depending on the material used, but is preferably 0.01 to 50% by weight, more preferably 0.05 to 20% by weight, even more preferably 0.1 to 10% by weight, based on the hole transporting layer material.

The thickness of the hole injecting layer and the hole transporting layer is preferably each 500 nm or less from the viewpoint of lowering the driving voltage.

The thickness of the hole transporting layer is preferably from 1 nm to 500 nm, more preferably from 5 nm to 200 nm, further preferably from 10 nm to 100 nm. Further, the thickness of the hole injecting layer is preferably from 0.1 nm to 200 nm, more preferably from 0.5 nm to 100 nm, further preferably from 1 nm to 100 nm.

The hole injecting layer and the hole transporting layer may be a single layered structure comprising one or more of the materials described above or may be of a multi-layered structure comprising plural layers of an identical composition or different kinds of compositions.

(Electron Injecting Layer, Electron Transporting Layer)

The electron injecting layer and the electron transporting layer are layers having a function of accepting electron from the cathode or from the side of the cathode and transporting them to the side of the anode.

The electron injecting material and the electron transporting material used in the invention may be low-molecular or high-molecular compounds.

The layer is preferably a layer containing metal complex having pyridine derivatives, quinoline derivatives, pyrimidine derivatives, pyrazine derivatives, phthalazine derivatives, phenanthroline derivatives, triazine derivatives, triazole derivatives, oxazole derivatives, oxadiazole derivatives, imidazole derivatives, fluorenone derivatives, anthraquinodimethane derivatives, anthron derivatives, diphenylquinone derivatives, thiopyrane dioxide derivatives, carbodiimide derivatives, fluorenylidene methane derivatives, distyrylpyradine derivatives, aromatic ring tetracarboxylic acid anhydrides such as naphthalene and perylene, phthalocyanine derivatives, and 8-quinolinole derivatives, and metal complex having metal phthalocyanine, benzoxazole, or benzothiazole as the ligand, organic silane derivatives represented by silole.

The thickness of the electron injecting layer and the electron transporting layer is preferably from 500 nm or less from the viewpoint of lowering the driving voltage.

The thickness of the electron transporting layer is preferably from 1 nm to 500 nm, more preferably from 5 nm to 200 nm, further preferably from 10 nm to 100 nm. Further, the thickness of the electron injecting layer is preferably from 0.1 nm to 200 nm, more preferably from 0.2 nm to 100 nm, further preferably, from 0.5 nm to 50 nm.

The electron injecting layer and the electron transporting layer may be of a single layered structure comprising one or more of the materials described above or a multi-layered structure comprising plural layers each of an identical composition or different kinds of compositions.

(Hole Blocking Layer)

The hole blocking layer is a layer having a function of preventing holes transported from the anode to the luminescence layer from passing through to the side of the cathode. In the invention, the hole blocking layer can be provided as an organic layer adjacent with the luminescence layer on the side of the cathode.

Examples of the compound constituting the hole blocking layer include aluminum complexes such as BAlq, triazole derivatives, and phenanthroline derivatives such as BCP.

The thickness of the hole blocking layer is preferably from 1 nm to 500 nm, more preferably 5 nm to 200 nm, further preferably from 10 nm to 100 nm.

The hole blocking layer may be of a single layered structure comprising one or more kinds of the materials described above or a multi-layered structure comprising plural layers each of an identical composition or different kinds of compositions.

(Electron Blocking Layer)

The electron blocking layer is a layer having a function of preventing electrons transported to the luminescence layer from the cathode to pass through to the side of the anode. In the invention, the electron blocking layer can be provided as an organic layer adjacent with the luminescence layer on the side of the anode.

Examples of compounds constituting the electron blacking layers include, for example, the hole transporting materials described above.

The thickness of the electron blocking layer is preferably from 1 nm to 500 nm, more preferably from 5 nm to 200 nm, further preferably from 10 nm to 100 nm.

The hole blocking layer may be of a single layered structure comprising one or more kinds of the materials described above or a multi-layered structure comprising plural layers each of an identical composition or different kinds of compositions.

### (Protective Layer)

In the invention, the entire organic EL device may be protected by a protective layer.

The material contained in the protective layer may be any material of suppressing intrusion of moisture or oxygen into the device that promotes deterioration of the device.

Specific examples include metals such as In, Sn, Pb, Au, Cu, Ag, Al, Ti, and Ni, metal oxides such as MgO, SiO, SiO₂, Al₂O₃, GeO, NiO, CaO, BaO, Fe₂O₃, Y₂O₃, and TiO₂, metal nitrides such as SiNₓ and SiNₓO_{y}, metal fluorides such as MgF₂, LiF, AlF₃, and CaF₂, polyethylene, polypropylene, polymethyl methacrylate, polyimide, polyurea, polytetrafluoroethylene, polychlorotrifluoroethylene, polydichlorodifluoroethylene, copolymer of chlorotrifluoroethylene and dichlorodifluoroethylene, a copolymer obtained by copolymerizing tetrafluoroethylene and a monomer mixture containing at least one comonomer, a fluoro-containing copolymer having a cyclic structures in the copolymerization main chain, water absorbing material with a water absorptivity of 1% or more, and a moisture proofing material with a water absorptivity of 0.1% or less.

The method of forming the protective layer is not particularly limited, and for example, a vacuum vapor deposition method, a sputtering method, a reactive sputtering method, an MBE (Molecular Beam Epitaxy) method, a cluster ion beam method, an ion plating method, a plasma polymerization method (RF-excited ion plating method), a plasma CVD method, a laser CVD method, a thermal CVD method, a gas source CVD method, a coating method, a printing method, or a transfer method can be applied.

(Sealing)

The organic EL device of the invention may be sealed for the entire device by using a sealing vessel.

A water absorbent or an inert liquid may be sealed in a space between the sealing vessel and the luminescence device. The water absorbent is not particularly limited and includes, for example, barium oxide, sodium oxide, potassium oxide, calcium oxide, sodium sulfate, calcium sulfate, magnesium sulfate, phosphorous pentoxide, calcium chloride, magnesium chloride, copper chloride, cesium fluoride, niobium fluoride, calcium bromide, vanadium bromide, molecular sieve, zeolite, and magnesium oxide. The inert liquid is not particularly limited and includes, for example, paraffins, liquid paraffins, fluoro-solvents such as perfluoro alkanes or perfluoro amines and perfluoro ethers, chloro-solvents, and silicone oils.

(Driving)

Light emission can be obtained from the organic EL device of the invention by applying a DC (may optionally containing AC component) voltage (usually from 2 to 15 V), or a DC current between the anode and the cathode.

For the driving method of the organic EL device of the invention, a driving method described in JP-A Nos. 2-148687, 6-301355, 5-29080, 7-134558, 8-234685 and 8-241047, and in JP No. 2784615 and U.S. Pat. Nos. 5,828,429 and 6,023,308 can be applied.

The light extraction efficiency of the light emitting device of the invention can be improved by various known method. For example, the shape of the substrate surface is processed (for example, a fine concavoconvex pattern is formed), the refractive index of the substrate/ITO layer/organic layer is regulated, and the film thickness of the substrate/ITO layer/organic layer is regulated, whereby the light extraction efficiency can be improved and the external quantum efficiency can be improved.

The luminescence device of the invention may be a top emission system wherein emission is taken out from the anode side.

(Applications of the Invention)

The organic electroluminescence device of the invention can be applied preferably to display devices, displays, backlights, electronograph, illumination sources, recording light sources, exposure sources, reading light sources, markers, signboards, interior designs, optical communication, etc.

Exemplary embodiments of the invention will be illustrated below:

<1> An organic electroluminescence device comprising a pair of electrodes on a substrate and at least one organic layer containing a luminescence layer between the electrodes, the luminescence layer comprising at least 3 luminescence materials different in luminescent color, and the at least 3 luminescence materials being platinum complexes.

<2> The organic electroluminescence device of <1>, wherein the at least 3 luminescence materials are a blue luminescence material having a luminescence peak wavelength of 400 nm or more and less than 500 nm, a green luminescence material having a luminescence peak wavelength of 500 nm or more and less than 570 nm, and a red luminescence material having a luminescence peak wavelength of 570 to 670 nm.

<3> The organic electroluminescence device of <1> or <2>, wherein the at least 3 luminescence materials are platinum complexes having a tridentate ligand or a tetradentate ligand.

<4> The organic electroluminescence device of any one of <1> to <3>, wherein at least one of the at least 3 luminescence materials is at least one metal complex, wherein the metal complex has a tridentate or higher dentate ligand having a partial structure represented by the following formula (1), and the ligand is a linear ligand:

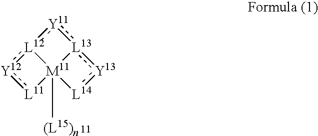

wherein in formula (1), M¹¹ represents a platinum ion; L¹¹, L¹², L¹³, L¹⁴ and L¹⁵ each independently represent a ligand coordinated to M¹¹; an atomic group may further be present between L¹¹ and L¹⁴, to form a cyclic ligand; L¹⁵ does not bond to both L¹¹ and L¹⁴ to form a cyclic ligand; Y¹¹, Y¹² and Y¹³ each independently represent a linking group, a single bond or a double bond; bonds between L¹¹ and Y¹², Y¹² and L¹², L¹² and Y¹¹, Y¹¹ and L¹³, L¹³ and Y¹³, and Y¹³ and L¹⁴ each independently represent a single bond or a double bond; and n¹¹ represents an integer from 0 to 4.

<5> The organic electroluminescence device of any one of <1> to <4>, wherein at least one of the 3 luminescence materials has a partial structure represented by the following formula (2):

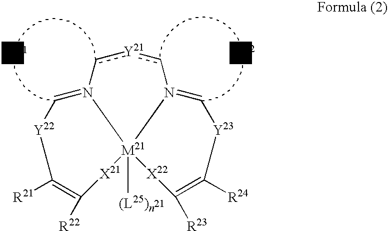

wherein in formula (2), M²¹ represents a platinum ion; Y²¹ represents a linking group, a single bond or a double bond; Y²² and Y²³ each independently represent a single bond or a linking group; Q²¹ and Q²² each independently represent an atomic group forming a nitrogen-containing heterocycle; a bond between a ring formed by Q²¹ and Y²¹, and a bond between a ring formed by Q²² and Y²¹, each independently represent a single bond or a double bond; X²¹ and X²² each independently represent an oxygen atom, a sulfur atom or a substituted or unsubstituted nitrogen atom; R²¹, R²², R²³ and R²⁴ each independently represent a hydrogen atom or a substituent; R²¹ and R²², or R²³ and R²⁴, may be bonded to each other to form a ring; L²⁵ represents a ligand coordinated to M²¹; and n²¹ represents an integer from 0 to 4.

<6> The organic electroluminescence device of any one of <1> to <5>, wherein at least one of the at least 3 luminescence materials is at least one platinum complex of a tetradentate ligand containing a partial structure represented by the following formula (3):

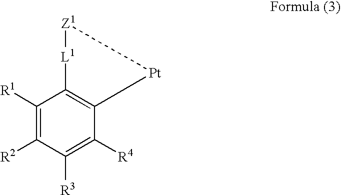

wherein Z¹ represents a nitrogen-containing heterocycle coordinated via a nitrogen atom to platinum; L¹ represents a single bond or a linking group; R¹, R³ and R⁴ each independently represent a hydrogen atom or a substituent; and R² represents a substituent.

<7> The organic electroluminescence device of <6>, wherein the platinum complex of a tetradentate ligand containing the plural structures represented by formula (3) is a platinum complex represented by the following formula (4):

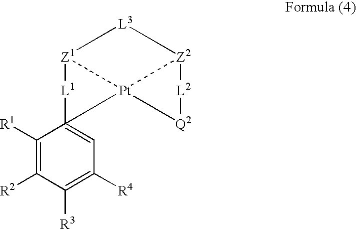

wherein in formula (4), Z¹ and Z² each independently represent a nitrogen-containing heterocycle coordinated via a nitrogen atom to platinum; Q² represents a group bonded to platinum via a carbon atom, an oxygen atom, a sulfur atom, a nitrogen atom or a phosphorus atom; L¹, L² and L³ each independently represent a single bond or a linking group; R¹, R³ and R⁴ each independently represent a hydrogen atom or a substituent; and R² represents a substituent.

<8> The organic electroluminescence device of <6>, wherein the platinum complex represented by formula (3) is a platinum complex represented by the following formula (5):

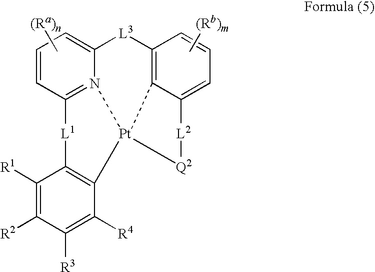

wherein in formula (5), Q² represents a group bonded to platinum via a carbon atom, an oxygen atom, a sulfur atom, a nitrogen atom or a phosphorus atom; L¹, L² and L³ each independently represent a single bond or a linking group; R¹, R³ and R⁴ each independently represent a hydrogen atom or a substituent; R² represents a substituent; R^{a} and R^{b} each independently represent a substituent; and n and m each independently represent an integer from 0 to 3.

<9> The organic electroluminescence device of <7>, wherein the platinum complex represented by formula (4) is a platinum complex represented by the following formula (6):

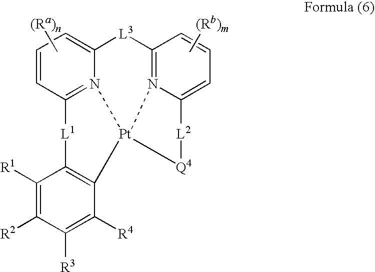

wherein in formula (6), Q⁴ represents an aromatic hydrocarbon cyclic group or an aromatic heterocyclic group which is bonded to platinum via a carbon atom or a nitrogen atom; L¹, L² and L³ each independently represent a single bond or a linking group; R¹, R³ and R⁴ each independently represent a hydrogen atom or a substituent; R² represents a substituent; R^{a} and R^{b} each independently represent a substituent; n and m each independently represent an integer from 0 to 3.

<10> The organic electroluminescence device of <9>, wherein the platinum complex represented by formula (6) is a compound represented by the following formula (7):

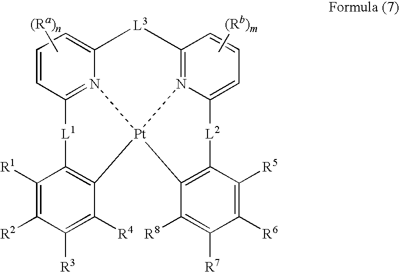

wherein in formula (7), L¹, L² and L³ each independently represent a single bond or a linking group; R¹, R³ and R⁴ each independently represent a hydrogen atom or a substituent; R² represents a substituent; R^{a} and R^{b} each independently represent a substituent; n and m each independently represent an integer from 0 to 3; R⁵, R⁷ and R⁸ each independently represent a hydrogen atom or a substituent; and R⁶ represents a substituent.

<11> The organic electroluminescence device of <1> to <10>, wherein the luminescence layer comprises a hole transporting host material.

### EXAMPLES

Hereinafter, the present invention will be described in more detail with reference to the Examples, but the invention is not limited to these examples.

1. Preparation of Organic EL Device

1) Preparation of Device 1 of the Invention

A glass substrate of 0.5 mm in thickness and 2.5 cm per side was placed in a washing container, washed by sonication in 2-propanol, and then treated with UV-ozone for 30 minutes. The following layers were deposited on this transparent anode. Unless particularly noted, the deposition rate in the Examples in the invention is 0.2 nm/sec. The deposition rate was measured with a crystal oscillator. The film thickness shown below is also measured with a crystal oscillator.

Anode: Indium tin oxide (abbreviated as ITO) was disposed in a film thickness of 100 nm on the glass substrate.

Hole transporting layer: Bis[N-(1-naphthyl)-N-phenyl]benzidine (abbreviated as α-NPD) was deposited in a thickness of 50 nm on the anode.

Luminescence layer: A hole transporting host material N,N′-dicarbazolyl-3,5-benzene (abbreviated as mCP) doped with 15% by weight of blue luminescence material B1, 0.5% by weight of green luminescence material G1 and 0.5% by weight of red luminescence material R1 was co-deposited in a thickness of 30 nm on the hole transporting layer.

Electron transporting layer: Bis-(2-methyl-8-quinolinolate)-4-(phenylphenolate) aluminum (abbreviated as BAlq) was deposited in a thickness of 40 nm on the luminescence layer.

Electron injecting layer: LiF was deposited in a thickness of 1 nm on the electron transporting layer.

Cathode: A patterned mask (a mask having a luminescence region of 2 mm×2 mm) was arranged on the electron injecting layer, and metal aluminum was deposited in a depth of 100 nm to form a cathode.

The prepared laminate was placed in globe box replaced with an argon gas, and sealed with a stainless-steel stealing can and with a UV-ray curable adhesive (XNR5516HV, manufactured by Nagase Chiba).

2) Preparation of Devices 2 to 7 of the Invention

The devices 2 to 7 of the invention were prepared in the same manner as in preparation of the device 1 of the invention except that the luminescence layer was changed as described below.

—Composition of Luminescence Layers—

Device 2 of the invention: A luminescence layer doped with 15% by weight of blue color emitting material B1, 0.5% by weight of green color emitting material G1 and 0.5% by weight of red color emitting material R2 with as mCP as a host material was used.

Device 3 of the invention: A luminescence layer doped with 15% by weight of blue color emitting material B1, 0.5% by weight of green color emitting material G1 and 0.5% by weight of red color emitting material R3 with mCP as a host material was used.

Device 4 of the invention: A luminescence layer doped with 15% by weight of blue color emitting material B1, 0.5% by weight of green color emitting material G2 and 0.5% by weight of red color emitting material R1 with mCP as a host material was used.

Device 5 of the invention: A luminescence layer doped with 15% by weight of blue color emitting material B1, 0.5% by weight of green color emitting material G3 and 0.5% by weight of red color emitting material R1 with mCP as a host material was used.

Device 6 of the invention: A luminescence layer doped with 15% by weight of blue color emitting material B2, 0.5% by weight of green color emitting material G1 and 0.5% by weight of red color emitting material R1 with mCP as a host material was used.

Device 7 of the invention: A luminescence layer doped with 15% by weight of blue color emitting material B3, 0.5% by weight of green color emitting material G1 and 0.5% by weight of red color emitting material R1 with mCP as a host material was used.

Device 8 of the invention: A luminescence layer doped with 15% by weight of blue color emitting material B1, 0.5% by weight of green color emitting material G1 and 0.5% by weight of red color emitting material R2 with H-1 in place of mCP as a host material was used.

Device 9 of the invention: A luminescence layer doped with 15% by weight of blue color emitting material B1, 0.5% by weight of green color emitting material G1 and 0.5% by weight of red color emitting material R2 with H-2 in place of mCP as a host material was used.

3) Preparation of Comparative Devices 1 to 6

The comparative devices 1 to 6 were prepared in the same manner as in preparation of the device 1 of the invention except that the fluorescence layer was changed as shown below.

—Composition of Luminescence Layer—

Comparative device 1: A luminescence layer doped with 15% by weight of Ir (piq)₃ (red luminescence material) with mCP as a host material was used.

Comparative device 2: A luminescence layer doped only with 15% by weight of red luminescence material R1 with mCP as a host material was used.

Comparative device 3: A luminescence layer doped with 15% by weight of Ir (ppy)₃ (green luminescence material) with mCP as a host material was used.

Comparative device 4: A luminescence layer doped only with 15% by weight of green luminescence material G1 with mCP as a host material was used.

Comparative device 5: A luminescence layer doped with 15% by weight of FIrpic (blue luminescence material) with mCP as a host material was used.

Comparative device 6: A luminescence layer doped only with 15% by weight of blue luminescence material B1 with mCP as a host material was used.

The comparative devices 1 to 6 described above are examples where the luminescence material is a single material.

4) Preparation of Comparative Devices 7 to 12

Comparative devices 7 to 12 were prepared in the same manner as in preparation of the device 1 of the invention except that the luminescence layer was changed as described below.

—Composition of Luminescence Layer—

Comparative device 7: A luminescence layer doped with 15% by weight of blue color emitting material B1, 0.5% by weight of green fluorescent material G1 and 0.5% by weight of Ir (piq)₃ (red color emitting material) with mCP as a host material was used.

Comparative device 8: A luminescence layer doped with 15% by weight of blue color emitting material B1, 0.5% by weight of Ir (ppy)₃ (green light emitting material) and 0.5% by weight of red color emitting material R1 with mCP as a host material was used.

Comparative device 9: A luminescence layer doped with 15% by weight of FIrpic (blue color emitting material), 0.5% by weight of green color emitting material G1 and 0.5% by weight of red color emitting material R1 with mCP as a host material was used.

Comparative device 10: A luminescence layer doped with 15% by weight of blue color emitting material B1, 0.5% by weight of Ir (ppy)₃ (green color emitting material) and 0.5% by weight of Ir (piq)₃ (red color emitting material) with mCP as a host material was used.

Comparative device 11: A luminescence layer doped with 15% by weight of FIrpic (blue color emitting material), 0.5% by weight of green color emitting material G1 and 0.5% by weight of Ir (piq)₃ (red color emitting material) with mCP as a host material was used.

Comparative device 12: A luminescence layer doped with 15% by weight of FIrpic (blue color emitting material), 0.5% by weight of Ir (ppy)₃ (green color emitting material) and 0.5% by weight of red color emitting material R1 with mCP as a host material was used.

Structures of the materials used in the Examples are shown below.

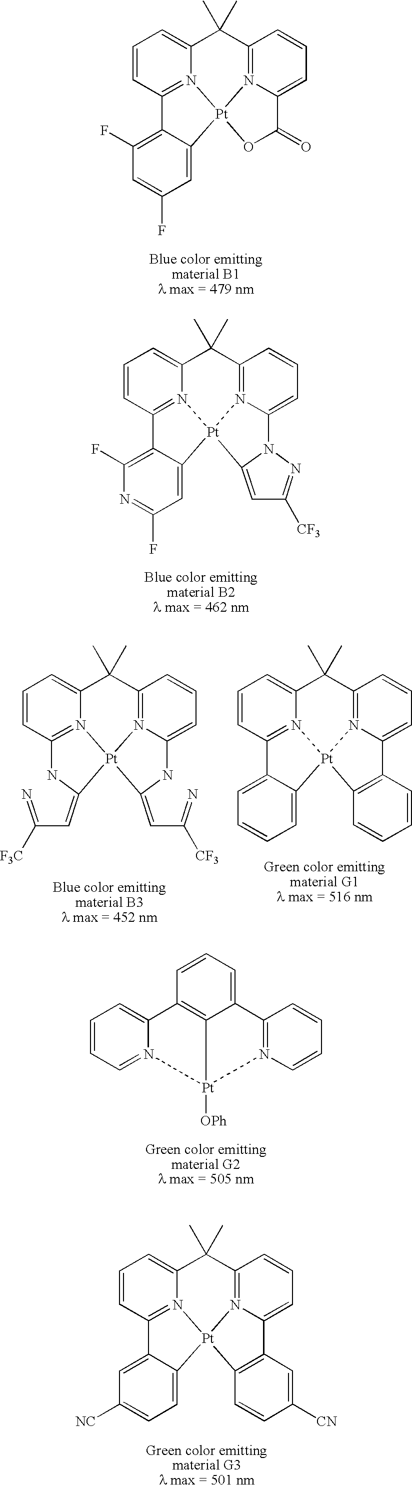

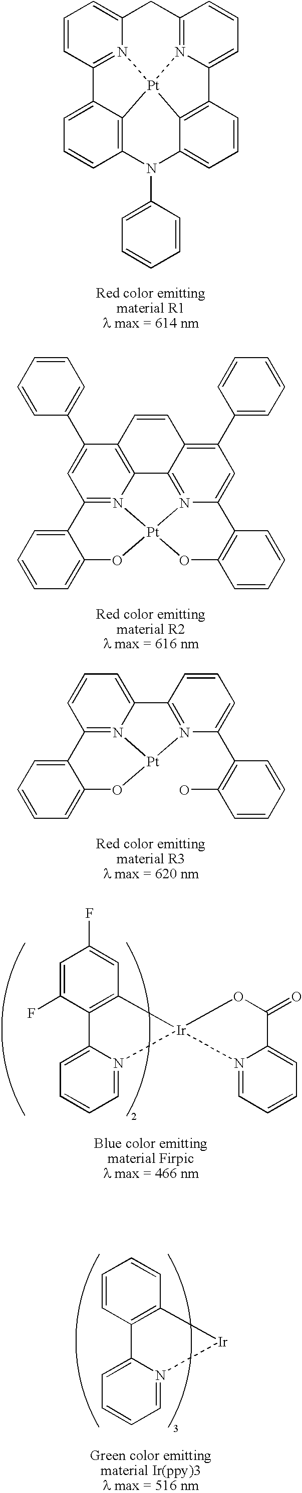

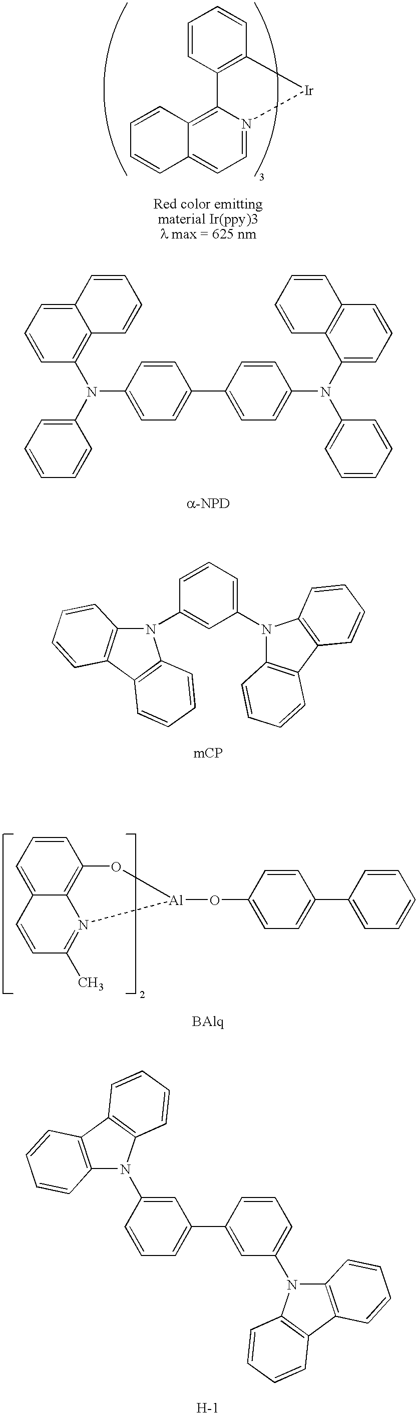

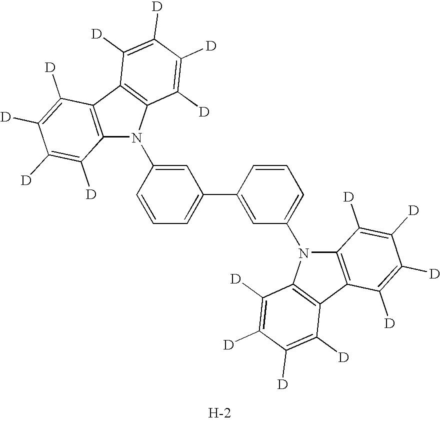

2. Evaluation of Performance

The organic EL devices of the invention and the comparative organic EL devices thus obtained were examined for their driving voltage in the following manner.

### —Measurement Conditions of Driving Voltage—

Using a source measure unit 2400 (manufactured by Toyo Technica Co.), DC voltage was applied to each device thereby emitting light. The voltage was measured as driving voltage with an intensity of 1000 cd/m².

The obtained results are shown in Table 1.

When the comparative devices 1 to 6 with each material used alone were compared, the comparative devices 2, 4 and 6 using platinum complexes are recognized to have a lower driving voltage by about 0.5 to 0.8 V than the comparative devices 1, 3 and 5 using complexes other than platinum. However, when the devices 1 to 6 of the invention wherein both the 3 colors are mixtures of platinum complexes are compared with the comparative devices 7 to 12 using mixtures of other complexes, the devices of the invention showed an unexpected effect of lowering a driving voltage by 3 V or more.

In the comparative devices 7, 8, and 10 to 12 wherein platinum complexes are mixed with indium complexes, abnormal light emission was recognized due to charge transfer complexes, and the light emission efficiency was lower than with the devices of the invention.

TABLE 1

| Device No. | Driving Voltage (V) |
|---|---|
| Device 1 of the Invention | 7.4 |
| Device 2 of the Invention | 7.5 |
| Device 3 of the Invention | 7.7 |
| Device 4 of the Invention | 7.8 |
| Device 5 of the Invention | 7.3 |
| Device 6 of the Invention | 7.4 |
| Device 7 of the Invention | 7.5 |
| Device 8 of the Invention | 7.7 |
| Device 9 of the Invention | 7.6 |
| Device 1 of the Comparative Example | 10.5 |
| Device 2 of the Comparative Example | 9.7 |
| Device 3 of the Comparative Example | 9.6 |
| Device 4 of the Comparative Example | 9.1 |
| Device 5 of the Comparative Example | 11.2 |
| Device 6 of the Comparative Example | 10.5 |
| Device 7 of the Comparative Example | 10.5 |
| Device 8 of the Comparative Example | 9.1 |
| Device 9 of the Comparative Example | 11.6 |
| Device 10 of the Comparative Example | 11.2 |
| Device 11 of the Comparative Example | 12.6 |
| Device 12 of the Comparative Example | 12.1 |

### Example 2

### 1. Preparation of Device 11 of the Invention

Device 11 of the invention was prepared in the same manner as in preparation of the device 1 of the invention except that the luminescence layer was changed to the following 3 layers.

—Composition of the Luminescence Layer—

A first luminescence layer, a second luminescence layer and a third luminescence layer were formed in this order on the hole transporting layer.

First luminescence layer: A luminescence layer doped with 15% by weight of blue color emitting material B1 with mCP as a host material was deposited in a thickness of 25 nm.
Second luminescence layer: A luminescence layer doped with 15% by weight of green color emitting material G1 with mCP as a host material was deposited in a thickness of 2.5 nm.
Third luminescence layer: A luminescence layer doped with 15% by weight of red color emitting material R1 with mCP as a host material was deposited in a thickness of 2.5 nm.

### 2. Evaluation of Performance

The driving voltage of the resulting device 11 was measured in the same manner as in Example 1.

As a result, the driving voltage was 8.1 V at 1000 cd/m². This driving voltage was higher than with the device of the invention in Example 1, but was significantly lower than with the comparative devices.

According to the invention, there is provided an organic fluorescence device with high fluorescence efficiency at low voltage.

Use of metal complexes as luminescence materials has been known. Particularly, iridium complexes have been disclosed as highly phosphorescence emission materials in JP-A Nos. 2001-319780 and 2004-14155. However, the iridium complexes are known to provide green and red luminescence materials, but are not known to provide blue luminescence materials. Accordingly, when white color is obtained by mixing of colors, a material other than the iridium complex should be selected as the blue luminescence material. However, there is a problem that a fluorescence material disclosed in JP-A No. 2004-14155 is inferior in emission frequency, and butadiene compounds or pyrene compounds described in JP-A No. 2001-319780 are also inferior in emission frequency and durability. When blue color emission, green color emission, and red color emission are mixed to form white color emission, when the balance of combination of these color emissions is changed, or when a color filter is combined with white color emission for full-color display, the emission of these 3 colors is required to be achieved without being balanced by change in driving conditions (for example, emission intensity, change in driving voltage, emission time, storage period after production, etc.).

The inventors extensively examined various phosphorescence metal complexes satisfying the above conditions, and as a result, unexpectedly found that the blue emission, green emission, and red emission can be constituted with only platinum complexes, to solve the problem.

The mechanism of constitution of color emission with only platinum complexes is not evident, and by the inventor's analysis, iridium complexes have low ionization potential (Ip) and are enriched in hole transportation, while platinum complexes are materials having high electron affinity (Ea) and enriched in electron transportation. For example, when a platinum complex is used as a blue luminescence material, iridium complexes are used as green luminescence material and red luminescence material, and these are used in combination, then they are different in electron transportation thus increasing the driving voltage or forming a charge-transfer complex (DA complex) thereby suppressing emission, increasing the driving voltage, and reducing the emission efficiency.

According to the invention, the blue light emission, green light emission and red light emission can be constituted with platinum complexes, so that the driving voltage can be kept low and the emission of the 3 colors can be kept with good balance, and as a result, high efficiency and low driving voltage could be realized.

What is claimed is:

1. An organic electroluminescence device comprising a pair of electrodes on a substrate and at least one organic layer containing a luminescence layer between the electrodes, the luminescence layer comprising at least 3 luminescence materials different in luminescent color, and the at least 3 luminescence materials being platinum complexes.

2. The organic electroluminescence device of claim 1, wherein the at least 3 luminescence materials are a blue luminescence material having a luminescence peak wavelength of 400 nm or more and less than 500 nm, a green luminescence material having a luminescence peak wavelength of 500 nm or more and less than 570 nm, and a red luminescence material having a luminescence peak wavelength of 570 to 670 nm.

3. The organic electroluminescence device of claim 1, wherein the at least 3 luminescence materials are platinum complexes having a tridentate ligand or a tetradentate ligand.

4. The organic electroluminescence device of claim 1, wherein at least one of the at least 3 luminescence materials is at least one metal complex, wherein the metal complex has a tridentate or higher dentate ligand having a partial structure represented by the following formula (1), and the ligand is a linear ligand: 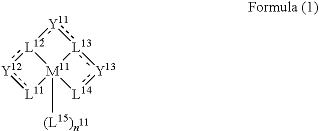
wherein in formula (1), M¹¹ represents a platinum ion; L¹¹, L¹², L¹³, L¹⁴ and L¹⁵ each independently represent a ligand coordinated to M¹¹; an atomic group may further be present between L¹¹ and L¹⁴, to form a cyclic ligand; L¹⁵ does not bond to both L¹¹ and L¹⁴ to form a cyclic ligand; Y¹¹, Y¹² and Y¹³ each independently represent a linking group, a single bond or a double bond; bonds between L¹¹ and Y¹², Y¹² and L¹², L¹² and Y¹¹, Y¹¹ and L¹³, L¹³ and Y¹³, and Y¹³ and L¹⁴ each independently represent a single bond or a double bond; and n¹¹ represents an integer from 0 to 4.

5. The organic electroluminescence device of claim 1, wherein at least one of the 3 luminescence materials has a partial structure represented by the following formula (2): 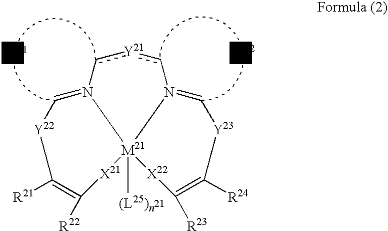
wherein in formula (2), M²¹ represents a platinum ion; Y²¹ represents a linking group, a single bond or a double bond; Y²² and Y²³ each independently represent a single bond or a linking group; Q²¹ and Q²² each independently represent an atomic group forming a nitrogen-containing heterocycle; a bond between a ring formed by Q²¹ and Y²¹, and a bond between a ring formed by Q²² and Y²¹, each independently represent a single bond or a double bond; X²¹ and X²² each independently represent an oxygen atom, a sulfur atom or a substituted or unsubstituted nitrogen atom; R²¹, R²², R²³ and R²⁴ each independently represent a hydrogen atom or a substituent; R²¹ and R²², or R²³ and R²⁴, may be bonded to each other to form a ring; L²⁵ represents a ligand coordinated to M²¹; and n²¹ represents an integer from 0 to 4.

6. The organic electroluminescence device of claim 1, wherein at least one of the at least 3 luminescence materials is at least one platinum complex of a tetradentate ligand containing a partial structure represented by the following formula (3): 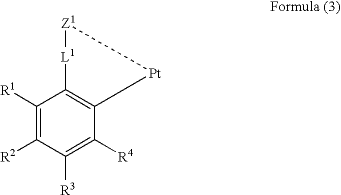
wherein in formula (3), Z¹ represents a nitrogen-containing heterocycle coordinated via a nitrogen atom to platinum; L¹ represents a single bond or a linking group; R¹, R³ and R⁴ each independently represent a hydrogen atom or a substituent; and R² represents a substituent.

7. The organic electroluminescence device of claim 6, wherein the platinum complex of a tetradentate ligand containing the partial structure represented by formula (3) is a platinum complex represented by the following formula (4): 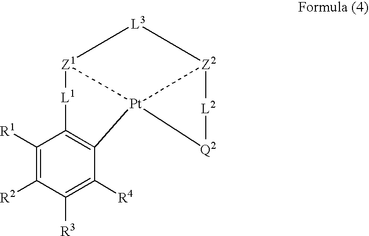
wherein in formula (4), Z¹ and Z² each independently represent a nitrogen-containing heterocycle coordinated via a nitrogen atom to platinum; Q² represents a group bonded to platinum via a carbon atom, an oxygen atom, a sulfur atom, a nitrogen atom or a phosphorus atom; L¹, L² and L³ each independently represent a single bond or a linking group; R¹, R³ and R⁴ each independently represent a hydrogen atom or a substituent; and R² represents a substituent.

8. The organic electroluminescence device of claim 6, wherein the platinum complex represented by formula (3) is a platinum complex represented by the following formula (5): 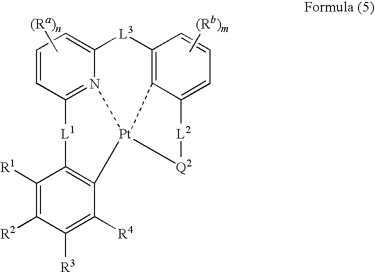
wherein in formula (5), Q² represents a group bonded to platinum via a carbon atom, an oxygen atom, a sulfur atom, a nitrogen atom or a phosphorus atom; L¹, L² and L³ each independently represent a single bond or a linking group; R¹, R³ and R⁴ each independently represent a hydrogen atom or a substituent; R² represents a substituent; R^{a} and R^{b} each independently represent a substituent; and n and m each independently represent an integer from 0 to 3.

9. The organic electroluminescence device of claim 7, wherein the platinum complex represented by formula (4) is a platinum complex represented by the following formula (6): 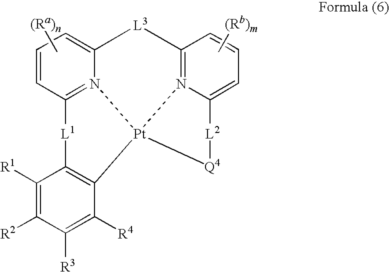
wherein in formula (6), Q⁴ represents an aromatic hydrocarbon cyclic group or an aromatic heterocyclic group which is bonded to platinum via a carbon atom or a nitrogen atom; L¹, L² and L³ each independently represent a single bond or a linking group; R¹, R³ and R⁴ each independently represent a hydrogen atom or a substituent; R² represents a substituent; R^{a} and R^{b} each independently represent a substituent; n and m each independently represent an integer from 0 to 3.

10. The organic electroluminescence device of claim 9, wherein the platinum complex represented by formula (6) is a compound represented by the following formula (7): 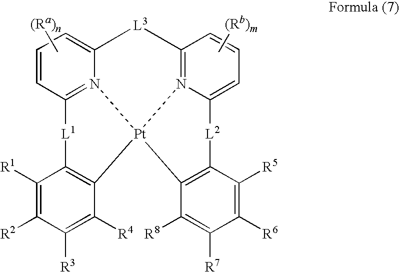
wherein in formula (7), L¹, L² and L³ each independently represent a single bond or a linking group; R¹, R³ and R⁴ each independently represent a hydrogen atom or a substituent; R² represents a substituent; R^{a} and R^{b} each independently represent a substituent; n and m each independently represent an integer from 0 to 3; R⁵, R⁷ and R⁸ each independently represent a hydrogen atom or a substituent; and R⁶ represents a substituent.

11. The organic electroluminescence device of claim 1, wherein the luminescence layer comprises a hole transporting host material.
